(19) United States
(12) Patent Application Publication
(10) Pub. No.: US 2023/0301189 A1
(43) Pub. Date: Sep. 21, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Qiang Wang, Beijing (CN); Le Wang, Beijing (CN); Ziyan Zhang, Beijing (CN); Meiying Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/098,961

(22) Filed: Jan. 19, 2023

(30) Foreign Application Priority Data
Jan. 28, 2022 (CN) 202210098714.5

(51) Int. Cl. H10K 85/60

(52) U.S. Cl. CPC H10K 85/6574; H10K 85/615; H10K 85/654; H10K 85/657; H10K 85/6572; H10K 85/6576; H10K 2101/10

(57) ABSTRACT

Provided is an organic electroluminescent device. The organic electroluminescent device comprises a first compound having a structure of Formula H-L-Ar and a second compound having a structure of Formula 2. The compounds may be used as host materials in the organic electroluminescent device, and this new compound combination can provide better device performance, such as higher efficiency, a longer lifetime and a low voltage. Further provided are an electronic device comprising the organic electroluminescent device and a compound combination comprising the first compound and the second compound.

### CROSS-REFERENCE TO RELATED APPLICATION(S)

This application claims priority to Chinese Patent Application No. 202210098714.5 filed on Jan. 28, 2022, the disclosure of which is incorporated herein by reference in its entirety.

### TECHNICAL FIELD

The present disclosure relates to an organic electronic device, for example, an organic electroluminescent device. More particularly, the present disclosure relates to an electroluminescent device comprising a first compound having a structure of H-L-Ar and a second compound having a structure of Formula 2 and a display assembly comprising the electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

KR20150077220A discloses a compound having a general structure of

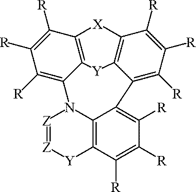

and further discloses use of the compound in an organic electroluminescentdevice. However, this application does not disclose nor teach that this compound and a compound, which is formed by joining a triazine group to dibenzofuran or a structure similar to dibenzofuran through a single bond or a joining group, are used together as host materials, nor does it teach that a dual-host device comprising this compound can achieve a better effect.

US20180337340A1 discloses a compound having a general structure of

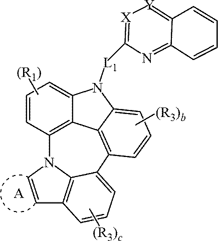

and also discloses an organic electroluminescent device where this compound is used as a first host compound, where the organic electroluminescent device may further comprise a second host compound. However, this application does not disclose that this compound and a second host compound, which has both naphthyl-phenyl and a triazine group joined to dibenzofuran or a structure similar to dibenzofuran through a single bond or a joining group, are used together as host materials, nor does it teach that a dual-host device structure comprising this compound can improve device performance.

KR1020200072211A discloses an organic optical compound having a structure of

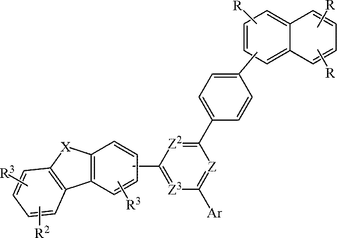

and further discloses use of the compound in an organic electroluminescent device. However, this application does not disclose or teach that this compound with a compound, which has an indole-fused azamacrocycle structural unit, are used together as host materials in the organic electroluminescent device.

KR1020190135707A discloses an organic electroluminescent device whose light-emitting layer comprises two hosts, where one host structure has a general formula of

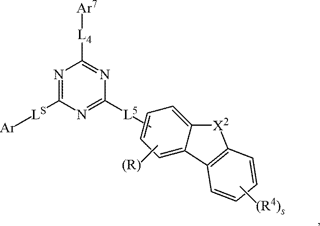

and the other host structure has a general formula of

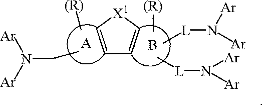

However, this application does not disclose nor teach that this triazine compound and a compound, which has an indole-fused azamacrocycle structural unit, are used together as host materials.

WO2021230714A discloses an organic electroluminescent device whose light-emitting layer comprises two hosts, where a first host structure has a general formula of

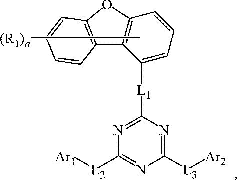

and a second host structure has a general formula of

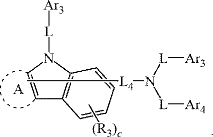

However, this application does not disclose nor teach that the triazine compound and a compound, which has an indole-fused azamacrocycle structural unit, are used together as host materials, nor does it teach that a dual-host device structure comprising the combination can improve device performance.

WO2021221475A1 discloses an organic electroluminescent device whose light-emitting layer comprises two hosts, where a first host structure has a general formula of

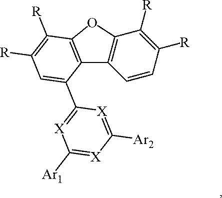

and a second host structure has a general formula of

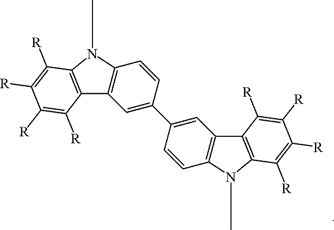

However, this application does not disclose nor teach that the triazine compound and a compound, which has an indole-fused azamacrocycle structural unit, are used together as host materials.

However, for many host materials reported at present, there is still room for improvement. To meet an increasing requirement of the industry, especially requirements for performance such as higher device efficiency, a longer lifetime and a lower drive voltage, a new material combination still requires further research and development.

### SUMMARY

The present disclosure aims to provide a series of electroluminescent devices each comprising a first compound having a structure of H-L-Ar and a second compound having a structure of Formula 2 in an organic layer to solve at least part of the above-mentioned problems. The first compound and the second compound may be used as host materials in the organic electroluminescent device, and this new compound combination can provide better device performance.

According to an embodiment of the present disclosure, disclosed is an electroluminescent device, which comprises:
an anode,
a cathode and
an organic layer disposed between the anode and the cathode, wherein the organic layer comprises at least a first compound and a second compound;
wherein the first compound has a structure of H-L-Ar, wherein H has a structure represented by Formula 1:

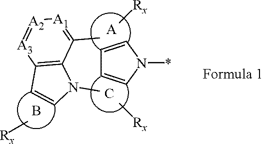

wherein in Formula 1,
A₁, A₂ and A₃ are, at each occurrence identically or differently, selected from N or CR, and the ring A, the ring B and the ring C are, at each occurrence identically or differently, selected from a carbocyclic ring having 5 to 18 carbon atoms or a heterocyclic ring having 3 to 18 carbon atoms;
Rₓ represents, at each occurrence identically or differently, mono-substitution, multiple substitutions or non-substitution;
Ar is selected from substituted or unsubstituted aryl having 6 to 30 carbon atoms, substituted or unsubstituted heteroaryl having 3 to 30 carbon atoms, substituted or unsubstituted arylamino having 6 to 30 carbon atoms or a combination thereof;
L is selected from a single bond, substituted or unsubstituted arylene having 6 to 30 carbon atoms, substituted or unsubstituted heteroarylene having 3 to 30 carbon atoms or a combination thereof;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ can be optionally joined to form a ring; and
“*” represents a position where H is joined to L;
wherein the second compound has a structure represented by Formula 2:

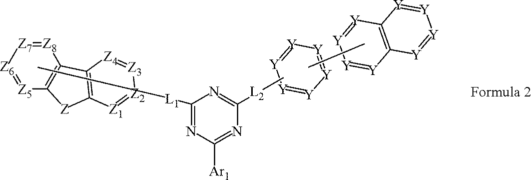

wherein in Formula 2,
Z is selected from O, S or Se;
Z₁ to Z₈ are selected from C, N or CR_{z}, and one of Z₁ to Z₈ is selected from C and joined to L₁;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

According to another embodiment of the present disclosure, further disclosed is a compound combination, which comprises the first compound and the second compound in the preceding embodiment.

According to another embodiment of the present disclosure, further disclosed is an electronic apparatus, which comprises the electroluminescent device in the preceding embodiment.

The present disclosure provides the electroluminescent device comprising the first compound having the structure of H-L-Ar and the second compound having the structure of Formula 2, and the electroluminescent device can obtain higher efficiency, a longer lifetime and a low voltage. That is, better device performance is provided.

### BRIEF DESCRIPTION OF DRAWINGS

FIG. 1 is a schematic diagram of an organic light-emitting apparatus that may comprise an electroluminescent device disclosed herein.

FIG. 2 is a schematic diagram of another organic light-emitting apparatus that may comprise an electroluminescent device disclosed herein.

### DETAILED DESCRIPTION

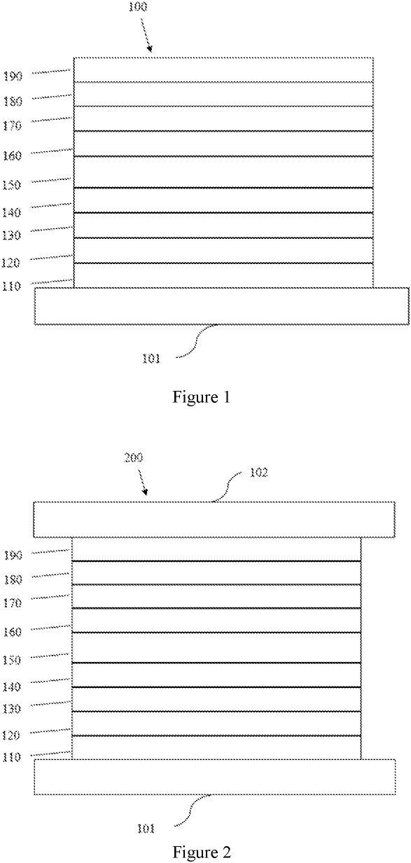

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Pat. Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Pat. Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Pat. Application Publication No. 2003/0230980, which are incorporated by reference herein in their entireties. Examples of injection layers are provided in U.S. Pat. Application Publication No. 2004/0174116, which is incorporated by reference herein in its entirety. A description of protective layers may be found in U.S. Pat. Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide - as used herein includes fluorine, chlorine, bromine, and iodine.

Alkyl - as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl - as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl - as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl - as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl - as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group - as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle - as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl - as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy - as used herein, is represented by -O-alkyl, -O-cycloalkyl, -O-heteroalkyl, or -O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy - as used herein, is represented by -O-aryl or -O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl - as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl - as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl - as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl - as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl - as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C-H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

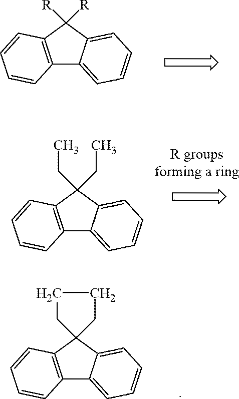

The expression that adjacent substituents can be optionally joined to form a ring is also intended to mean that two substituents bonded to carbon atoms which are directly bonded to each other are joined to each other via a chemical bond to form a ring, which can be exemplified by the following formula:

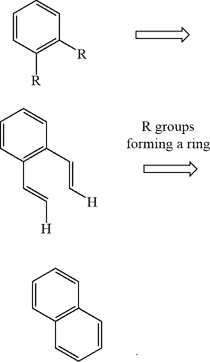

The expression that adjacent substituents can be optionally joined to form a ring is also intended to mean that two substituents bonded to further distant carbon atoms are joined to each other via a chemical bond to form a ring, which can be exemplified by the following formula:

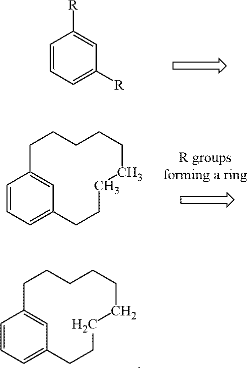

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

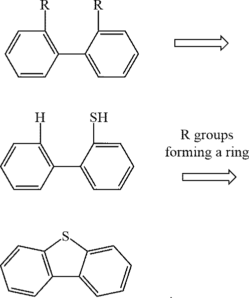

According to an embodiment of the present disclosure, disclosed is an electroluminescent device, which comprises:
an anode,
a cathode and
an organic layer disposed between the anode and the cathode, wherein the organic layer comprises at least a first compound and a second compound;
wherein the first compound has a structure of H-L-Ar, wherein H has a structure represented by Formula 1:

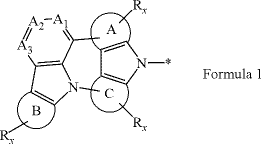

wherein in Formula 1,
A₁, A₂ and A₃ are, at each occurrence identically or differently, selected from N or CR, and the ring A, the ring B and the ring C are, at each occurrence identically or differently, selected from a carbocyclic ring having 5 to 18 carbon atoms or a heterocyclic ring having 3 to 18 carbon atoms;
Rₓ represents, at each occurrence identically or differently, mono-substitution, multiple substitutions or non-substitution;
Ar is selected from substituted or unsubstituted aryl having 6 to 30 carbon atoms, substituted or unsubstituted heteroaryl having 3 to 30 carbon atoms, substituted or unsubstituted arylamino having 6 to 30 carbon atoms or a combination thereof;
L is selected from a single bond, substituted or unsubstituted arylene having 6 to 30 carbon atoms, substituted or unsubstituted heteroarylene having 3 to 30 carbon atoms or a combination thereof;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ can be optionally joined to form a ring; and
“*” represents a position where H is joined to L;
wherein the second compound has a structure represented by Formula 2:

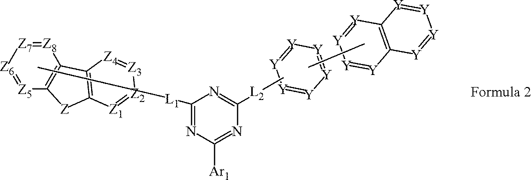

wherein in Formula 2,
Z is selected from O, S or Se;
Z₁ to Z₈ are selected from C, N or CR_{z}, and one of Z₁ to Z₈ is selected from C and joined to L₁;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

In the present disclosure, the expression that adjacent substituents R, Rₓ can be optionally joined to form a ring is intended to mean that any one or more of groups of adjacent substituents, such as adjacent substituents R, adjacent substituents Rₓ, and adjacent substituents R and Rₓ, can be joined to form a ring. Obviously, for those skilled in the art, it is also possible that none of these groups of adjacent substituents are joined to form a ring.

In the present disclosure, the expression that adjacent substituents R_{z} can be optionally joined to form a ring is intended to mean that any one of groups of adjacent substituents, such as adjacent substituents R_{z}, can be joined to form a ring. Obviously, for those skilled in the art, it is also possible that none of these groups of adjacent substituents are joined to form a ring.

According to an embodiment of the present disclosure, wherein in the first compound, the ring A, the ring B and the ring C are, at each occurrence identically or differently, selected from a five-membered carbocyclic ring, an aromatic ring having 6 to 18 carbon atoms or a heteroaromatic ring having 3 to 18 carbon atoms.

According to an embodiment of the present disclosure, wherein in the first compound, the ring A, the ring B and the ring C are, at each occurrence identically or differently, selected from a five-membered carbocyclic ring, a benzene ring, a five-membered heteroaromatic ring or a six-membered heteroaromatic ring.

According to an embodiment of the present disclosure, wherein in the first compound, H has a structure represented by Formula 1A:

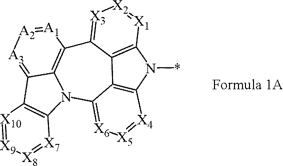

wherein A₁ to A₃ are, at each occurrence identically or differently, selected from N or CR, and X₁ to X₁₀ are, at each occurrence identically or differently, selected from N or CRₓ;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, Rₓ can be optionally joined to form a ring.

According to an embodiment of the present disclosure, R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, an isocyano group, a hydroxyl group, a sulfanyl group and combinations thereof; and
adjacent substituents R, Rₓ can be optionally joined to form a ring.

According to an embodiment of the present disclosure, at least one of R and Rₓ is selected from deuterium, halogen, a cyano group, a hydroxyl group, a sulfanyl group, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms or a combination thereof; and
adjacent substituents R, Rₓ can be optionally joined to form a ring.

According to an embodiment of the present disclosure, at least one of R and Rₓ is selected from deuterium, fluorine, a cyano group, a hydroxyl group, a sulfanyl group, methyl, trideuteromethyl, vinyl, phenyl, biphenyl, naphthyl, 4-cyanophenyl, dibenzofuranyl, dibenzothienyl, triphenylenyl, carbazolyl, 9-phenylcarbazolyl, 9,9-dimethylfluorenyl, pyridyl, phenylpyridyl or a combination thereof.

According to an embodiment of the present disclosure, wherein H is selected from any one of the group consisting of H-1 to H-139, wherein the specific structures of H-1 to H-139 are referred to claim 5.

According to an embodiment of the present disclosure, hydrogens in the structures of H-1 to H-139 can be partially or fully substituted with deuterium.

According to an embodiment of the present disclosure, Ar is selected from a structure represented by any one of the group consisting of Formula 1-a to Formula 1-d:

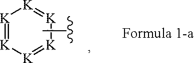

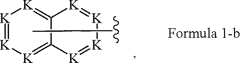

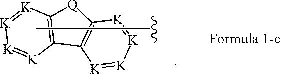

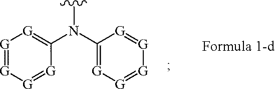

wherein K is, at each occurrence identically or differently, selected from C, N or CR_{K};
G is, at each occurrence identically or differently, selected from N or CR_{G};
Q is selected from NR_{q}, O, S, SiR_{q}R_{q}, CR_{q}R_{q}, BR_{q} or PR_{q};
R_{K}, R_{q} and R_{G} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{q}, R_{K}, R_{G} can be optionally joined to form a ring; and

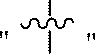

represents a position where Ar is joined to L.

In the present disclosure, the expression that adjacent substituents R_{q}, R_{K}, R_{G} can be optionally joined to form a ring is intended to mean that any one or more of groups of adjacent substituents, such as adjacent substituents R_{q}, adjacent substituents R_{K}, adjacent substituents R_{G}, and adjacent substituents R_{q} and R_{K}, can be joined to form a ring. Obviously, for those skilled in the art, it is also possible that none of these groups of adjacent substituents are joined to form a ring.

According to an embodiment of the present disclosure, wherein Q is selected from NR_{q}, O, S or CR_{q}R_{q}.

According to an embodiment of the present disclosure, wherein Q is selected from O.

According to an embodiment of the present disclosure, wherein R_{q}, R_{K} and R_{G} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, a cyano group and combinations thereof; and
adjacent substituents R_{q}, R_{K}, R_{G} can be optionally joined to form a ring.

According to an embodiment of the present disclosure, R_{q}, R_{K} and R_{G} are, at each occurrence identically or differently, selected from the group consisting of: hydrogen, deuterium, fluorine, a cyano group, methyl, ethyl, propyl, isopropyl, phenyl, biphenyl, naphthyl, vinyl, 9-phenylcarbazolyl, naphthylphenyl, phenylpyridyl, dibenzofuranyl, dibenzothienyl, 9,9-dimethylfluorenyl, carbazolyl, pyridyl, pyrimidinyl, 4-cyanophenyl, triphenylenyl, terphenyl and combinations thereof; and
adjacent substituents R_{q}, R_{K}, R_{G} can be optionally joined to form a ring.

According to an embodiment of the present disclosure, wherein Ar is, at each occurrence identically or differently, selected from substituted or unsubstituted phenyl, substituted or unsubstituted naphthyl, substituted or unsubstituted triazinyl, substituted or unsubstituted quinazolinyl, substituted or unsubstituted benzoquinazolinyl, substituted or unsubstituted benzoquinoxalinyl, substituted or unsubstituted quinoxalinyl, substituted or unsubstituted dibenzofuranyl, substituted or unsubstituted benzonaphthofuranyl, substituted or unsubstituted dibenzothienyl, substituted or unsubstituted benzonaphthothiophenyl, substituted or unsubstituted azadibenzofuranyl, substituted or unsubstituted azadibenzothienyl, substituted or unsubstituted carbazolyl, substituted or unsubstituted fluorenyl, substituted or unsubstituted spirobifluorenyl, substituted or unsubstituted diphenylamino or a combination thereof.

According to an embodiment of the present disclosure, wherein Ar is, at each occurrence identically or differently, selected from substituted or unsubstituted phenyl, substituted or unsubstituted naphthyl, substituted or unsubstituted dibenzofuranyl, substituted or unsubstituted benzonaphthofuranyl, substituted or unsubstituted dibenzothienyl, substituted or unsubstituted carbazolyl, substituted or unsubstituted fluorenyl, substituted or unsubstituted spirobifluorenyl or a combination thereof.

According to an embodiment of the present disclosure, wherein Ar is selected from any one of the group consisting of Ar-1 to Ar-130, wherein the specific structures of Ar-1 to Ar-130 are referred to claim 9.

According to an embodiment of the present disclosure, hydrogens in the structures of Ar-1 to Ar-130 can be partially or fully substituted with deuterium.

According to an embodiment of the present disclosure, wherein L is, at each occurrence identically or differently, selected from a single bond, substituted or unsubstituted arylene having 6 to 18 carbon atoms, substituted or unsubstituted heteroarylene having 3 to 18 carbon atoms or a combination thereof.

According to an embodiment of the present disclosure, wherein L is, at each occurrence identically or differently, selected from a single bond, substituted or unsubstituted phenylene, substituted or unsubstituted naphthylene, substituted or unsubstituted biphenylene, substituted or unsubstituted terphenylene, substituted or unsubstituted dibenzofuranylene, substituted or unsubstituted dibenzothienylene or a combination thereof.

According to an embodiment of the present disclosure, wherein L is selected from any one of the group consisting of L-0 to L-29, wherein the specific structures of L-0 to L-29 are referred to claim 10.

According to an embodiment of the present disclosure, hydrogens in the structures of L-1 to L-29 can be partially or fully substituted with deuterium.

According to an embodiment of the present disclosure, wherein the first compound has the structure of H-L-Ar, wherein H is selected from any one of the group consisting of H-1 to H-139, L is selected from any one of the group consisting of L-0 to L-29, and Ar is selected from any one of the group consisting of Ar-1 to Ar-130; optionally, hydrogens in the first compound can be partially or fully substituted with deuterium.

According to an embodiment of the present disclosure, wherein the first compound is selected from the group consisting of Compound 1 to Compound 772, wherein the specific structures of Compound 1 to Compound 772 are referred to claim 11.

According to an embodiment of the present disclosure, wherein hydrogens in the structures of Compound 1 to Compound 772 can be partially or fully substituted with deuterium.

According to an embodiment of the present disclosure, wherein the second compound has a structure represented by Formula 2-1 or Formula 2-2:

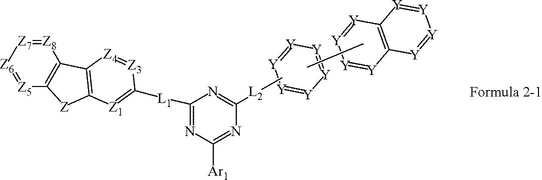

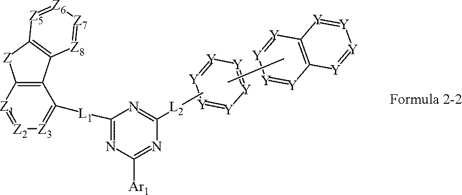

wherein
Z is selected from O, S or Se;
Z₁ to Z₈ are, at each occurrence identically or differently, selected from N or CR_{z};
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

According to an embodiment of the present disclosure, wherein in Formula 2, Z₁ to Z₈ are, at each occurrence identically or differently, selected from C or CR_{z}, and/or Y is, at each occurrence identically or differently, selected from C or CR_{y}, wherein R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein in Formula 2-1 and Formula 2-2, Z₁ to Z₈ are selected from CR_{z}, and/or Y is, at each occurrence identically or differently, selected from C or CR_{y}, wherein R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

In this embodiment, the expression that in Formula 2-1 and Formula 2-2, Z₁ to Z₈ are selected from CR_{z} is intended to mean that in Formula 2-1, Z₁ and Z₃ to Z₈ are selected from CR_{z}, and in Formula 2-2, Z₁ to Z₃ and Z₅ to Z₈ are selected from CR_{z}.

According to an embodiment of the present disclosure, wherein R_{z} and R_{y} are, at each occurrence identically or differently, selected from the group consisting of: hydrogen, deuterium, substituted or unsubstituted phenyl, substituted or unsubstituted naphthyl, substituted or unsubstituted biphenyl and combinations thereof.

According to an embodiment of the present disclosure, wherein Z is selected from O or S; preferably, Z is O.

According to an embodiment of the present disclosure, wherein Ar₁ is, at each occurrence identically or differently, selected from substituted or unsubstituted aryl having 6 to 30 carbon atoms.

According to an embodiment of the present disclosure, wherein Ar₁ is, at each occurrence identically or differently, selected from the group consisting of: phenyl, naphthyl, biphenyl, phenanthryl, terphenyl, triphenylenyl and combinations thereof.

According to an embodiment of the present disclosure, wherein L₁ and L₂ are, at each occurrence identically or differently, selected from a single bond, substituted or unsubstituted arylene having 6 to 18 carbon atoms, substituted or unsubstituted heteroarylene having 3 to 18 carbon atoms or a combination thereof.

According to an embodiment of the present disclosure, wherein L₁ and L₂ are, at each occurrence identically or differently, selected from a single bond, substituted or unsubstituted phenylene, substituted or unsubstituted naphthylene, substituted or unsubstituted biphenylene or a combination thereof.

According to an embodiment of the present disclosure, wherein at least one of Z₁ to Z₈ is selected from N, and/or at least one of Y is N.

According to an embodiment of the present disclosure, wherein the second compound is selected from the group consisting of Compound A-1 to Compound A-200, wherein the specific structures of Compound A-1 to Compound A-200 are referred to claim 17.

According to an embodiment of the present disclosure, wherein hydrogens in the structures of Compound A-1 to Compound A-200 can be partially or fully substituted with deuterium.

According to an embodiment of the present disclosure, wherein the organic layer is a light-emitting layer, and the first compound and the second compound are host materials.

According to an embodiment of the present disclosure, wherein the light-emitting layer further comprises at least one phosphorescent material.

According to an embodiment of the present disclosure, wherein the at least one phosphorescent material is a metal complex having a general formula of M(Lₐ)ₘ(L_{b})ₙ(L_{c})_{q};
M is selected from a metal with a relative atomic mass greater than 40;
Lₐ, L_{b} and L_{c} are a first ligand, a second ligand and a third ligand coordinated to M, respectively; Lₐ, L_{b} and L_{c} can be optionally joined to form a multidentate ligand; and
Lₐ, L_{b} and L_{c} may be identical or different; m is 1, 2 or 3; n is 0, 1 or 2; q is 0, 1 or 2; the sum of m, n and q is equal to an oxidation state of M; when m is greater than or equal to 2, a plurality of Lₐ may be identical or different; when n is 2, two L_{b} may be identical or different; when q is 2, two L_{c} may be identical or different;
wherein Lₐ has a structure represented by Formula 3:

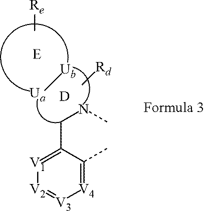

wherein
   the ring D is selected from a five-membered heteroaromatic ring or a six-membered heteroaromatic ring;
   the ring E is selected from a five-membered unsaturated carbocyclic ring, a benzene ring, a five-membered heteroaromatic ring or a six-membered heteroaromatic ring;
   the ring D and the ring E are fused via Uₐ and U_{b};
   Uₐ and U_{b} are, at each occurrence identically or differently, selected from C or N;
   R_{d} and Rₑ represent, at each occurrence identically or differently, mono-substitution, multiple substitutions or non-substitution;
   V₁ to V₄ are, at each occurrence identically or differently, selected from CRᵥ or N;
   R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
   adjacent substituents R_{d}, Rₑ, Rᵥ can be optionally joined to form a ring;
   wherein L_{b} and L_{c} are, at each occurrence identically or differently, selected from any one of the following structures: 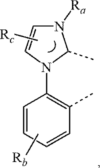 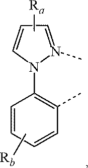 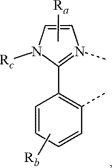 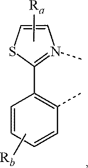 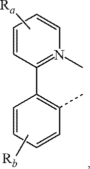 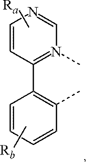 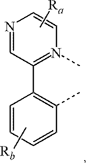 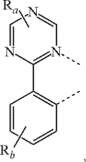 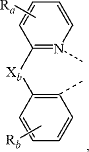 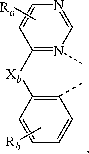 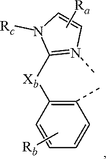 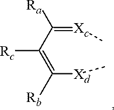
   wherein
      Rₐ, R_{b} and R_{c} represent, at each occurrence identically or differently, mono-substitution, multiple substitutions or non-substitution;
      X_{b} is, at each occurrence identically or differently, selected from the group consisting of: O, S, Se, NR_{N1} and CR_{C1}R_{C2};
      X_{c} and X_{d} are, at each occurrence identically or differently, selected from the group consisting of: O, S, Se and NR_{N2};
      Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
      in the structures of the ligands L_{b} and L_{c}, adjacent substituents Rₐ, R_{b}, R_{c}, R_{N1}, R_{N2}, R_{C1} and R_{C2} can be optionally joined to form a ring.

In the present disclosure, the expression that adjacent substituents R_{d}, Rₑ and Rᵥ can be optionally joined to form a ring is intended to mean that in the presence of substituents R_{d}, Rₑ and Rᵥ, any one or more of groups of adjacent substituents, such as adjacent substituents R_{d}, adjacent substituents Rₑ, adjacent substituents Rᵥ, adjacent substituents R_{d} and Rₑ, adjacent substituents R_{d} and Rᵥ, and adjacent substituents Rₑ and Rᵥ, can be joined to form a ring. Obviously, in the presence of substituents R_{d}, Rₑ and Rᵥ, it is also possible that none of these groups of adjacent substituents are joined to form a ring.

In the present disclosure, the expression that adjacent substituents Rₐ, R_{b}, R_{c}, R_{N1}, R_{N2}, R_{C1}, R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1}, and R_{C2}, can be joined to form a ring. Obviously, it is also possible that none of these substituents are joined to form a ring.

According to an embodiment of the present disclosure, wherein in Formula 3, at least one or two groups of adjacent substituents of R_{d}, Rₑ and Rᵥ are joined to form a ring. For example, two substituents R_{d} are joined to form a ring, or two substituents Rₑ are joined to form a ring, or two substituents Rᵥ are joined to form a ring, or substituents R_{d} and Rₑ are joined to form a ring, or substituents R_{d} and Rᵥ are joined to form a ring, or substituents Rₑ and Rᵥ are joined to form a ring, or two substituents Rₑ are joined to form a ring while two substituents R_{d} are joined to form a ring, or two substituents Rᵥ are joined to form a ring while two substituents R_{d} are joined to form a ring, or two substituents Rᵥ are joined to form a ring while two substituents Rₑ are joined to form a ring, or two substituents Rᵥ are joined to form a ring while substituents Rₑ and Rᵥ are joined to form a ring, or two substituents Rᵥ are joined to form a ring while substituents R_{d} and Rᵥ are joined to form a ring; more groups of adjacent substituents of R_{d}, Rₑ and Rᵥ are joined to form a ring with a similar case.

According to an embodiment of the present disclosure, in the device, the at least one phosphorescent material is a metal complex having a general formula of M(Lₐ)ₘ(L_{b})ₙ;
M is selected from a metal with a relative atomic mass greater than 40;
Lₐ and L_{b} are a first ligand and a second ligand coordinated to M, respectively; Lₐ and L_{b} can be optionally joined to form a multidentate ligand; and
m is 1, 2 or 3; n is 0, 1 or 2; the sum of m and n is equal to an oxidation state of M; when m is greater than or equal to 2, a plurality of Lₐ may be identical or different; when n is 2, two L_{b} may be identical or different;
wherein Lₐ has a structure represented by Formula 3:

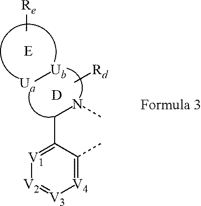

wherein
   the ring D is selected from a five-membered heteroaromatic ring or a six-membered heteroaromatic ring;
   the ring E is selected from a five-membered unsaturated carbocyclic ring, a benzene ring, a five-membered heteroaromatic ring or a six-membered heteroaromatic ring;
   the ring D and the ring E are fused via Uₐ and U_{b};
   Uₐ and U_{b} are, at each occurrence identically or differently, selected from C or N;
   R_{d} and Rₑ represent, at each occurrence identically or differently, mono-substitution, multiple substitutions or non-substitution;
   V₁ to V₄ are, at each occurrence identically or differently, selected from CRᵥ or N;
   R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
   adjacent substituents R_{d}, Rₑ, Rᵥ can be optionally joined to form a ring;
   wherein the ligand L_{b} has the following structure: 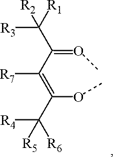
   wherein R₁ to R₇ are each independently selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group and combinations thereof.

According to an embodiment of the present disclosure, in the device, the ligand L_{b} has the following structure:

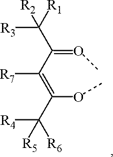

wherein at least one of R₁ to R₃ is selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one of R₄ to R₆ is selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, in the device, the ligand L_{b} has the following structure:

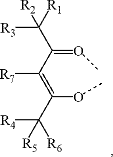

wherein at least two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, in the device, the ligand L_{b} has the following structure:

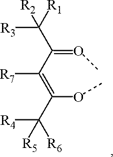

wherein at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

According to an embodiment of the present disclosure, wherein the metal M is selected from Ir, Pt or Os. According to an embodiment of the present disclosure, wherein the at least one phosphorescent material is an Ir complex and has a structure represented by any one of Ir(Lₐ)(L_{b})(L_{c}), Ir(Lₐ)₂(L_{b}), Ir(Lₐ)(L_{b})₂, Ir(Lₐ)₂(L_{c}) or Ir(Lₐ)(L_{c})₂.

According to an embodiment of the present disclosure, wherein Lₐ has the structure represented by Formula 3 and contains at least one structural unit selected from the group consisting of a 6-membered-fused-6-membered aromatic ring, a 6-membered-fused-6-membered heteroaromatic ring, a 6-membered-fused-5-membered aromatic ring, and a 6-membered-fused-5-membered heteroaromatic ring.

According to an embodiment of the present disclosure, wherein Lₐ has the structure represented by Formula 3 and comprises at least one structural unit selected from the group consisting of naphthalene, phenanthrene, quinoline, isoquinoline and azaphenanthrene.

According to an embodiment of the present disclosure, wherein in the electroluminescent device, the at least one phosphorescent material is an Ir complex and comprises a ligand Lₐ, wherein the Lₐ is, at each occurrence, selected from any one of the group consisting of the following structures:

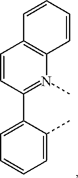

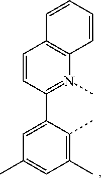

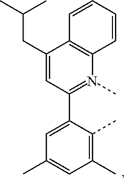

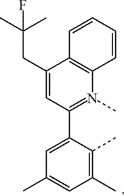

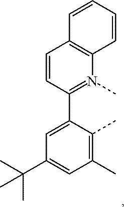

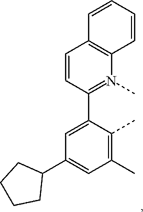

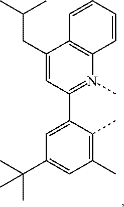

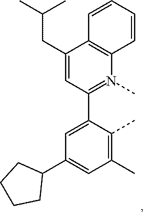

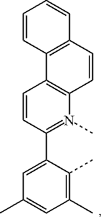

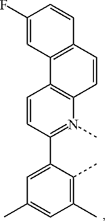

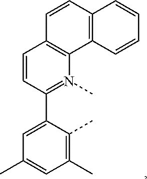

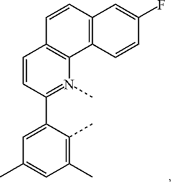

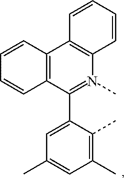

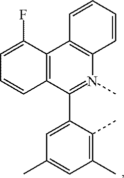

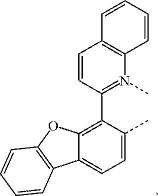

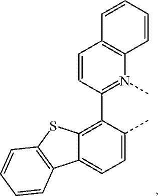

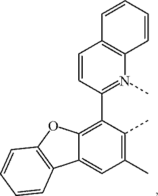

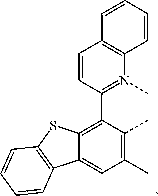

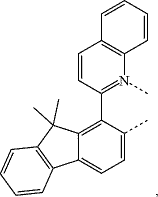

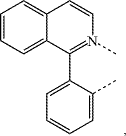

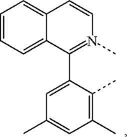

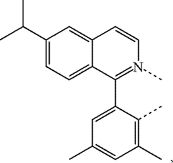

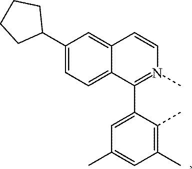

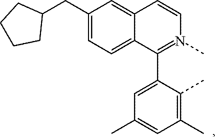

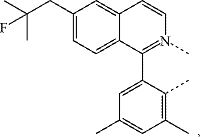

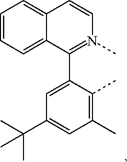

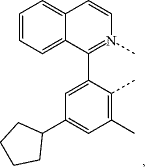

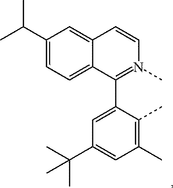

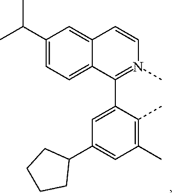

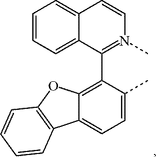

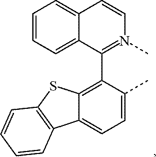

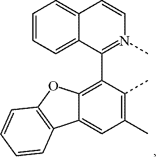

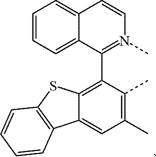

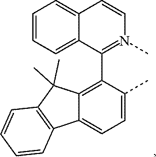

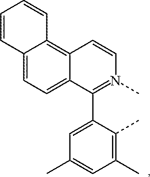

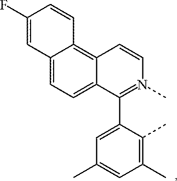

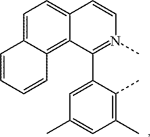

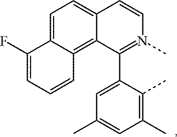

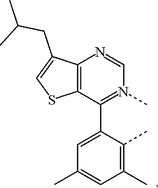

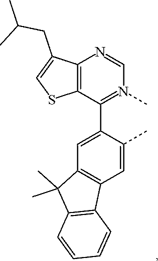

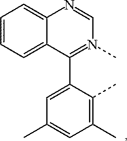

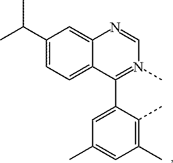

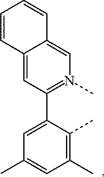

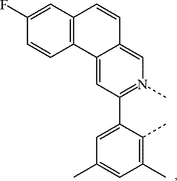

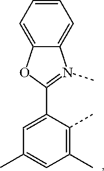

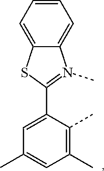

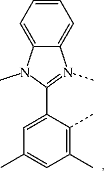

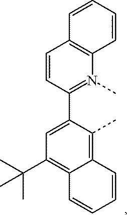

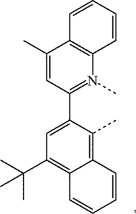

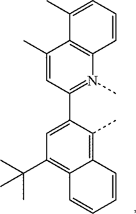

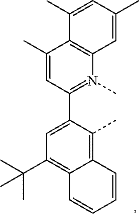

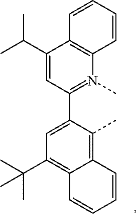

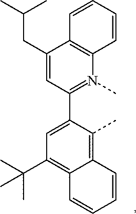

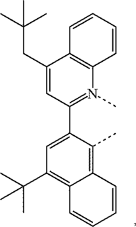

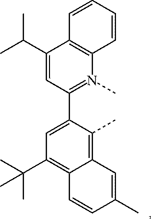

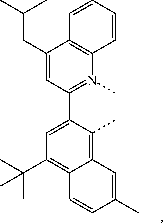

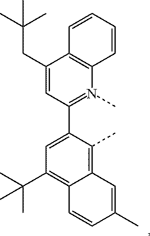

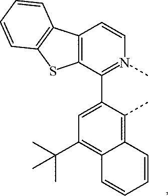

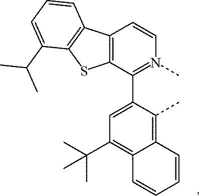

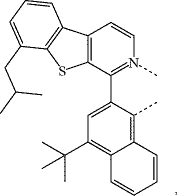

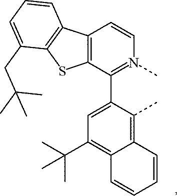

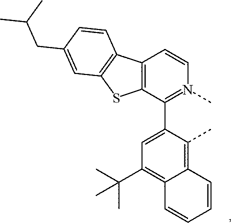

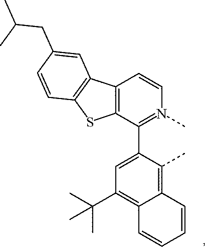

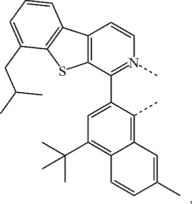

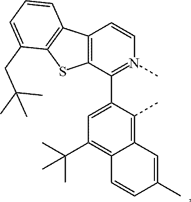

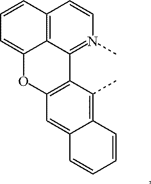

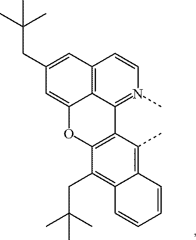

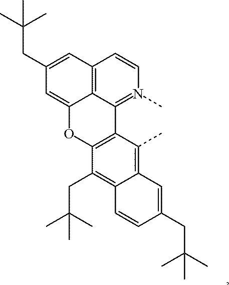

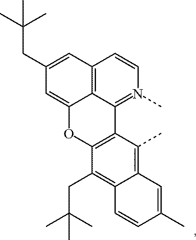

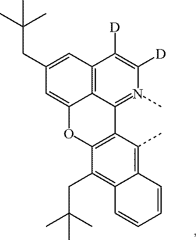

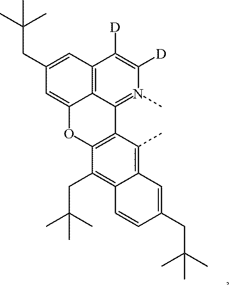

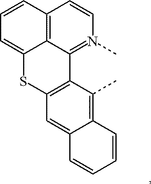

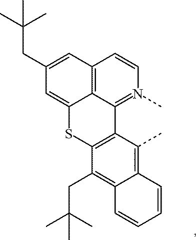

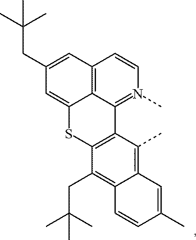

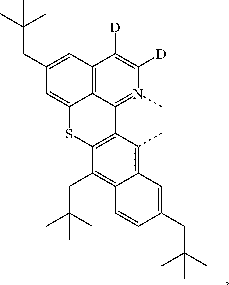

According to an embodiment of the present disclosure, wherein in the electroluminescent device, the at least one phosphorescent material is an Ir complex and comprises a ligand L_{b}, wherein the L_{b} is, at each occurrence, selected from any one of the group consisting of the following structures:

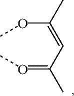

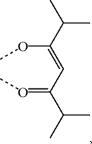

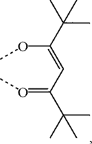

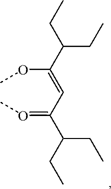

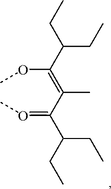

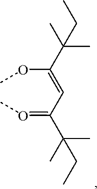

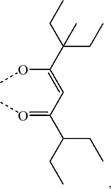

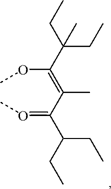

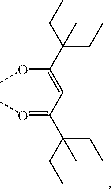

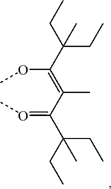

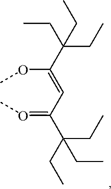

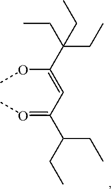

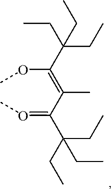

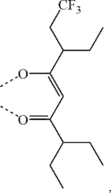

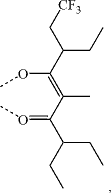

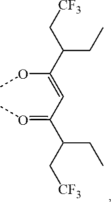

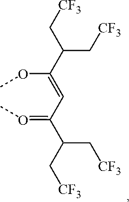

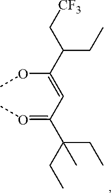

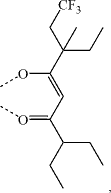

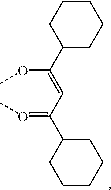

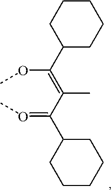

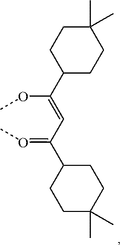

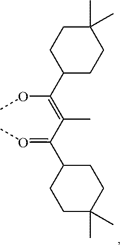

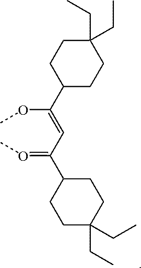

According to an embodiment of the present disclosure, wherein in the electroluminescent device, the at least one phosphorescent material is selected from the group consisting of the following structures:

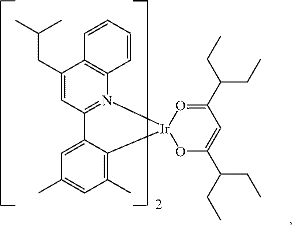

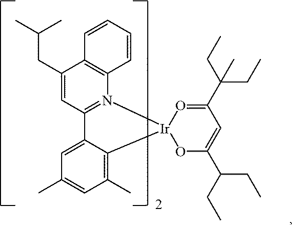

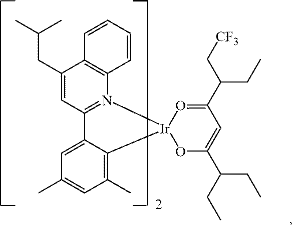

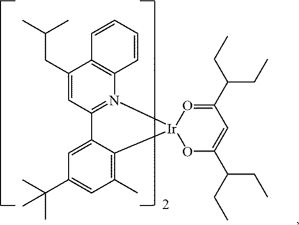

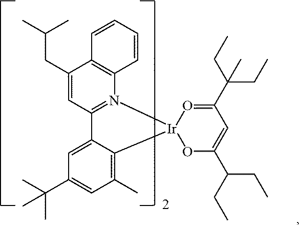

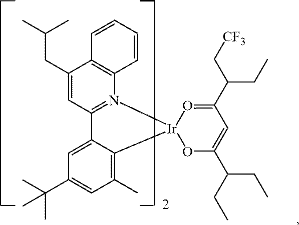

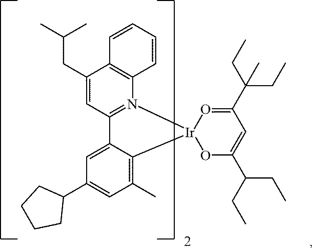

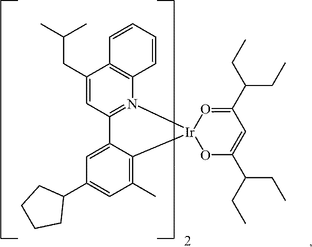

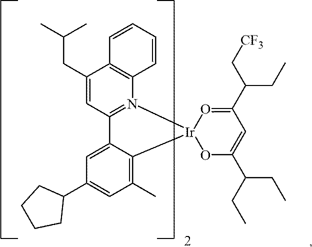

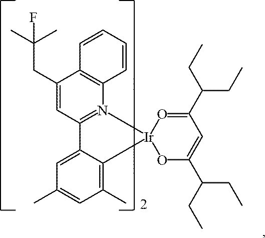

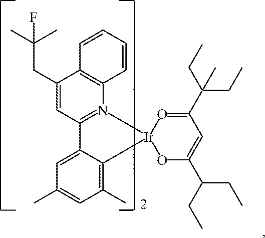

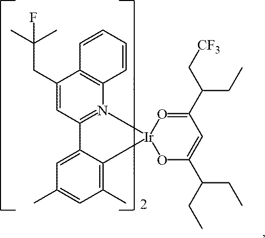

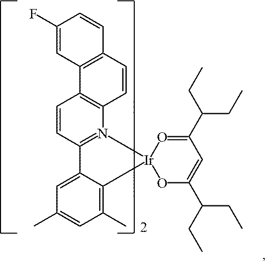

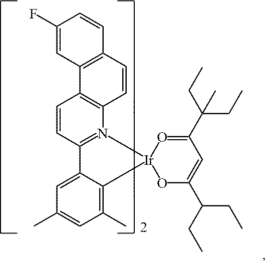

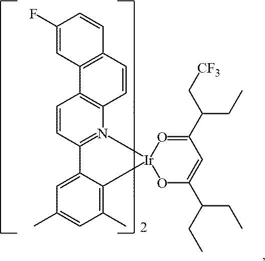

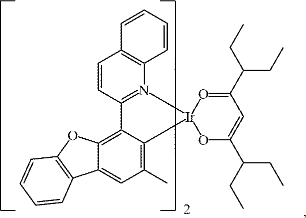

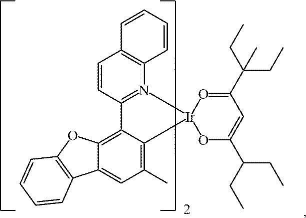

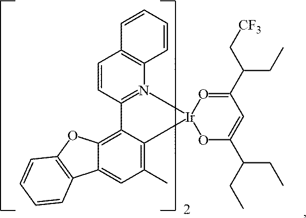

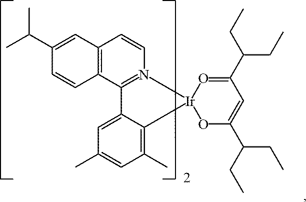

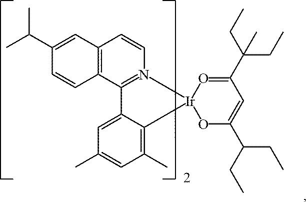

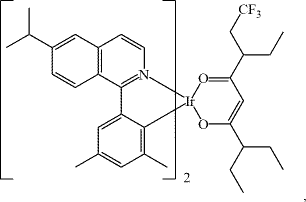

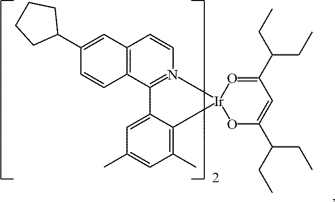

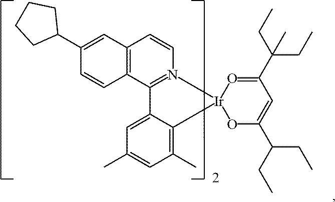

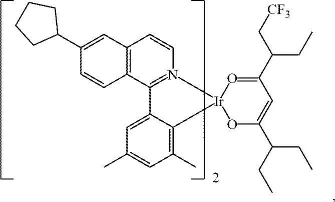

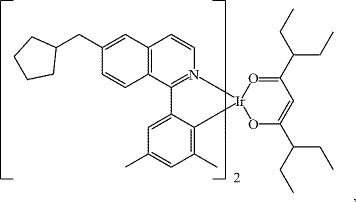

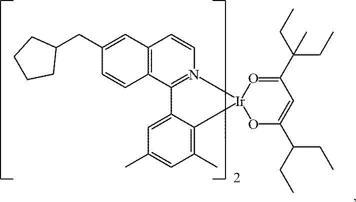

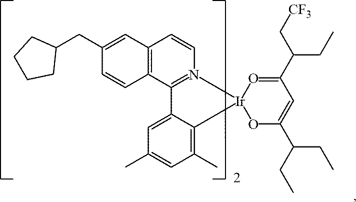

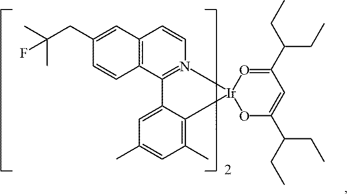

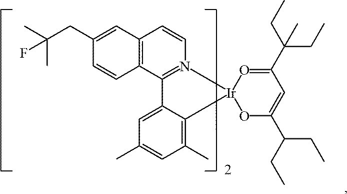

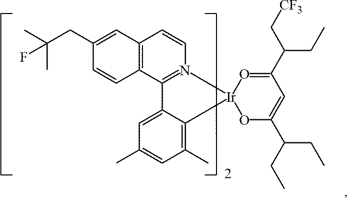

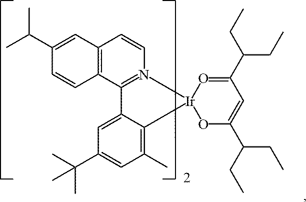

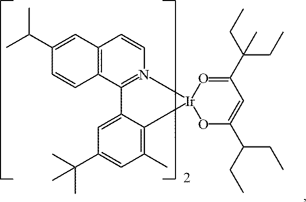

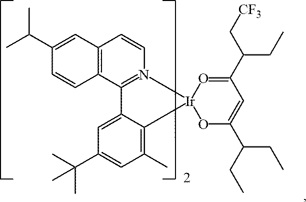

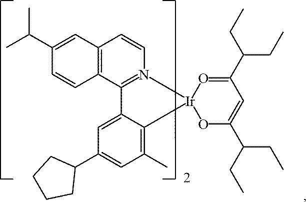

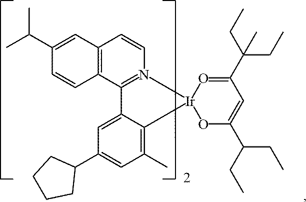

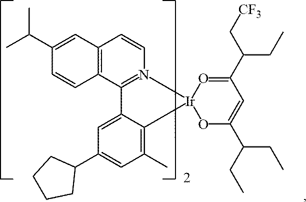

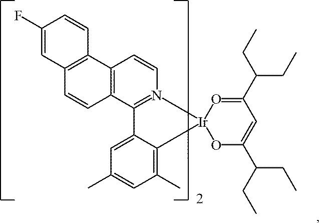

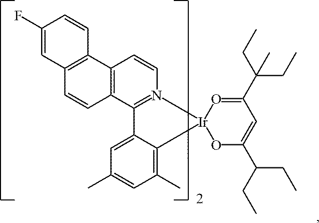

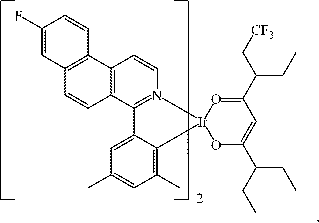

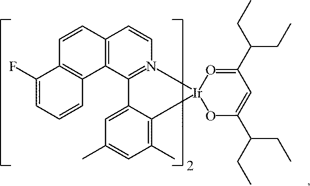

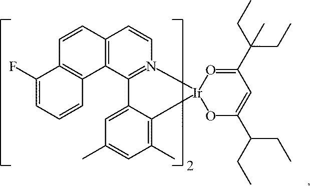

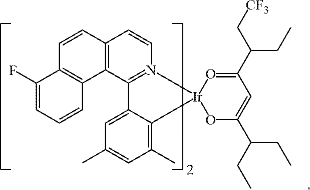

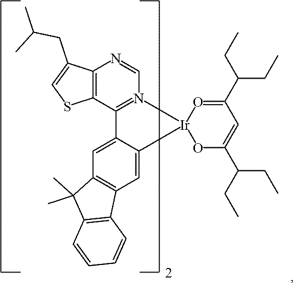

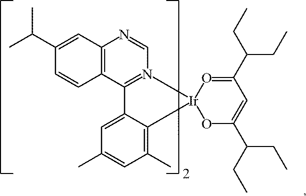

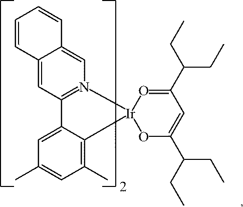

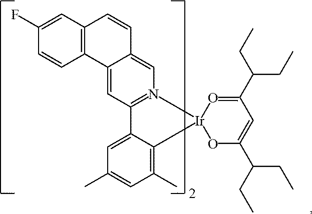

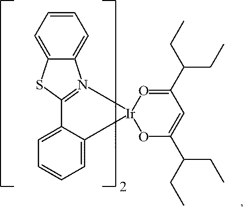

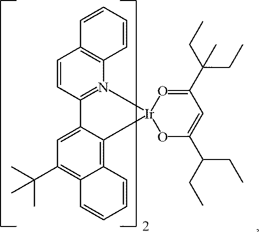

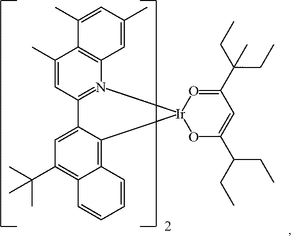

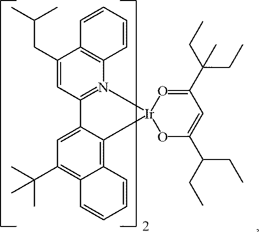

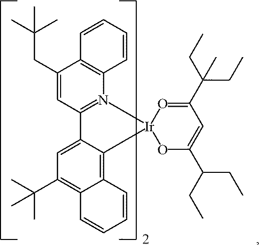

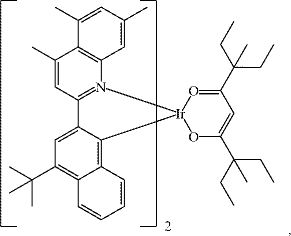

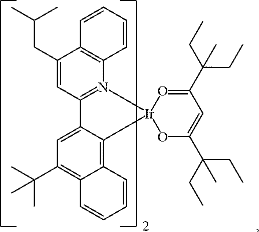

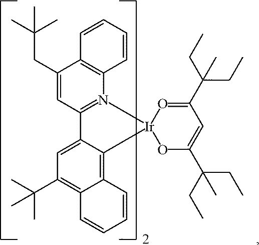

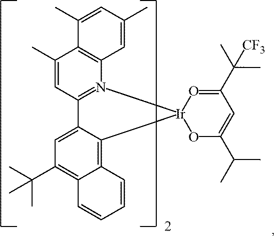

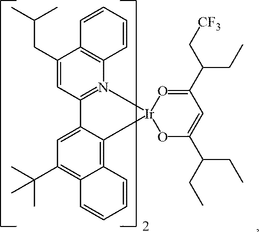

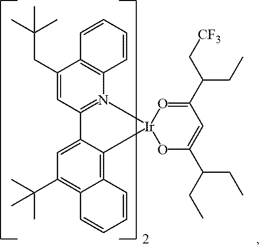

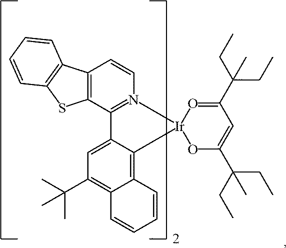

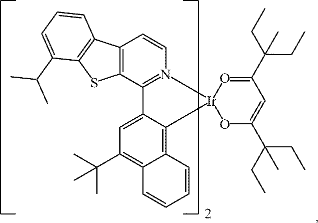

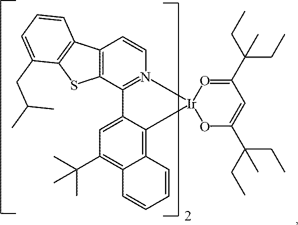

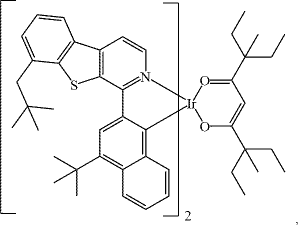

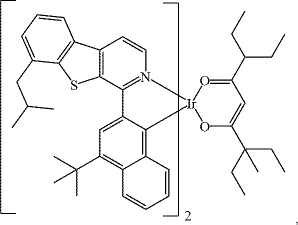

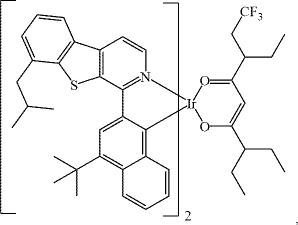

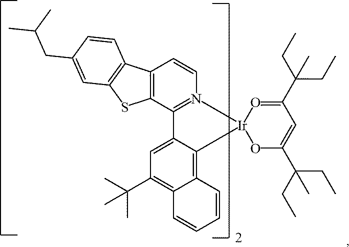

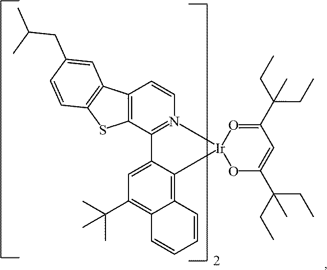

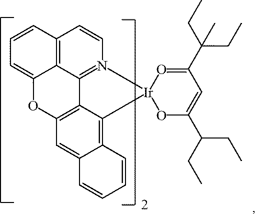

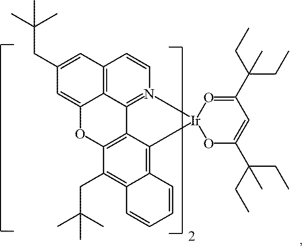

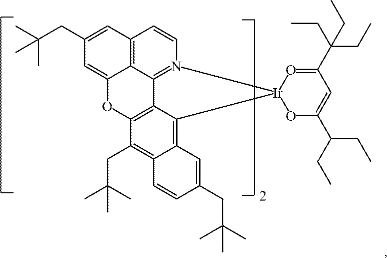

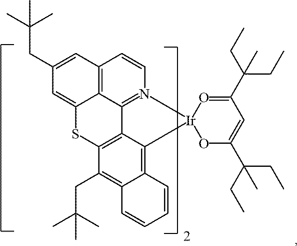

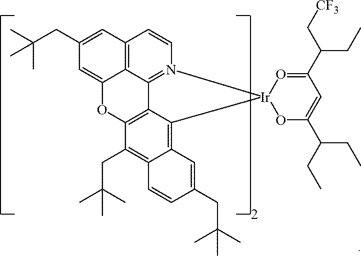

According to an embodiment of the present disclosure, wherein the electroluminescent device emits red light.

According to another embodiment of the present disclosure, further disclosed is a compound combination, which comprises the first compound and the second compound whose specific structures are as shown in any one of the preceding embodiments.

According to another embodiment of the present disclosure, further disclosed is an electronic apparatus, which comprises an electroluminescent device whose specific structure is as shown in any one of the preceding embodiments.

### Combination With Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, materials disclosed herein may be used in combination with a wide variety of dopants, hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art.

### Material Synthesis Example

A method for preparing the selected first compound is not limited in the present disclosure. Those skilled in the art may use a conventional synthesis method for the preparation, or may refer to preparation methods in patent applications such as US2018337340A1 and CN2020113994260. The method for preparing the selected first compound is not repeated here.

A method for preparing the selected second compound is not limited in the present disclosure. Those skilled in the art may use a conventional synthesis method for the preparation, or may refer to a synthesis route and preparation method of the following compound to easily obtain the selected second compound.

### Synthesis Example 1: Synthesis of Compound A-1

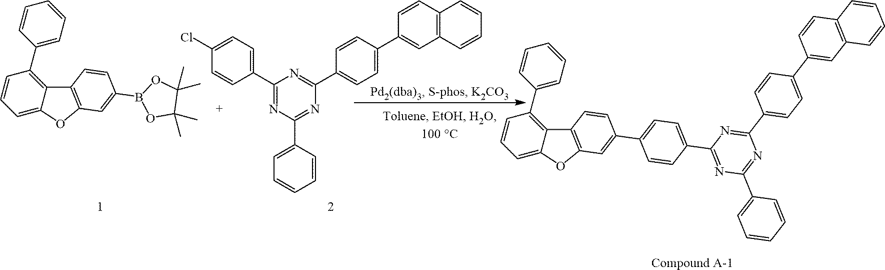

Under nitrogen protection, Intermediate 1 (2.3 g, 6.2 mmol), Intermediate 2 (2.9 g, 6.2 mmol), tris(dibenzylideneacetone)dipalladium (0.28 g, 0.31 mmol), 2-dicyclohexylphosphino-2′,6′-dimethoxybiphenyl (S-phos, 0.25 g, 0.62 mmol), potassium carbonate (1.7 g, 12.4 mmol) and solvent (toluene/ethanol/water = 280/70/70 mL) were added to a three-necked flask and reacted overnight at 100° C. After the reaction was completed, the system was cooled to room temperature and filtered to obtain a solid. The crude product was recrystallized from toluene to obtain Compound A-1 as a white solid (2.8 g, with a yield of 65%). The product was confirmed as the target product with a molecular weight of 677.2.

Those skilled in the art will appreciate that the above preparation method are merely exemplary. Those skilled in the art can obtain other structures of the second compound selected in the present disclosure through the modifications of the preparation method.

The method for preparing an electroluminescent device is not limited. The preparation methods in the following examples are merely examples and not to be construed as limitations. Those skilled in the art can make reasonable improvements on the preparation methods in the following examples based on the related art. Exemplarily, the proportions of various materials in a light-emitting layer are not particularly limited. Those skilled in the art can reasonably select the proportions within a certain range based on the related art. For example, taking the total weight of the materials in the light-emitting layer as reference, a host material may account for 80% to 99% and a light-emitting material may account for 1% to 20%; or the host material may account for 90% to 98% and the light-emitting material may account for 2% to 10%. Further, the host material may be two materials, where a ratio of the two host materials to the host material may be from 99:1 to 1:99; alternatively, the ratio may be from 80:20 to 20:80; alternatively, the ratio may be from 60:40 to 40:60.Characteristics of light-emitting devices prepared in examples are tested using conventional devices in the art by a method well-known to those skilled in the art. In the examples of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well-known to the persons skilled in the art. As the persons skilled in the art are aware of the above-mentioned equipment use, test methods and other related contents, the inherent data of the sample can be obtained with certainty and without influence, so the above related contents are not further described in this patent.

### Device Example

First, a glass substrate having an indium tin oxide (ITO) anode with a thickness of 80 nm was cleaned and then treated with UV zone and oxygen plasma. After the treatment, the substrate was dried in a nitrogen-filled glovebox to remove moisture. Then, the substrate was mounted on a substrate holder and placed in a vacuum chamber. Organic layers specified below were sequentially deposited on the ITO anode at a rate of 0.01 to 5 Å/s and a vacuum degree of about 10⁻⁸ torr. Compound HT and Compound HI were co-deposited as a hole injection layer (HIL) with a thickness of 100 Å. Compound HT was used as a hole transporting layer (HTL) with a thickness of 400 Å. Compound EB was used as an electron blocking layer (EBL) with a thickness of 50 Å. Then, Compound 117 as a first host, Compound A-1 as a second host and Compound RD as a dopant were co-deposited as an emissive layer (EML) with a thickness of 400 Å. Compound HB was used as a hole blocking layer (HBL) with a thickness of 50 Å. On the hole blocking layer, Compound ET and 8-hydroxyquinolinolato-lithium (Liq) were co-deposited as an electron transporting layer (ETL) with a thickness of 350 Å. Finally, 8-hydroxyquinolinolato-lithium (Liq) was deposited as an electron injection layer (EIL) with a thickness of 10 Å, and Al was deposited as a cathode with a thickness of 1200 Å. The device was transferred back to the glovebox and encapsulated with a glass lid to complete the device.

### Device Example 2

The implementation mode in Device Example 2 was the same as that in Device Example 1, except that in the emissive layer (EML), Compound A-1 was replaced with Compound A-168 as the second host.

### Device Example 3

The implementation mode in Device Example 3 was the same as that in Device Example 1, except that in the emissive layer (EML), Compound 117 was replaced with Compound 71 as the first host.

### Device Example 4

The implementation mode in Device Example 4 was the same as that in Device Example 3, except that in the emissive layer (EML), Compound A-1 was replaced with Compound A-168 as the second host.

### Device Example 5

The implementation mode in Device Example 5 was the same as that in Device Example 3, except that in the emissive layer (EML), Compound A-1 was replaced with Compound A-143 as the second host.

### Device Example 6

The implementation mode in Device Example 6 was the same as that in Device Example 1, except that in the emissive layer (EML), Compound A-1 was replaced with Compound A-158 as the second host.

### Device Example 7

The implementation mode in Device Example 7 was the same as that in Device Example 1, except that in the emissive layer (EML), Compound A-1 was replaced with Compound A-142 as the second host.

### Device Example 8

The implementation mode in Device Example 8 was the same as that in Device Example 3, except that in the emissive layer (EML), Compound A-1 was replaced with Compound A-148 as the second host.

### Device Comparative Example 1

The implementation mode in Device Comparative Example 1 was the same as that in Device Example 1, except that Compound 117 and Compound A-1 were replaced with Compound 117 as the host and Compound 117 and Compound RD were co-deposited (at a weight ratio of 98:2) in the emissive layer (EML).

### Device Comparative Example 2

The implementation mode in Device Comparative Example 2 was the same as that in Device Example 1, except that Compound 117 and Compound A-1 were replaced with Compound A-168 as the host and Compound A-168 and Compound RD were co-deposited (at a weight ratio of 98:2) in the emissive layer (EML).

### Device Comparative Example 3

The implementation mode in Device Comparative Example 3 was the same as that in Device Example 1, except that Compound 117 and Compound A-1 were replaced with Compound A-1 as the host and Compound A-1 and Compound RD were co-deposited (at a weight ratio of 98:2) in the emissive layer (EML).

### Device Comparative Example 4

The implementation mode in Device Comparative Example 4 was the same as that in Device Example 2, except that in the emissive layer (EML), Compound 117 was replaced with Compound C as the first host.

Detailed structures and thicknesses of layers of the devices are shown in the following table. A layer using more than one material is obtained by doping different compounds at their weight ratio as recorded.

TABLE 1

Part of device structures in device examples and device comparative examples

| | | | | | | |
|---|---|---|---|---|---|---|
| Device ID | HIL | HTL | EBL | EML | HBL | ETL |
| Example 1 | Compound HT: Compound HI (97:3) (100 Å) | Compound HT (400 Å) | Compound EB (50 Å) | Compound A-1:Compound 117:Compound RD (29.4:68.6:2) (400 Å) | Compound HB (50 Å) | Compound ET:Liq (40:60) (350 Å) |
| Example 2 | Compound HT: Compound HI (97:3) (100 Å) | Compound HT (400 Å) | Compound EB (50 Å) | Compound A-168:Compound 117:Compound RD (29.4:68.6:2) (400 Å) | Compound HB (50 Å) | Compound ET:Liq (40:60) (350 Å) |
| Example 3 | Compound HT: Compound HI (97:3) (100 Å) | Compound HT (400 Å) | Compound EB (50 Å) | Compound A-1:Compound 71:Compound RD (29.4:68.6:2) (400 Å) | Compound HB (50 Å) | Compound ET:Liq (40:60) (350 Å) |
| Example 4 | Compound HT: Compound HI (97:3) (100 Å) | Compound HT (400 Å) | Compound EB (50 Å) | Compound A-168:Compound 71:Compound RD (29.4:68.6:2) (400 Å) | Compound HB (50 Å) | Compound ET:Liq (40:60) (350 Å) |
| Example 5 | Compound HT: Compound HI (97:3) (100 Å) | Compound HT (400 Å) | Compound EB (50 Å) | Compound A-143:Compound 71:Compound RD (29.4:68.6:2) (400 Å) | Compound HB (50 Å) | Compound ET:Liq (40:60) (350 Å) |
| Example 6 | Compound HT: Compound HI (97:3) (100 Å) | Compound HT (400 Å) | Compound EB (50 Å) | Compound A-158:Compound 117:Compound RD (29.4:68.6:2) (400 Å) | Compound HB (50 Å) | Compound ET:Liq (40:60) (350 Å) |
| Example 7 | Compound HT: Compound HI (97:3) (100 Å) | Compound HT (400 Å) | Compound EB (50 Å) | Compound A-142:Compound 117:Compound RD (29.4:68.6:2) (400 Å) | Compound HB (50 Å) | Compound ET:Liq (40:60) (350 Å) |
| Example 8 | Compound HT: Compound HI (97:3) (100 Å) | Compound HT (400 Å) | Compound EB (50 Å) | Compound A-148:Compound 71:Compound RD (29.4:68.6:2) (400 Å) | Compound HB (50 Å) | Compound ET:Liq (40:60) (350 Å) |
| Comparative Example 1 | Compound HT: Compound HI (97:3) (100 Å) | Compound HT (400 Å) | Compound EB (50 Å) | Compound 117:Compound RD (98:2) (400 Å) | Compound HB (50 Å) | Compound ET:Liq (40:60) (350 Å) |
| Comparative Example 2 | Compound HT: Compound HI (97:3) (100 Å) | Compound HT (400 Å) | Compound EB (50 Å) | Compound A-168:Compound RD (98:2) (400 Å) | Compound HB (50 Å) | Compound ET:Liq (40:60) (350 Å) |
| Comparative Example 3 | Compound HT: Compound HI (97:3) (100 Å) | Compound HT (400 Å) | Compound EB (50 Å) | Compound A-1 :Compound RD (98:2) (400 Å) | Compound HB (50 Å) | Compound ET:Liq (40:60) (350 Å) |
| Comparative Example 4 | Compound HT: Compound HI (97:3) (100 Å) | Compound HT (400 Å) | Compound EB (50 Å) | Compound A-168:Compound C:Compound RD (29.4:68.6:2) (400 Å) | Compound HB (50 Å) | Compound ET:Liq (40:60) (350 Å) |

The structures of the materials used in the devices are shown as follows:

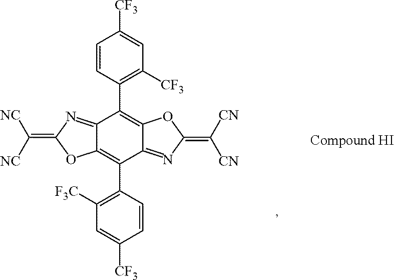

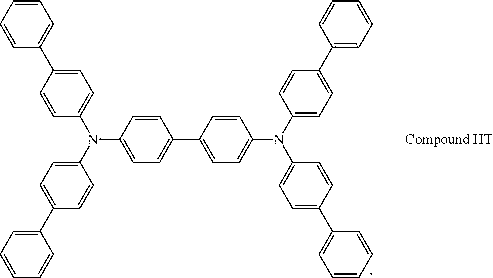

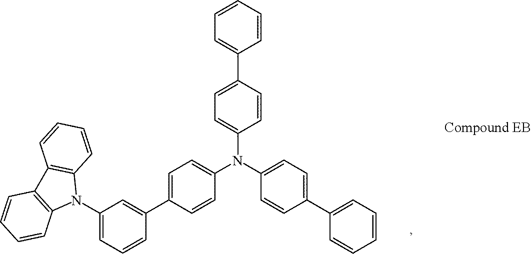

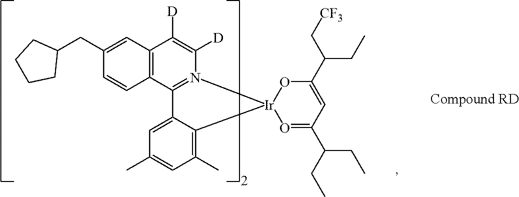

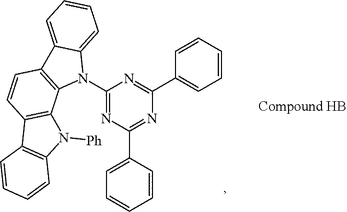

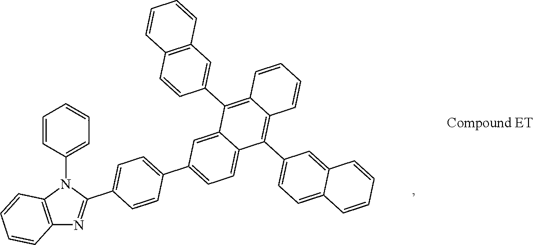

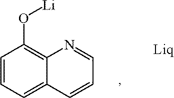

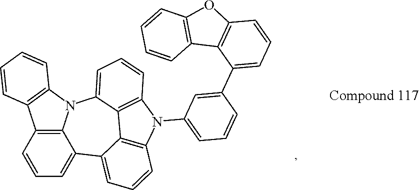

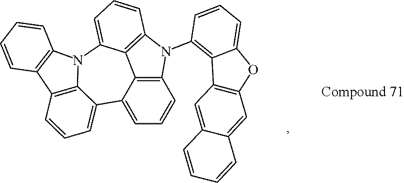

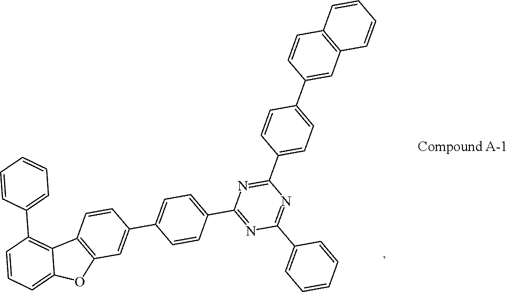

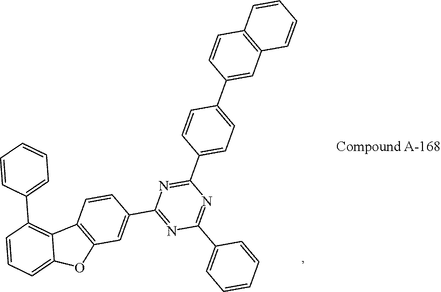

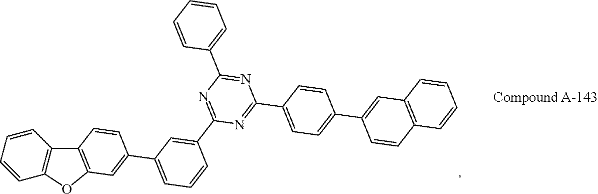

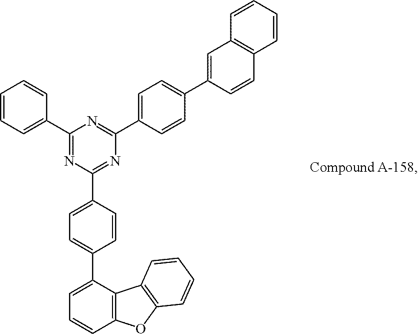 [SMILES: c1ccc(-c2nc(-c3ccc(-c4ccc5ccccc5c4)cc3)nc(-c3ccc(-c4cccc5oc6ccccc6c45)cc3)n2)cc1]

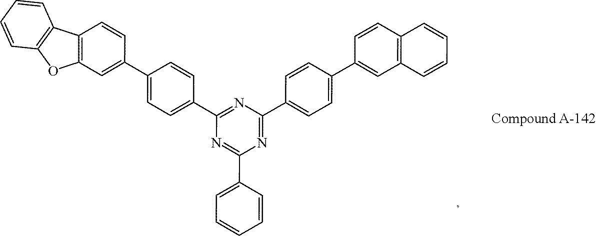

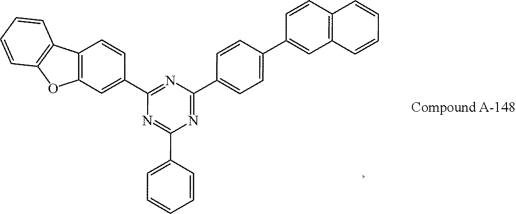

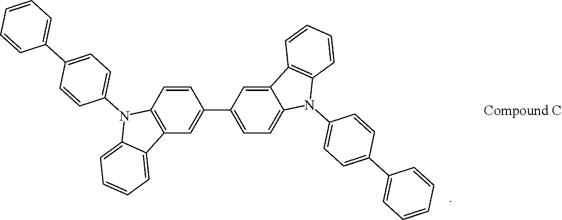

The maximum emission wavelength (λₘₐₓ), current efficiency (CE), external quantum efficiency (EQE) and voltage of the device examples and device comparative examples were measured at a constant current of 15 mA/cm². The lifetime (LT97) of the device examples and device comparative examples was measured at a constant current of 80 mA/cm², where the device lifetime (LT97) refers to the time for the device to decay to 97% of its initial brightness. The data was recorded and shown in Table 2.

TABLE 2

Device data

| Device ID | λₘₐₓ (nm) | Voltage [V] | CE [cd/A] | EQE [%] | LT97 [h] |
|---|---|---|---|---|---|
| Example 1 | 619 | 3.69 | 25.30 | 25.27 | 151 |
| Example 2 | 619 | 3.92 | 25.75 | 25.68 | 168 |
| Example 3 | 619 | 4.16 | 25.39 | 25.91 | 143 |
| Example 4 | 619 | 4.30 | 25.35 | 25.89 | 162 |
| Example 5 | 620 | 4.61 | 25.74 | 25.67 | 138 |
| Example 6 | 620 | 3.84 | 25.36 | 25.18 | 123 |
| Example 7 | 620 | 3.95 | 25.62 | 25.65 | 150 |
| Example 8 | 619 | 4.45 | 25.82 | 26.01 | 134 |
| Comparative Example 1 | 618 | 4.23 | 16.50 | 16.36 | 20 |
| Comparative Example 2 | 618 | 4.62 | 15.98 | 15.54 | 0.7 |
| Comparative Example 3 | 618 | 4.61 | 15.98 | 16.36 | 0.7 |
| Comparative Example 4 | 618 | 4.26 | 22.80 | 23.45 | 53 |

### Discussion

As can be seen from the data in Table 2, Device Examples 1 to 8 using the combination of the first compound and the second compound selected in the present disclosure in the light-emitting layer have substantially the same maximum emission wavelength as Device Comparative Examples 1 to 3 using the first compound or the second compound alone.

In terms of voltage, Device Example 1 can provide a significantly reduced operating voltage, and compared to the current efficiency and external quantum efficiency of Device Comparative Example 1, both the current efficiency and the external quantum efficiency of Device Example 1 are significantly improved, which are improved by 53.3% and 54.5%, respectively. Compared to the current efficiency and external quantum efficiency of Device Comparative Example 3, both the current efficiency and the external quantum efficiency of Device Example 1 are significantly improved, which are improved by 58.3% and 54.5%, respectively. In terms of lifetime, the LT97 of Example 1 is even improved by 6.5 times and 216 times compared to those of Comparative Examples 1 and 3.

The data comparison of Device Examples 2, 3 and 4 and Device Comparative Examples 1, 2 and 3 indicates that the device examples using the combination of the first compound and the second compound selected in the present disclosure have more advantages than the device comparative examples using the first compound or the second compound alone, which can significantly improve the device efficiency and the lifetime so that the device achieves more excellent performance.

Compared to Device Comparative Example 4 using Compound C widely used in the industry as a co-host, the current efficiency, external quantum efficiency and lifetime of the device of Device Example 2 can be significantly improved while the voltage is significantly reduced, especially the lifetime, which is significantly improved by as much as two times.

Although Device Example 4 has substantially the same maximum emission wavelength and voltage as Device Comparative Example 4, the current efficiency and external quantum efficiency of Device Example 4 are, compared to those of Device Comparative Example 4, improved by 11.2% and 10.4%, respectively, and the lifetime is even improved by 2.1 times.

Device Examples 5 to 8 use different combinations of the first compound and the second compound in the light-emitting layer and still exhibit excellent device efficiency and low voltage, which again proves the superiority of the combination of the first compound and the second compound selected in the present disclosure.

The above data indicates that the device using the combination of the first compound and the second compound selected in the present disclosure can enable holes and electrons in the device to achieve a more balanced state, thereby exhibiting higher current efficiency, higher external quantum efficiency and a longer lifetime in the device.

From the above results, it can be seen that the combination of the first compound and the second compound selected in the present disclosure can significantly improve the efficiency and lifetime of the electroluminescent device, reduce the device voltage to some extent and has a broad commercial development prospect and application value.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An electroluminescent device, comprising:
an anode,
a cathode and
an organic layer disposed between the anode and the cathode, wherein the organic layer comprises at least a first compound and a second compound;
wherein the first compound has a structure of H-L-Ar, wherein H has a structure represented by Formula 1: 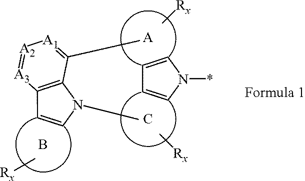
wherein in Formula 1,
A₁, A₂ and A₃ are, at each occurrence identically or differently, selected from N or CR, and the ring A, the ring B and the ring C are, at each occurrence identically or differently, selected from a carbocyclic ring having 5 to 18 carbon atoms or a heterocyclic ring having 3 to 18 carbon atoms;
Rₓ represents, at each occurrence identically or differently, mono-substitution, multiple substitutions or non-substitution;
Ar is selected from substituted or unsubstituted aryl having 6 to 30 carbon atoms, substituted or unsubstituted heteroaryl having 3 to 30 carbon atoms, substituted or unsubstituted arylamino having 6 to 30 carbon atoms or a combination thereof;
L is selected from a single bond, substituted or unsubstituted arylene having 6 to 30 carbon atoms, substituted or unsubstituted heteroarylene having 3 to 30 carbon atoms or a combination thereof;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ can be optionally joined to form a ring; and
“*” represents a position where H is joined to L;
wherein the second compound has a structure represented by Formula 2: 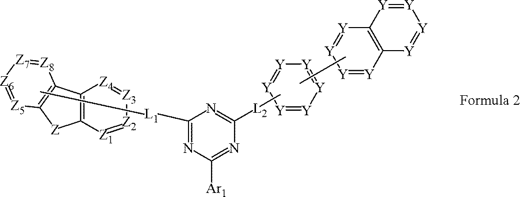
wherein in Formula 2,
Z is selected from O, S or Se;
Z₁ to Z₈ are selected from C, N or CR_{z}, and one of Z₁ to Z₈ is selected from C and joined to L₁;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

2. The electroluminescent device according to claim 1, wherein the ring A, the ring B and the ring C are, at each occurrence identically or differently, selected from a five-membered carbocyclic ring, an aromatic ring having 6 to 18 carbon atoms or a heteroaromatic ring having 3 to 18 carbon atoms; and
preferably, the ring A, the ring B and the ring C are, at each occurrence identically or differently, selected from a five-membered carbocyclic ring, a benzene ring, a five-membered heteroaromatic ring or a six-membered heteroaromatic ring.

3. The electroluminescent device according to claim 1, wherein H has a structure represented by Formula 1A: 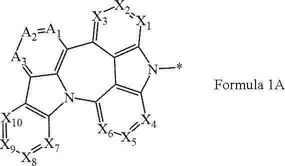
wherein A₁ to A₃ are, at each occurrence identically or differently, selected from N or CR, and X₁ to X₁₀ are, at each occurrence identically or differently, selected from N or CRₓ;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ can be optionally joined to form a ring; and
preferably, R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, an isocyano group, a hydroxyl group, a sulfanyl group and combinations thereof.

4. The electroluminescent device according to claim 1, wherein at least one of R and Rₓ is selected from deuterium, halogen, a cyano group, a hydroxyl group, a sulfanyl group, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms or a combination thereof;
adjacent substituents R and Rₓ can be optionally joined to form a ring; and
preferably, at least one of R and Rₓ is selected from deuterium, fluorine, a cyano group, a hydroxyl group, a sulfanyl group, methyl, trideuteromethyl, vinyl, phenyl, biphenyl, naphthyl, 4-cyanophenyl, dibenzofuranyl, dibenzothienyl, triphenylenyl, carbazolyl, 9-phenylcarbazolyl, 9,9-dimethylfluorenyl, pyridyl, phenylpyridyl or a combination thereof.

5. The electroluminescent device according to claim 1, wherein H is selected from the group consisting of the following structures: 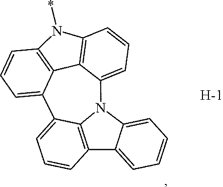 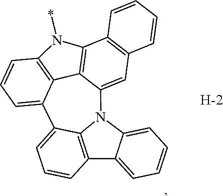 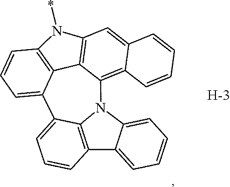 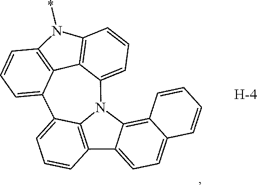 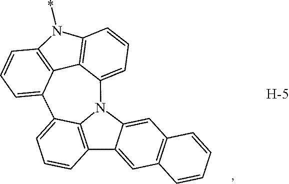 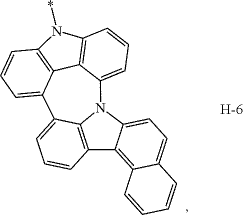 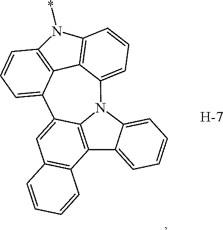 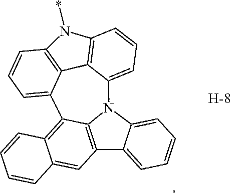 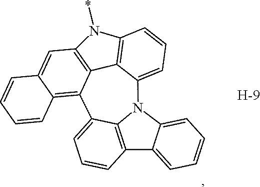 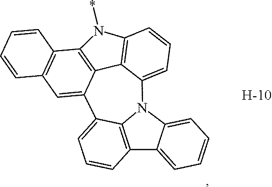 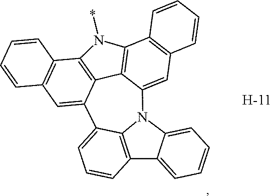 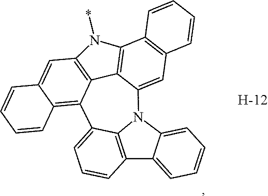 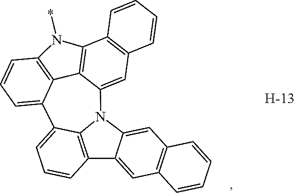 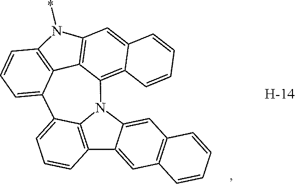 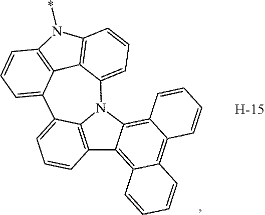 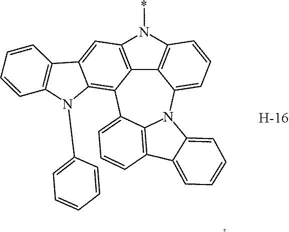 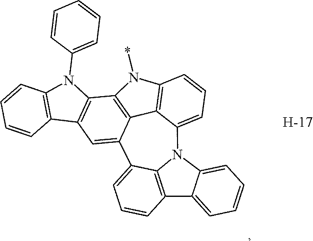 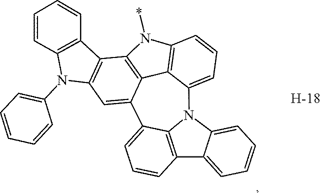 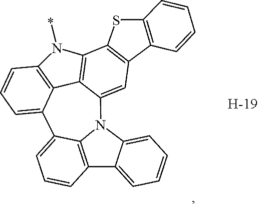 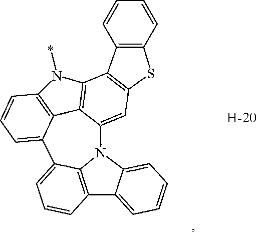 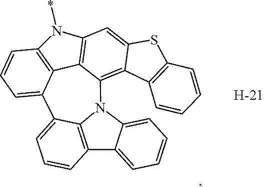 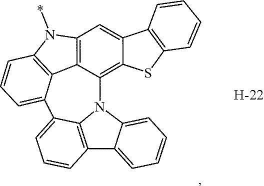 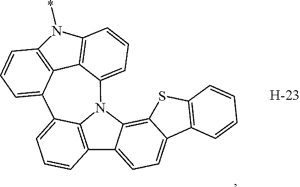 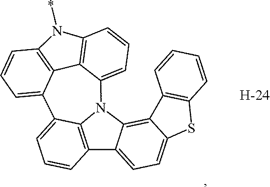 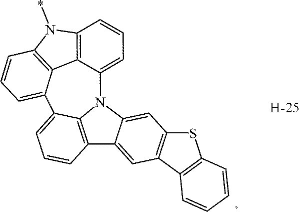 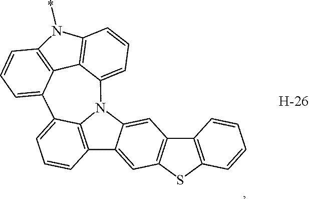 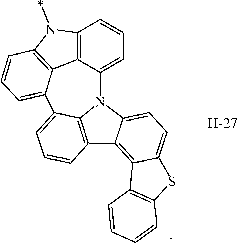 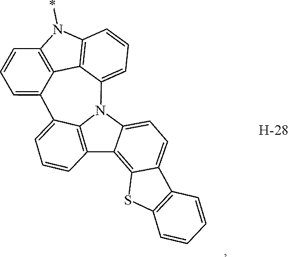 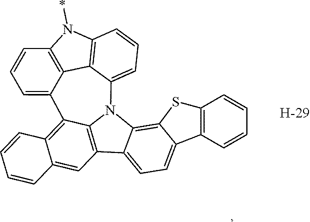 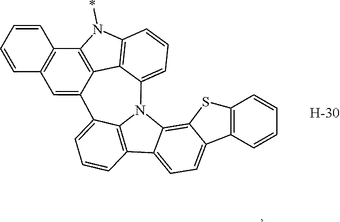 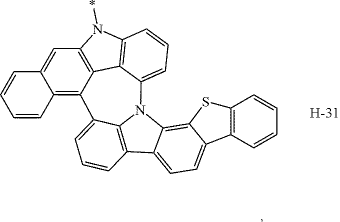 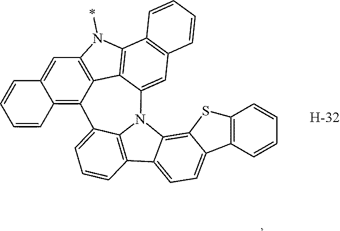 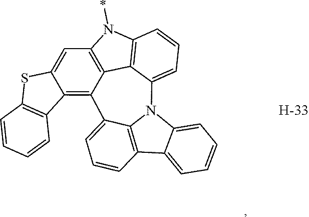 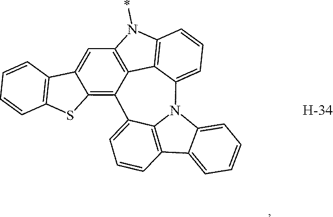 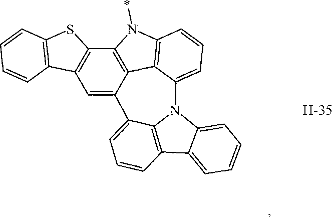 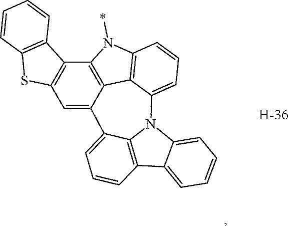 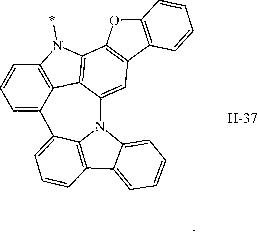 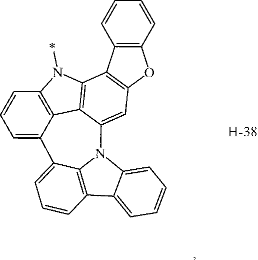 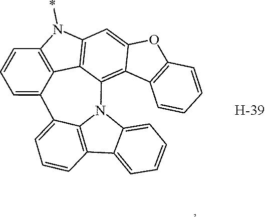 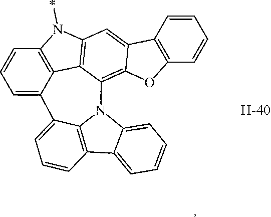 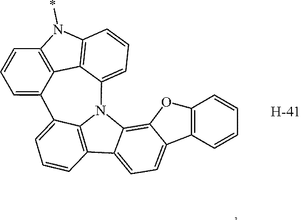 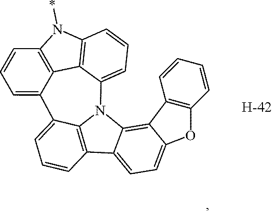 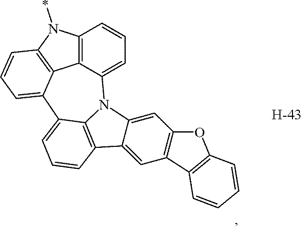 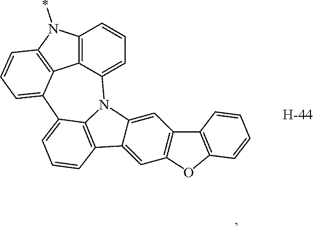 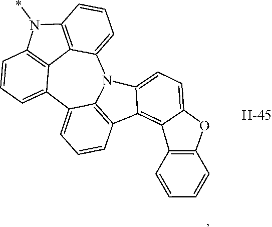 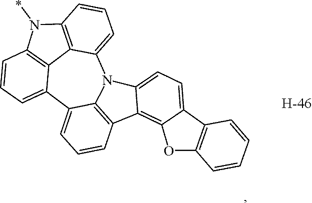 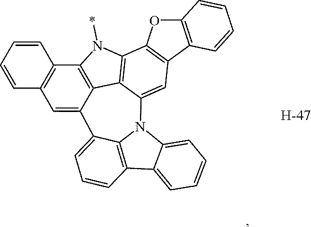 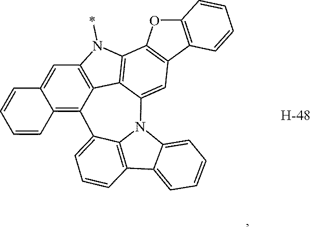 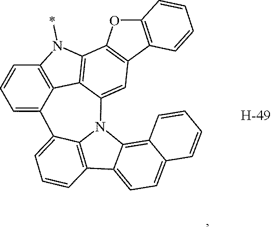 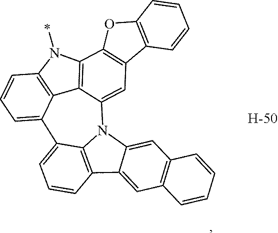 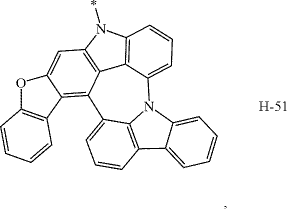 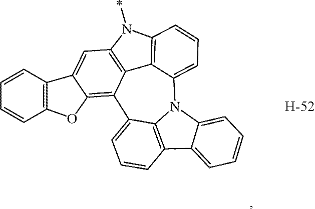 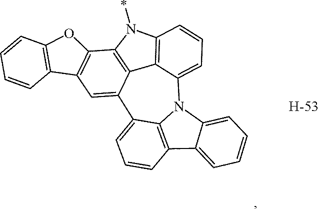 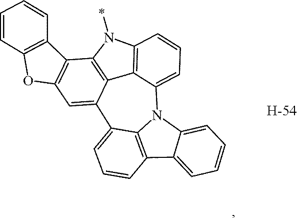 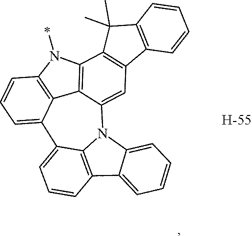 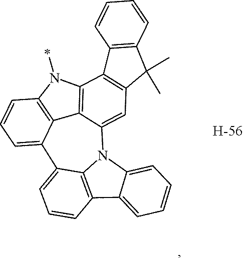 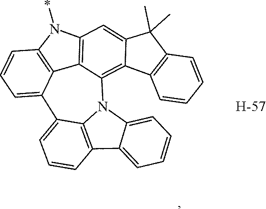 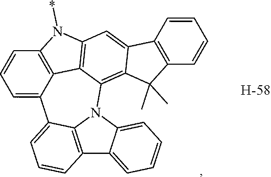 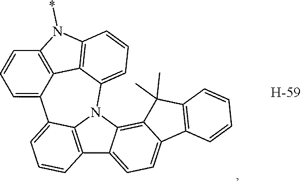 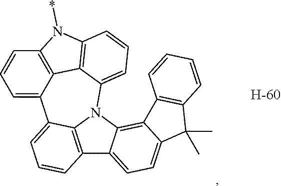 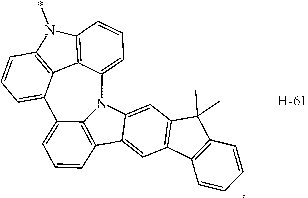 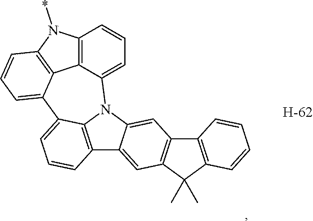 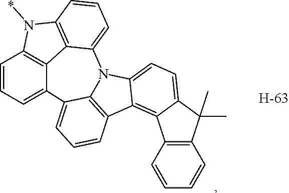 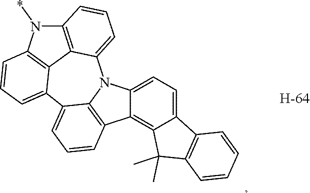 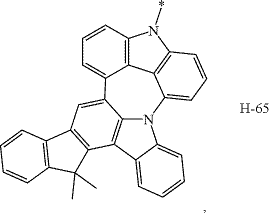 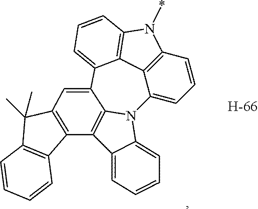 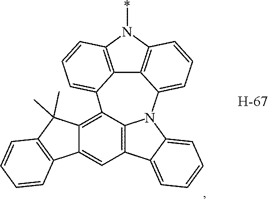 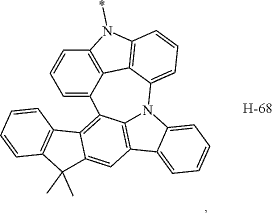 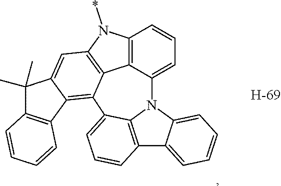 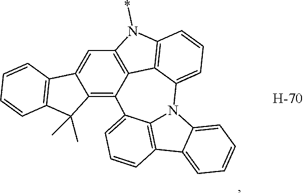 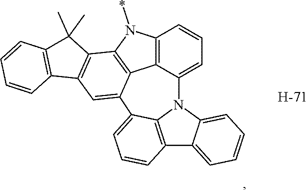 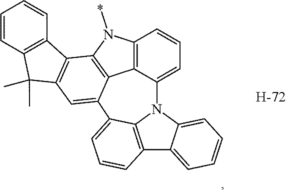 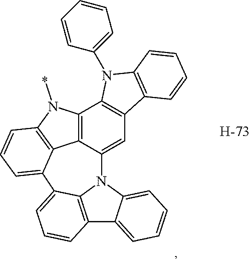 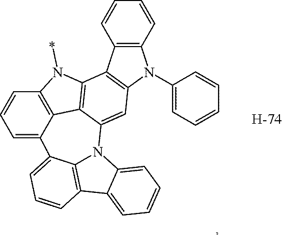 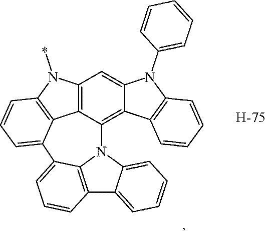 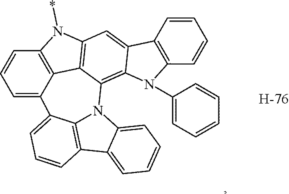 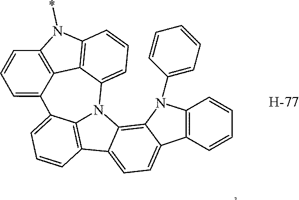 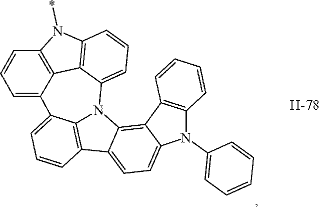 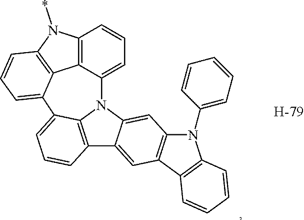 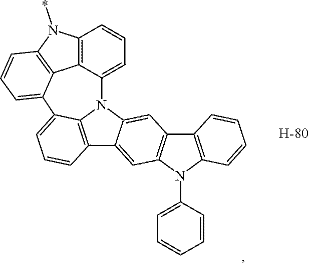 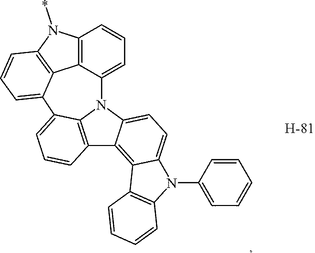 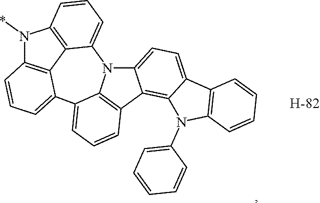 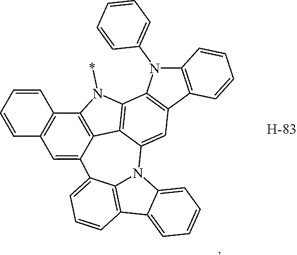 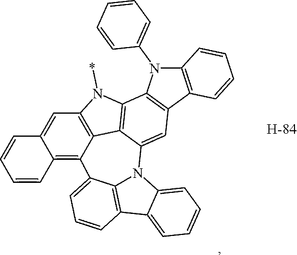 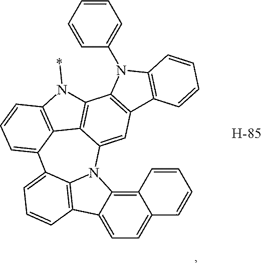 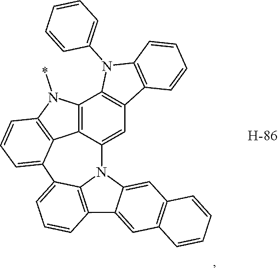 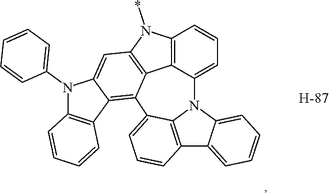 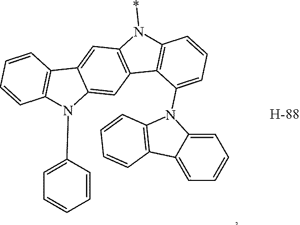 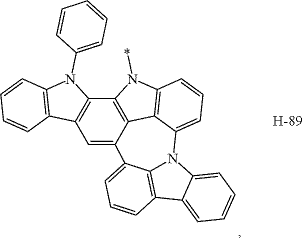 [SMILES: *n1c2cccc3c2c2c(cc4c5ccccc5n(-c5ccccc5)c4c21)c1cccc2c4ccccc4n3c12 ; ","] 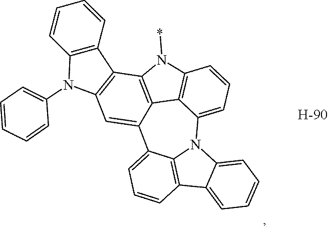 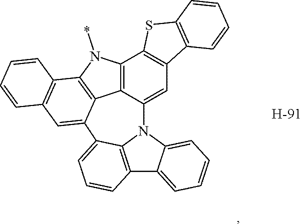 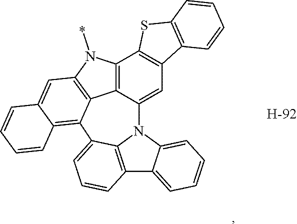 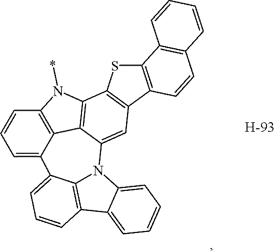 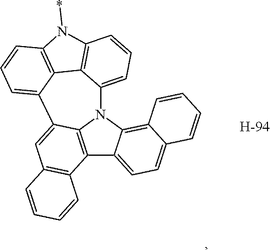 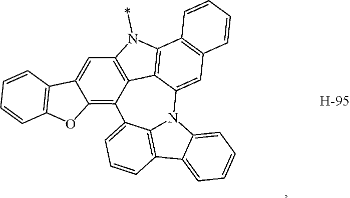 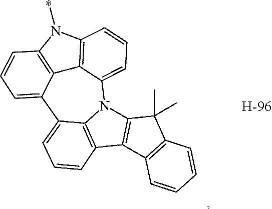 [SMILES: *n1c2cccc3c4cccc5c6c(n(c7cccc1c7c32)c54)C(C)(C)c1ccccc1-6 ; ","] 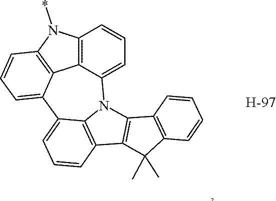 [SMILES: *n1c2cccc3c4cccc5c6c(n(c7cccc1c7c32)c54)-c1ccccc1C6(C)C ; ","] 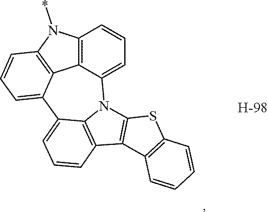 [SMILES: *n1c2cccc3c4cccc5c6c7ccccc7sc6n(c6cccc1c6c32)c45 ; ","] 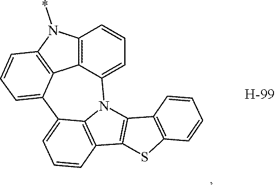 [SMILES: *n1c2cccc3c4cccc5c6sc7ccccc7c6n(c6cccc1c6c32)c45 ; ","] 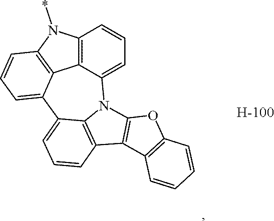 [SMILES: *n1c2cccc3c4cccc5c6c7ccccc7oc6n(c6cccc1c6c32)c45 ; ","] 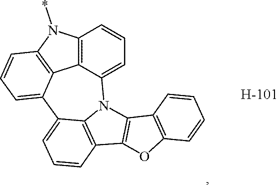 [SMILES: *n1c2cccc3c4cccc5c6oc7ccccc7c6n(c6cccc1c6c32)c45 ; ","] 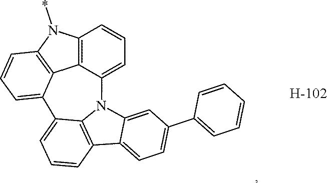 [SMILES: *n1c2cccc3c4cccc5c6ccc(-c7ccccc7)cc6n(c6cccc1c6c32)c45 ; ","] 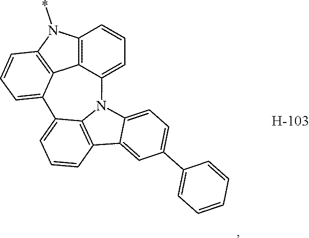 [SMILES: *n1c2cccc3c4cccc5c6cc(-c7ccccc7)ccc6n(c6cccc1c6c32)c45 ; ","] 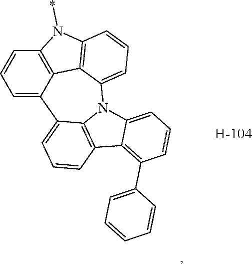 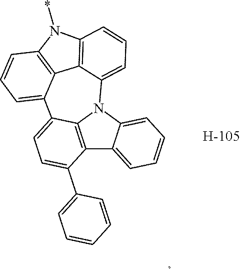 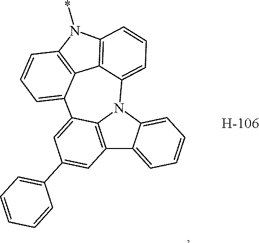 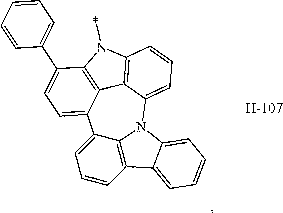 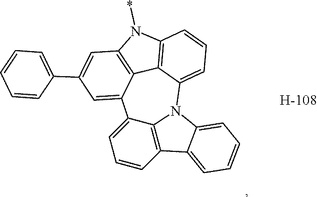 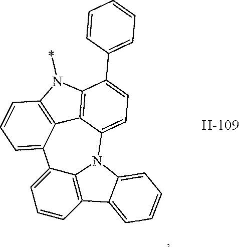 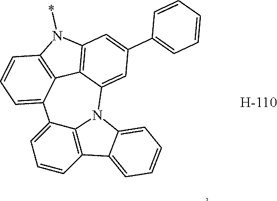 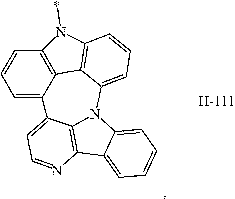 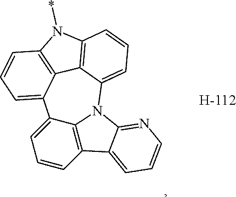 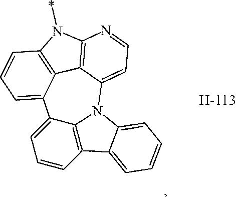 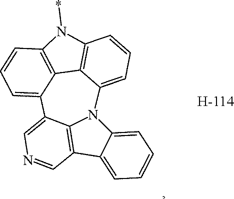 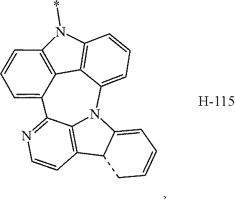 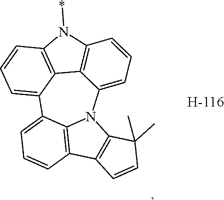 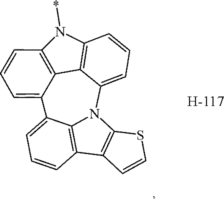 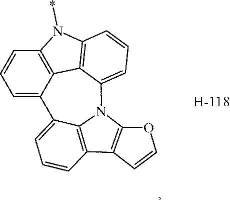 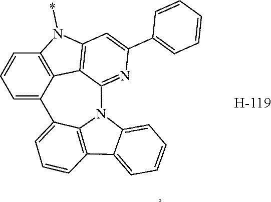 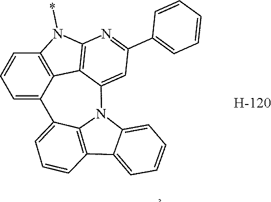 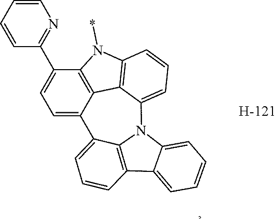 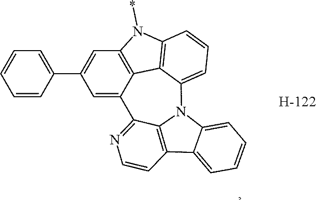 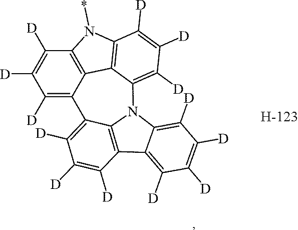 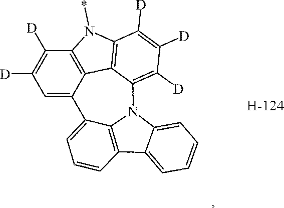 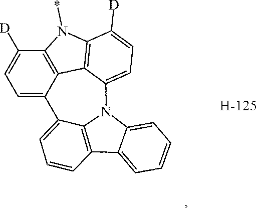 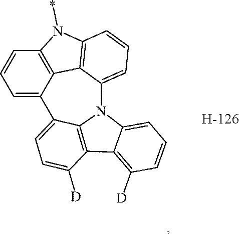 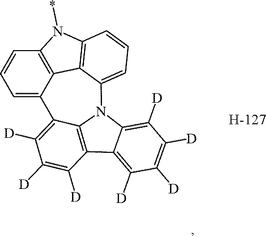 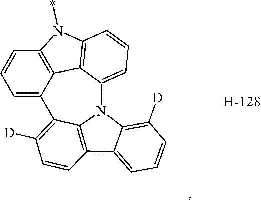 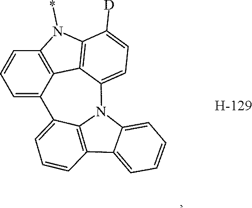 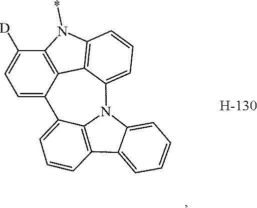 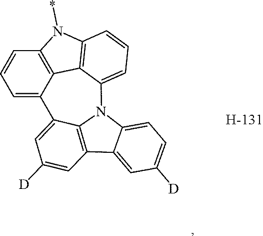 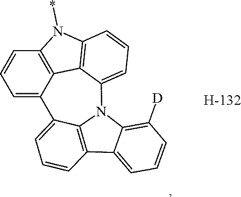 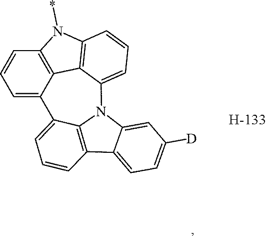 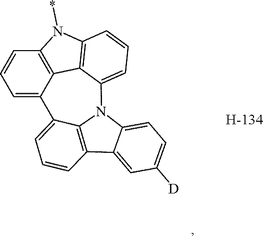 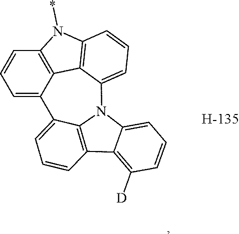 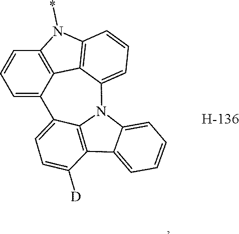 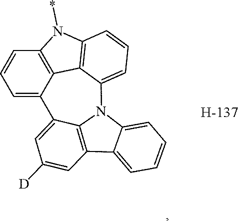 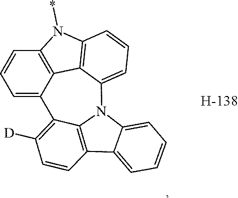 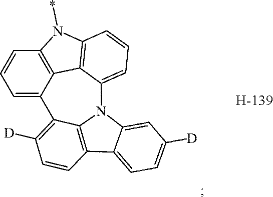
wherein “*” represents a position where H is joined to L; and
optionally, hydrogens in the above structures can be partially or fully substituted with deuterium.

6. The electroluminescent device according to claim 1, wherein Ar is selected from a structure represented by any one of the group consisting of Formula 1-a to Formula 1-d: 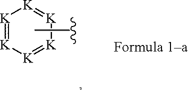 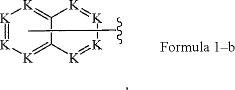 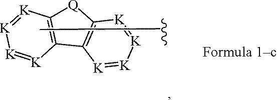 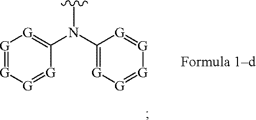
wherein K is, at each occurrence identically or differently, selected from C, N or CR_{K};
G is, at each occurrence identically or differently, selected from N or CR_{G};
Q is selected from NR_{q}, O, S, SiR_{q}R_{q}, CR_{q}R_{q}, BR_{q} or PR_{q}; preferably, Q is selected from NR_{q}, O, S or CR_{q}R_{q};
R_{K}, R_{q} and R_{G} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{q}, R_{K}, R_{G} can be optionally joined to form a ring; and 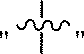
represents a position where Ar is joined to L.

7. The electroluminescent device according to claim 6, wherein R_{q}, R_{K} and R_{G} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, a cyano group and combinations thereof;
adjacent substituents R_{q}, R_{K}, R_{G} can be optionally joined to form a ring;
preferably, R_{q}, R_{K} and R_{G} are, at each occurrence identically or differently, selected from the group consisting of: hydrogen, deuterium, fluorine, a cyano group, methyl, ethyl, propyl, isopropyl, phenyl, biphenyl, naphthyl, vinyl, 9-phenylcarbazolyl, naphthylphenyl, phenylpyridyl, dibenzofuranyl, dibenzothienyl, 9,9-dimethylfluorenyl, carbazolyl, pyridyl, pyrimidinyl, 4-cyanophenyl, triphenylenyl, terphenyl and combinations thereof; and
adjacent substituents R_{q}, R_{K}, R_{G} can be optionally joined to form a ring.

8. The electroluminescent device according to claim 1, wherein Ar is, at each occurrence identically or differently, selected from substituted or unsubstituted phenyl, substituted or unsubstituted naphthyl, substituted or unsubstituted triazinyl, substituted or unsubstituted quinazolinyl, substituted or unsubstituted benzoquinazolinyl, substituted or unsubstituted benzoquinoxalinyl, substituted or unsubstituted quinoxalinyl, substituted or unsubstituted dibenzofuranyl, substituted or unsubstituted benzonaphthofuranyl, substituted or unsubstituted dibenzothienyl, substituted or unsubstituted benzonaphthothiophenyl, substituted or unsubstituted azadibenzofuranyl, substituted or unsubstituted azadibenzothienyl, substituted or unsubstituted carbazolyl, substituted or unsubstituted fluorenyl, substituted or unsubstituted spirobifluorenyl, substituted or unsubstituted diphenylamino or a combination thereof; and
preferably, Ar is, at each occurrence identically or differently, selected from substituted or unsubstituted phenyl, substituted or unsubstituted naphthyl, substituted or unsubstituted dibenzofuranyl, substituted or unsubstituted benzonaphthofuranyl, substituted or unsubstituted dibenzothienyl, substituted or unsubstituted carbazolyl, substituted or unsubstituted fluorenyl, substituted or unsubstituted spirobifluorenyl or a combination thereof.

9. The electroluminescent device according to claim 1, wherein Ar is selected from the group consisting of the following structures: 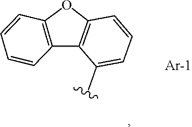 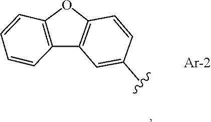 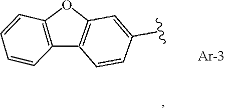 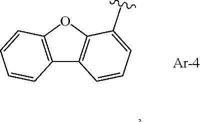 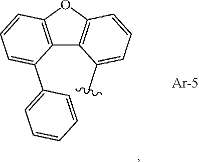 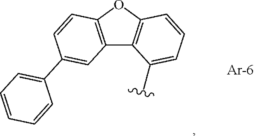 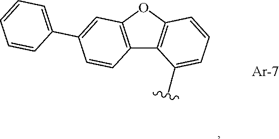 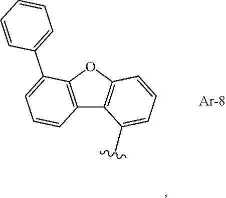 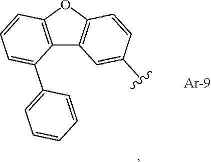 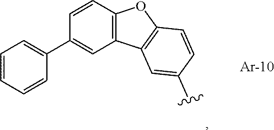 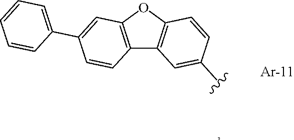 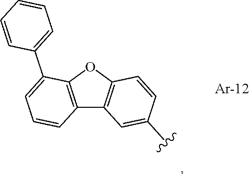 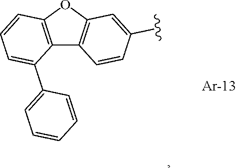 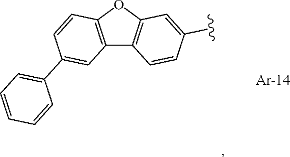 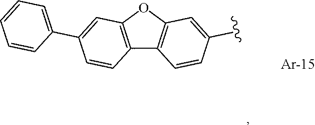 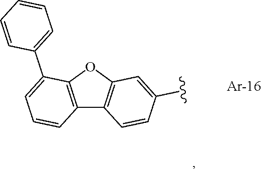 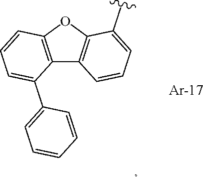 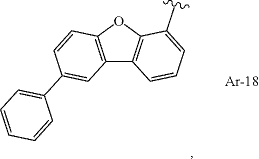 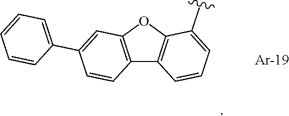 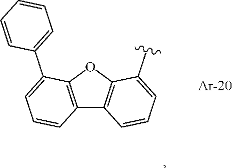 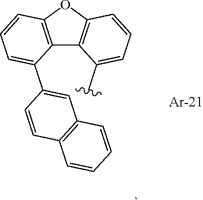 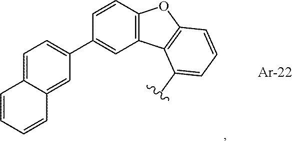 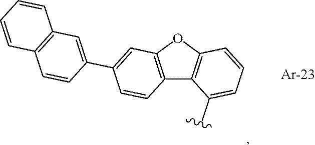 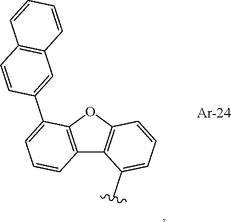 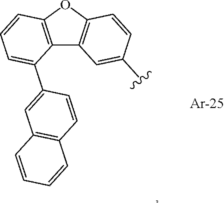 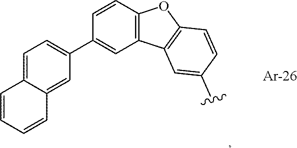 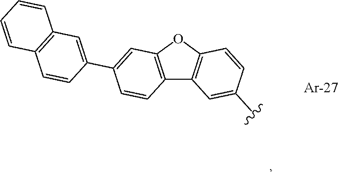 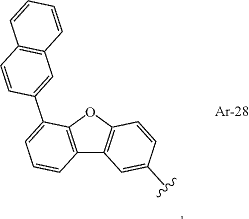 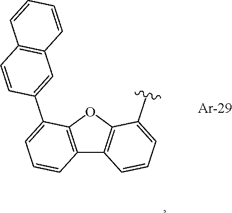 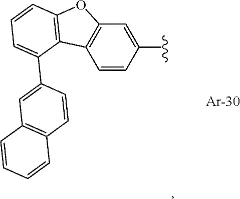 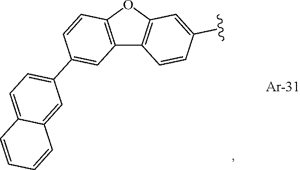 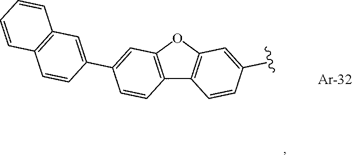 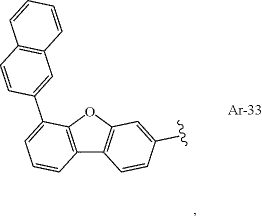 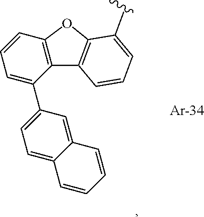 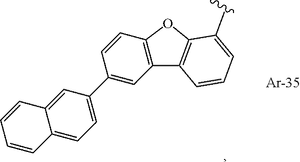 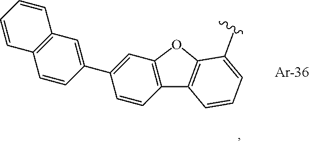 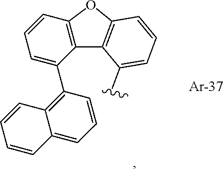 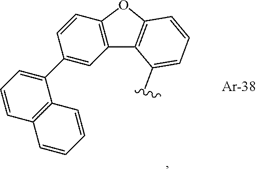 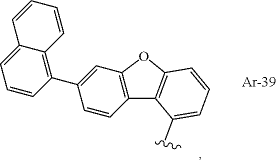 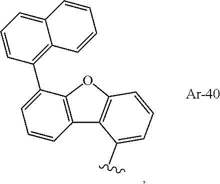 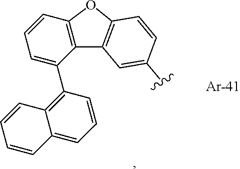 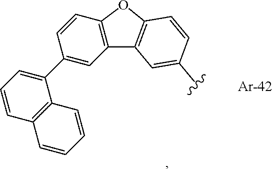 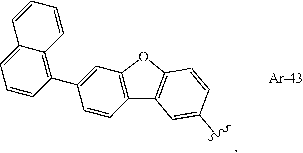 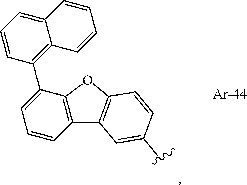 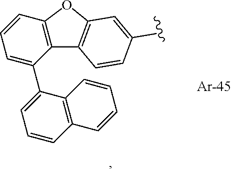 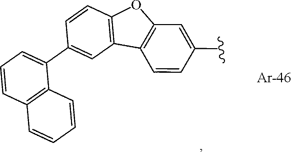 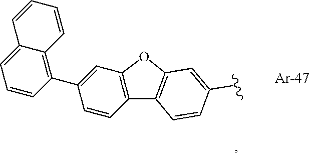 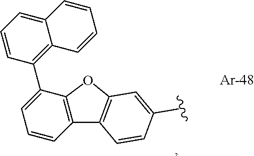 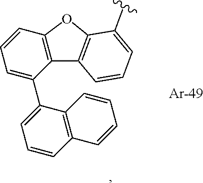 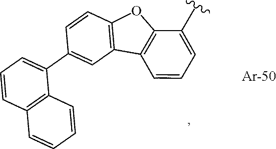 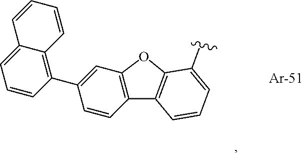 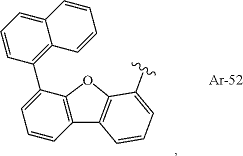 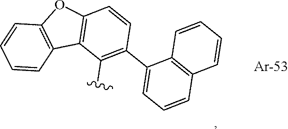 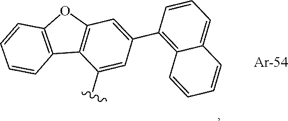 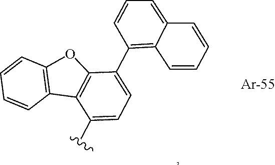 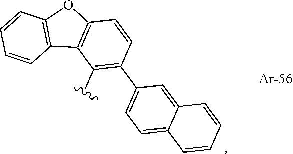 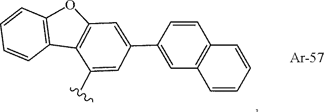 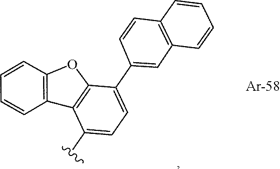 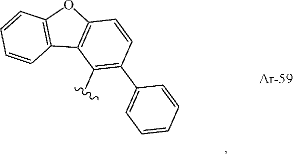 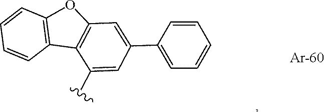 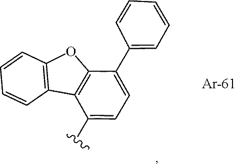 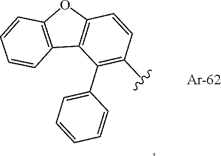 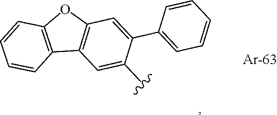 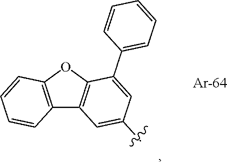 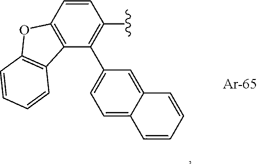 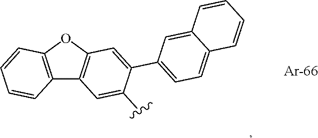 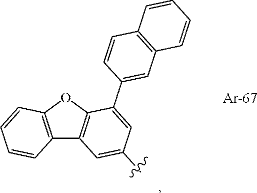 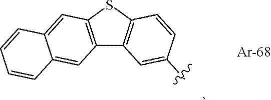 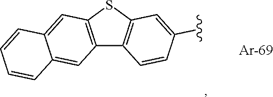 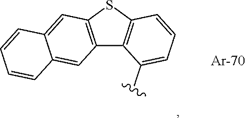 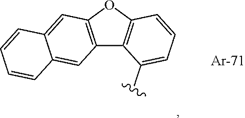 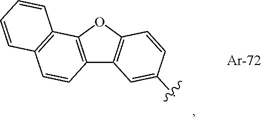 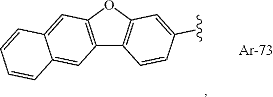 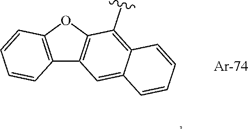 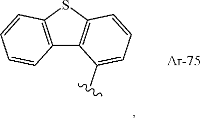 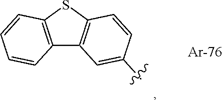 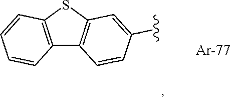 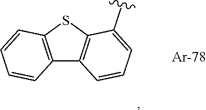 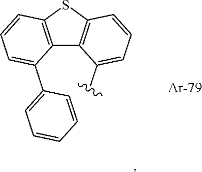 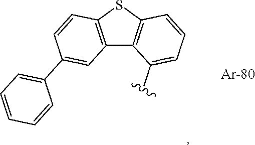 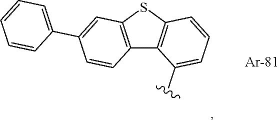 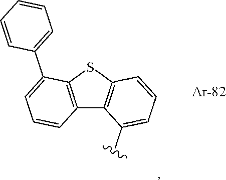 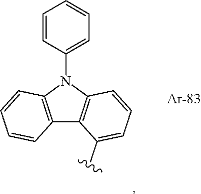 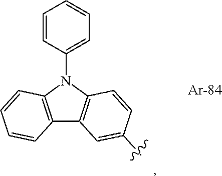 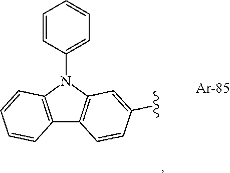 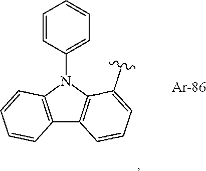 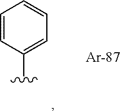 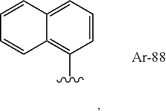 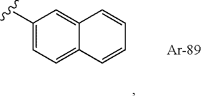 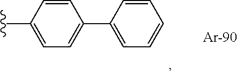 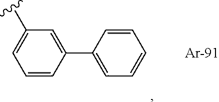 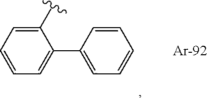 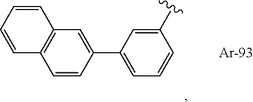 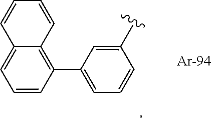 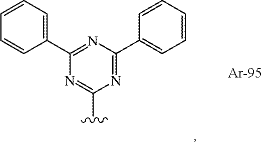 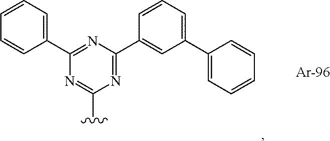 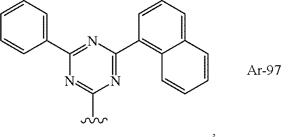 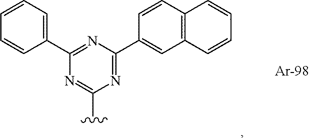 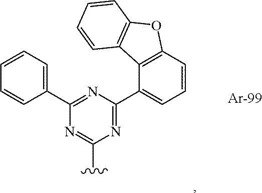 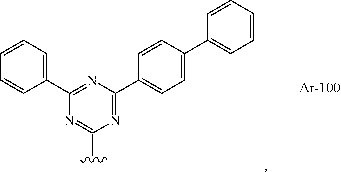 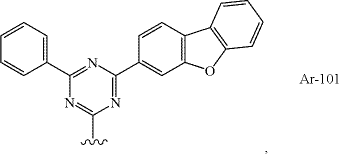 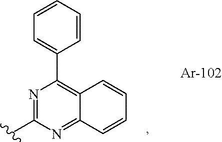 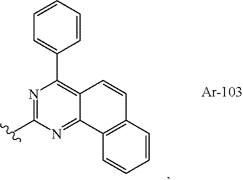 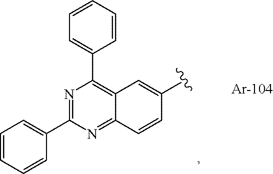 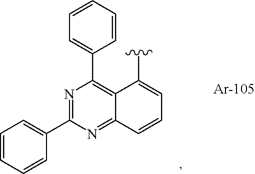 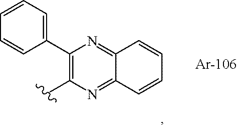 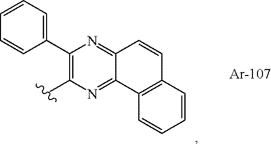 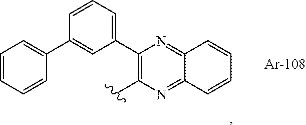 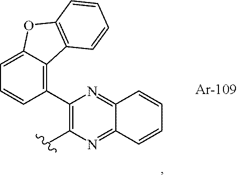 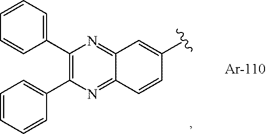 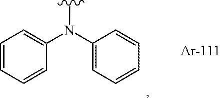 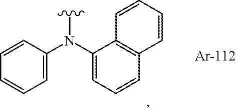 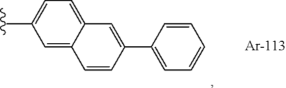 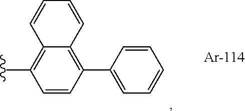 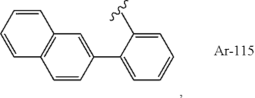 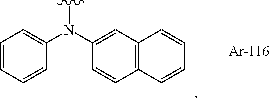 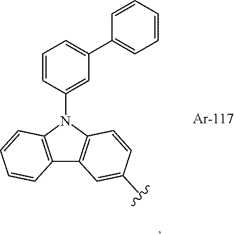 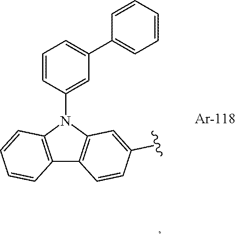 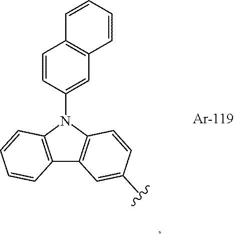 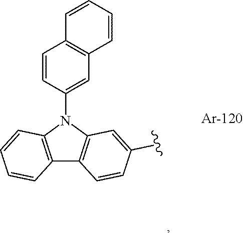 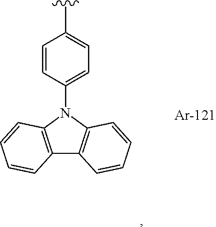 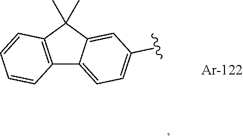 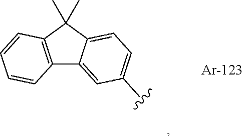 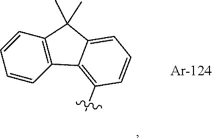 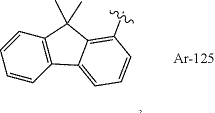 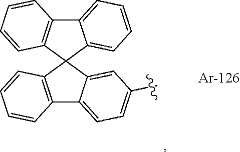 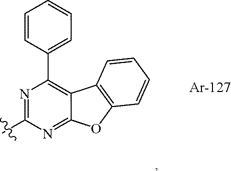 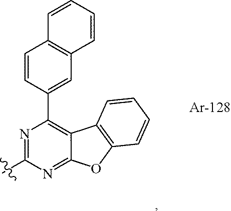 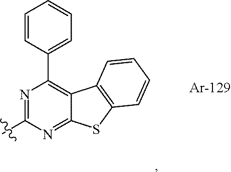 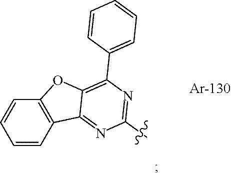
wherein 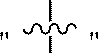
represents a position where Ar is joined to L; and
optionally, hydrogens in the above structures can be partially or fully substituted with deuterium.

10. The electroluminescent device according to claim 1, wherein L is selected from the group consisting of the following structures: 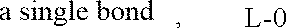 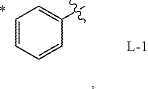 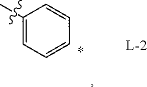 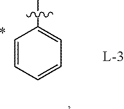 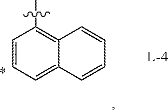 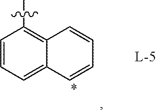 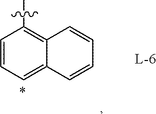 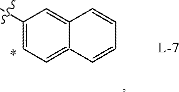 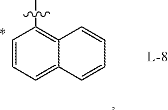 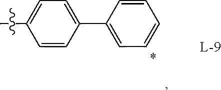 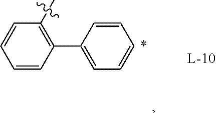 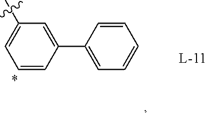 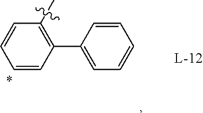 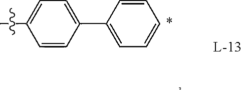 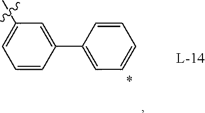 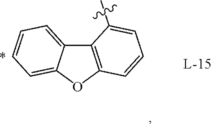 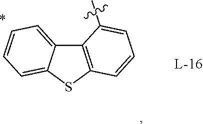 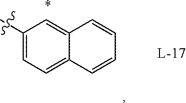 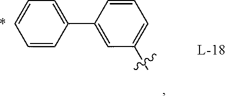 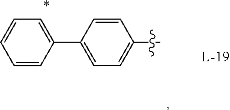 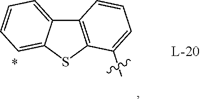 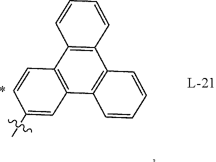 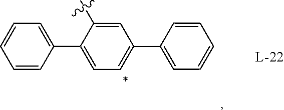 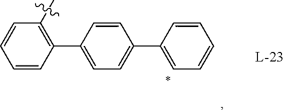 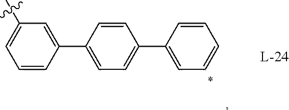 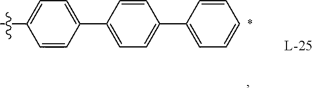 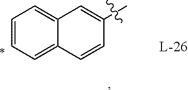 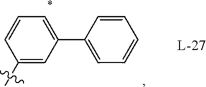 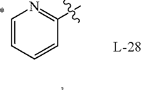 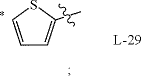
wherein “*” represents a position where L is joined to H, and 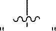
represent a position where L is joined to Ar; and
optionally, hydrogens in the structures of L-1 to L-29 can be partially or fully substituted with deuterium.

11. The electroluminescent device according to claim 1, wherein the first compound has the structure of H-L-Ar, wherein H is selected from any one of the group consisting of H-1 to H-139, L is selected from any one of the group consisting of L-0 to L-29, and Ar is selected from any one of the group consisting of Ar-1 to Ar-130; optionally, hydrogens in the first compound can be partially or fully substituted with deuterium;
wherein preferably, the first compound is selected from the group consisting of Compound 1 to Compound 772, wherein Compound 1 to Compound 772 have the structure of H-L-Ar, wherein H, L and Ar correspond to structures shown in the following table, respectively:

| Compound No. | H | L | Ar | Compound No. | H | L | Ar |
|---|---|---|---|---|---|---|---|
| 1 | H-1 | L-0 | Ar-1 | 387 | H-1 | L-3 | Ar-25 |
| 2 | H-1 | L-0 | Ar-2 | 388 | H-1 | L-3 | Ar-26 |
| 3 | H-1 | L-0 | Ar-3 | 389 | H-1 | L-3 | Ar-27 |
| 4 | H-1 | L-0 | Ar-4 | 390 | H-1 | L-3 | Ar-28 |
| 5 | H-1 | L-0 | Ar-5 | 391 | H-1 | L-3 | Ar-29 |
| 6 | H-1 | L-0 | Ar-6 | 392 | H-1 | L-3 | Ar-30 |
| 7 | H-1 | L-0 | Ar-7 | 393 | H-1 | L-3 | Ar-31 |
| 8 | H-1 | L-0 | Ar-8 | 394 | H-1 | L-3 | Ar-32 |
| 9 | H-1 | L-0 | Ar-9 | 395 | H-1 | L-3 | Ar-33 |
| 10 | H-1 | L-0 | Ar-10 | 396 | H-1 | L-3 | Ar-34 |
| 11 | H-1 | L-0 | Ar-11 | 397 | H-1 | L-3 | Ar-35 |
| 12 | H-1 | L-0 | Ar-12 | 398 | H-1 | L-3 | Ar-36 |
| 13 | H-1 | L-0 | Ar-13 | 399 | H-1 | L-3 | Ar-37 |
| 14 | H-1 | L-0 | Ar-14 | 400 | H-1 | L-3 | Ar-38 |
| 15 | H-1 | L-0 | Ar-15 | 401 | H-1 | L-3 | Ar-39 |
| 16 | H-1 | L-0 | Ar-16 | 402 | H-1 | L-3 | Ar-40 |
| 17 | H-1 | L-0 | Ar-17 | 403 | H-1 | L-3 | Ar-41 |
| 18 | H-1 | L-0 | Ar-18 | 404 | H-1 | L-3 | Ar-42 |
| 19 | H-1 | L-0 | Ar-19 | 405 | H-1 | L-3 | Ar-43 |
| 20 | H-1 | L-0 | Ar-20 | 406 | H-1 | L-3 | Ar-44 |
| 21 | H-1 | L-0 | Ar-21 | 407 | H-1 | L-3 | Ar-45 |
| 22 | H-1 | L-0 | Ar-22 | 408 | H-1 | L-3 | Ar-46 |
| 23 | H-1 | L-0 | Ar-23 | 409 | H-1 | L-3 | Ar-47 |
| 24 | H-1 | L-0 | Ar-24 | 410 | H-1 | L-3 | Ar-48 |
| 25 | H-1 | L-0 | Ar-25 | 411 | H-1 | L-3 | Ar-49 |
| 26 | H-1 | L-0 | Ar-26 | 412 | H-1 | L-3 | Ar-50 |
| 27 | H-1 | L-0 | Ar-27 | 413 | H-1 | L-3 | Ar-51 |
| 28 | H-1 | L-0 | Ar-28 | 414 | H-1 | L-3 | Ar-52 |
| 29 | H-1 | L-0 | Ar-29 | 415 | H-1 | L-3 | Ar-53 |
| 30 | H-1 | L-0 | Ar-30 | 416 | H-1 | L-3 | Ar-54 |
| 31 | H-1 | L-0 | Ar-31 | 417 | H-1 | L-3 | Ar-55 |
| 32 | H-1 | L-0 | Ar-32 | 418 | H-1 | L-3 | Ar-56 |
| 33 | H-1 | L-0 | Ar-33 | 419 | H-1 | L-3 | Ar-57 |
| 34 | H-1 | L-0 | Ar-34 | 420 | H-1 | L-3 | Ar-58 |
| 35 | H-1 | L-0 | Ar-35 | 421 | H-1 | L-3 | Ar-59 |
| 36 | H-1 | L-0 | Ar-36 | 422 | H-1 | L-3 | Ar-60 |
| 37 | H-1 | L-0 | Ar-37 | 423 | H-1 | L-3 | Ar-61 |
| 38 | H-1 | L-0 | Ar-38 | 424 | H-1 | L-3 | Ar-62 |
| 39 | H-1 | L-0 | Ar-39 | 425 | H-1 | L-3 | Ar-63 |
| 40 | H-1 | L-0 | Ar-40 | 426 | H-1 | L-3 | Ar-64 |
| 41 | H-1 | L-0 | Ar-41 | 427 | H-1 | L-3 | Ar-65 |
| 42 | H-1 | L-0 | Ar-42 | 428 | H-1 | L-3 | Ar-66 |
| 43 | H-1 | L-0 | Ar-43 | 429 | H-1 | L-3 | Ar-67 |
| 44 | H-1 | L-0 | Ar-44 | 430 | H-1 | L-3 | Ar-68 |
| 45 | H-1 | L-0 | Ar-45 | 431 | H-1 | L-3 | Ar-69 |
| 46 | H-1 | L-0 | Ar-46 | 432 | H-1 | L-3 | Ar-70 |
| 47 | H-1 | L-0 | Ar-47 | 433 | H-1 | L-3 | Ar-71 |
| 48 | H-1 | L-0 | Ar-48 | 434 | H-1 | L-3 | Ar-72 |
| 49 | H-1 | L-0 | Ar-49 | 435 | H-1 | L-3 | Ar-73 |
| 50 | H-1 | L-0 | Ar-50 | 436 | H-1 | L-3 | Ar-74 |
| 51 | H-1 | L-0 | Ar-51 | 437 | H-1 | L-3 | Ar-75 |
| 52 | H-1 | L-0 | Ar-52 | 438 | H-1 | L-3 | Ar-76 |
| 53 | H-1 | L-0 | Ar-53 | 439 | H-1 | L-3 | Ar-77 |
| 54 | H-1 | L-0 | Ar-54 | 440 | H-1 | L-3 | Ar-78 |
| 55 | H-1 | L-0 | Ar-55 | 441 | H-1 | L-3 | Ar-79 |
| 56 | H-1 | L-0 | Ar-56 | 442 | H-1 | L-3 | Ar-80 |
| 57 | H-1 | L-0 | Ar-57 | 443 | H-1 | L-3 | Ar-81 |
| 58 | H-1 | L-0 | Ar-58 | 444 | H-1 | L-3 | Ar-82 |
| 59 | H-1 | L-0 | Ar-59 | 445 | H-1 | L-3 | Ar-83 |
| 60 | H-1 | L-0 | Ar-60 | 446 | H-1 | L-3 | Ar-84 |
| 61 | H-1 | L-0 | Ar-61 | 447 | H-1 | L-3 | Ar-85 |
| 62 | H-1 | L-0 | Ar-62 | 448 | H-1 | L-3 | Ar-86 |
| 63 | H-1 | L-0 | Ar-63 | 449 | H-1 | L-3 | Ar-87 |
| 64 | H-1 | L-0 | Ar-64 | 450 | H-1 | L-3 | Ar-88 |
| 65 | H-1 | L-0 | Ar-65 | 451 | H-1 | L-3 | Ar-89 |
| 66 | H-1 | L-0 | Ar-66 | 452 | H-1 | L-3 | Ar-90 |
| 67 | H-1 | L-0 | Ar-67 | 453 | H-1 | L-3 | Ar-91 |
| 68 | H-1 | L-0 | Ar-68 | 454 | H-1 | L-3 | Ar-92 |
| 69 | H-1 | L-0 | Ar-69 | 455 | H-1 | L-3 | Ar-93 |
| 70 | H-1 | L-0 | Ar-70 | 456 | H-1 | L-3 | Ar-94 |
| 71 | H-1 | L-0 | Ar-71 | 457 | H-1 | L-3 | Ar-95 |
| 72 | H-1 | L-0 | Ar-72 | 458 | H-1 | L-3 | Ar-96 |
| 73 | H-1 | L-0 | Ar-73 | 459 | H-1 | L-3 | Ar-97 |
| 74 | H-1 | L-0 | Ar-74 | 460 | H-1 | L-3 | Ar-98 |
| 75 | H-1 | L-0 | Ar-75 | 461 | H-1 | L-3 | Ar-99 |
| 76 | H-1 | L-0 | Ar-76 | 462 | H-1 | L-3 | Ar-100 |
| 77 | H-1 | L-0 | Ar-77 | 463 | H-1 | L-3 | Ar-101 |
| 78 | H-1 | L-0 | Ar-78 | 464 | H-1 | L-3 | Ar-102 |
| 79 | H-1 | L-0 | Ar-79 | 465 | H-1 | L-3 | Ar-103 |
| 80 | H-1 | L-0 | Ar-80 | 466 | H-1 | L-3 | Ar-104 |
| 81 | H-1 | L-0 | Ar-81 | 467 | H-1 | L-3 | Ar-105 |
| 82 | H-1 | L-0 | Ar-82 | 468 | H-1 | L-3 | Ar-106 |
| 83 | H-1 | L-0 | Ar-83 | 469 | H-1 | L-3 | Ar-107 |
| 84 | H-1 | L-0 | Ar-84 | 470 | H-1 | L-3 | Ar-108 |
| 85 | H-1 | L-0 | Ar-85 | 471 | H-1 | L-3 | Ar-109 |
| 86 | H-1 | L-0 | Ar-86 | 472 | H-1 | L-3 | Ar-110 |
| 87 | H-1 | L-0 | Ar-87 | 473 | H-1 | L-3 | Ar-111 |
| 88 | H-1 | L-0 | Ar-88 | 474 | H-1 | L-3 | Ar-112 |
| 89 | H-1 | L-0 | Ar-89 | 475 | H-1 | L-3 | Ar-113 |
| 90 | H-1 | L-0 | Ar-90 | 476 | H-1 | L-3 | Ar-114 |
| 91 | H-1 | L-0 | Ar-91 | 477 | H-1 | L-3 | Ar-115 |
| 92 | H-1 | L-0 | Ar-92 | 478 | H-1 | L-3 | Ar-116 |
| 93 | H-1 | L-0 | Ar-93 | 479 | H-2 | L-3 | Ar-1 |
| 94 | H-1 | L-0 | Ar-94 | 480 | H-3 | L-3 | Ar-1 |
| 95 | H-1 | L-0 | Ar-95 | 481 | H-4 | L-3 | Ar-1 |
| 96 | H-1 | L-0 | Ar-96 | 482 | H-5 | L-3 | Ar-1 |
| 97 | H-1 | L-0 | Ar-97 | 483 | H-6 | L-3 | Ar-1 |
| 98 | H-1 | L-0 | Ar-98 | 484 | H-7 | L-3 | Ar-1 |
| 99 | H-1 | L-0 | Ar-99 | 485 | H-8 | L-3 | Ar-1 |
| 100 | H-1 | L-0 | Ar-100 | 486 | H-9 | L-3 | Ar-1 |
| 101 | H-1 | L-0 | Ar-101 | 487 | H-10 | L-3 | Ar-1 |
| 102 | H-1 | L-0 | Ar-102 | 488 | H-11 | L-3 | Ar-1 |
| 103 | H-1 | L-0 | Ar-103 | 489 | H-12 | L-3 | Ar-1 |
| 104 | H-1 | L-0 | Ar-104 | 490 | H-13 | L-3 | Ar-1 |
| 105 | H-1 | L-0 | Ar-105 | 491 | H-14 | L-3 | Ar-1 |
| 106 | H-1 | L-0 | Ar-106 | 492 | H-15 | L-3 | Ar-1 |
| 107 | H-1 | L-0 | Ar-107 | 493 | H-16 | L-3 | Ar-1 |
| 108 | H-1 | L-0 | Ar-108 | 494 | H-17 | L-3 | Ar-1 |
| 109 | H-1 | L-0 | Ar-109 | 495 | H-18 | L-3 | Ar-1 |
| 110 | H-1 | L-0 | Ar-110 | 496 | H-19 | L-3 | Ar-1 |
| 111 | H-1 | L-0 | Ar-111 | 497 | H-20 | L-3 | Ar-1 |
| 112 | H-1 | L-0 | Ar-112 | 498 | H-21 | L-3 | Ar-1 |
| 113 | H-1 | L-0 | Ar-113 | 499 | H-22 | L-3 | Ar-1 |
| 114 | H-1 | L-0 | Ar-114 | 500 | H-23 | L-3 | Ar-1 |
| 115 | H-1 | L-0 | Ar-115 | 501 | H-24 | L-3 | Ar-1 |
| 116 | H-1 | L-0 | Ar-116 | 502 | H-25 | L-3 | Ar-1 |
| 117 | H-1 | L-1 | Ar-1 | 503 | H-26 | L-3 | Ar-1 |
| 118 | H-1 | L-1 | Ar-2 | 504 | H-27 | L-3 | Ar-1 |
| 119 | H-1 | L-1 | Ar-3 | 505 | H-28 | L-3 | Ar-1 |
| 120 | H-1 | L-1 | Ar-4 | 506 | H-29 | L-3 | Ar-1 |
| 121 | H-1 | L-1 | Ar-5 | 507 | H-30 | L-3 | Ar-1 |
| 122 | H-1 | L-1 | Ar-6 | 508 | H-31 | L-3 | Ar-1 |
| 123 | H-1 | L-1 | Ar-7 | 509 | H-32 | L-3 | Ar-1 |
| 124 | H-1 | L-1 | Ar-8 | 510 | H-33 | L-3 | Ar-1 |
| 125 | H-1 | L-1 | Ar-9 | 511 | H-34 | L-3 | Ar-1 |
| 126 | H-1 | L-1 | Ar-10 | 512 | H-35 | L-3 | Ar-1 |
| 127 | H-1 | L-1 | Ar-11 | 513 | H-36 | L-3 | Ar-1 |
| 128 | H-1 | L-1 | Ar-12 | 514 | H-37 | L-3 | Ar-1 |
| 129 | H-1 | L-1 | Ar-13 | 515 | H-38 | L-3 | Ar-1 |
| 130 | H-1 | L-1 | Ar-14 | 516 | H-39 | L-3 | Ar-1 |
| 131 | H-1 | L-1 | Ar-15 | 517 | H-40 | L-3 | Ar-1 |
| 132 | H-1 | L-1 | Ar-16 | 518 | H-41 | L-3 | Ar-1 |
| 133 | H-1 | L-1 | Ar-17 | 519 | H-42 | L-3 | Ar-1 |
| 134 | H-1 | L-1 | Ar-18 | 520 | H-43 | L-3 | Ar-1 |
| 135 | H-1 | L-1 | Ar-19 | 521 | H-44 | L-3 | Ar-1 |
| 136 | H-1 | L-1 | Ar-20 | 522 | H-45 | L-3 | Ar-1 |
| 137 | H-1 | L-1 | Ar-21 | 523 | H-46 | L-3 | Ar-1 |
| 138 | H-1 | L-1 | Ar-22 | 524 | H-47 | L-3 | Ar-1 |
| 139 | H-1 | L-1 | Ar-23 | 525 | H-48 | L-3 | Ar-1 |
| 140 | H-1 | L-1 | Ar-24 | 526 | H-49 | L-3 | Ar-1 |
| 141 | H-1 | L-1 | Ar-25 | 527 | H-50 | L-3 | Ar-1 |
| 142 | H-1 | L-1 | Ar-26 | 528 | H-51 | L-3 | Ar-1 |
| 143 | H-1 | L-1 | Ar-27 | 529 | H-52 | L-3 | Ar-1 |
| 144 | H-1 | L-1 | Ar-28 | 530 | H-53 | L-3 | Ar-1 |
| 145 | H-1 | L-1 | Ar-29 | 531 | H-54 | L-3 | + |
| 146 | H-1 | L-1 | Ar-30 | 532 | H-55 | L-3 | Ar-1 |
| 147 | H-1 | L-1 | Ar-31 | 533 | H-56 | L-3 | Ar-1 |
| 148 | H-1 | L-1 | Ar-32 | 534 | H-57 | L-3 | Ar-1 |
| 149 | H-1 | L-1 | Ar-33 | 535 | H-58 | L-3 | Ar-1 |
| 150 | H-1 | L-1 | Ar-34 | 536 | H-59 | L-3 | Ar-1 |
| 151 | H-1 | L-1 | Ar-35 | 537 | H-60 | L-3 | Ar-1 |
| 152 | H-1 | L-1 | Ar-36 | 538 | H-61 | L-3 | Ar-1 |
| 153 | H-1 | L-1 | Ar-37 | 539 | H-62 | L-3 | Ar-1 |
| 154 | H-1 | L-1 | Ar-38 | 540 | H-63 | L-3 | Ar-1 |
| 155 | H-1 | L-1 | Ar-39 | 541 | H-64 | L-3 | Ar-1 |
| 156 | H-1 | L-1 | Ar-40 | 542 | H-65 | L-3 | Ar-1 |
| 157 | H-1 | L-1 | Ar-41 | 543 | H-66 | L-3 | Ar-1 |
| 158 | H-1 | L-1 | Ar-42 | 544 | H-67 | L-3 | Ar-1 |
| 159 | H-1 | L-1 | Ar-43 | 545 | H-68 | L-3 | Ar-1 |
| 160 | H-1 | L-1 | Ar-44 | 546 | H-69 | L-3 | Ar-1 |
| 161 | H-1 | L-1 | Ar-45 | 547 | H-70 | L-3 | Ar-1 |
| 162 | H-1 | L-1 | Ar-46 | 548 | H-71 | L-3 | Ar-1 |
| 163 | H-1 | L-1 | Ar-47 | 549 | H-72 | L-3 | Ar-1 |
| 164 | H-1 | L-1 | Ar-48 | 550 | H-73 | L-3 | Ar-1 |
| 165 | H-1 | L-1 | Ar-49 | 551 | H-74 | L-3 | Ar-1 |
| 166 | H-1 | L-1 | Ar-50 | 552 | H-75 | L-3 | Ar-1 |
| 167 | H-1 | L-1 | Ar-51 | 553 | H-76 | L-3 | Ar-1 |
| 168 | H-1 | L-1 | Ar-52 | 554 | H-77 | L-3 | Ar-1 |
| 169 | H-1 | L-1 | Ar-53 | 555 | H-78 | L-3 | Ar-1 |
| 170 | H-1 | L-1 | Ar-54 | 556 | H-79 | L-3 | Ar-1 |
| 171 | H-1 | L-1 | Ar-55 | 557 | H-80 | L-3 | Ar-1 |
| 172 | H-1 | L-1 | Ar-56 | 558 | H-81 | L-3 | Ar-1 |
| 173 | H-1 | L-1 | Ar-57 | 559 | H-82 | L-3 | Ar-1 |
| 174 | H-1 | L-1 | Ar-58 | 560 | H-83 | L-3 | Ar-1 |
| 175 | H-1 | L-1 | Ar-59 | 561 | H-84 | L-3 | Ar-1 |
| 176 | H-1 | L-1 | Ar-60 | 562 | H-85 | L-3 | Ar-1 |
| 177 | H-1 | L-1 | Ar-61 | 563 | H-86 | L-3 | Ar-1 |
| 178 | H-1 | L-1 | Ar-62 | 564 | H-87 | L-3 | Ar-1 |
| 179 | H-1 | L-1 | Ar-63 | 565 | H-88 | L-3 | Ar-1 |
| 180 | H-1 | L-1 | Ar-64 | 566 | H-89 | L-3 | Ar-1 |
| 181 | H-1 | L-1 | Ar-65 | 567 | H-90 | L-3 | Ar-1 |
| 182 | H-1 | L-1 | Ar-66 | 568 | H-91 | L-3 | Ar-1 |
| 183 | H-1 | L-1 | Ar-67 | 569 | H-92 | L-3 | Ar-1 |
| 184 | H-1 | L-1 | Ar-68 | 570 | H-93 | L-3 | Ar-1 |
| 185 | H-1 | L-1 | Ar-69 | 571 | H-94 | L-3 | Ar-1 |
| 186 | H-1 | L-1 | Ar-70 | 572 | H-95 | L-3 | Ar-1 |
| 187 | H-1 | L-1 | Ar-71 | 573 | H-96 | L-3 | Ar-1 |
| 188 | H-1 | L-1 | Ar-72 | 574 | H-97 | L-3 | Ar-1 |
| 189 | H-1 | L-1 | Ar-73 | 575 | H-98 | L-3 | Ar-1 |
| 190 | H-1 | L-1 | Ar-74 | 576 | H-99 | L-3 | Ar-1 |
| 191 | H-1 | L-1 | Ar-75 | 577 | H-100 | L-3 | Ar-1 |
| 192 | H-1 | L-1 | Ar-76 | 578 | H-101 | L-3 | Ar-1 |
| 193 | H-1 | L-1 | Ar-77 | 579 | H-102 | L-3 | Ar-1 |
| 194 | H-1 | L-1 | Ar-78 | 580 | H-103 | L-3 | Ar-1 |
| 195 | H-1 | L-1 | Ar-79 | 581 | H-104 | L-3 | Ar-1 |
| 196 | H-1 | L-1 | Ar-80 | 582 | H-105 | L-3 | Ar-1 |
| 197 | H-1 | L-1 | Ar-81 | 583 | H-106 | L-3 | Ar-1 |
| 198 | H-1 | L-1 | Ar-82 | 584 | H-107 | L-3 | Ar-1 |
| 199 | H-1 | L-1 | Ar-83 | 585 | H-108 | L-3 | Ar-1 |
| 200 | H-1 | L-1 | Ar-84 | 586 | H-109 | L-3 | Ar-1 |
| 201 | H-1 | L-1 | Ar-85 | 587 | H-110 | L-3 | Ar-1 |
| 202 | H-1 | L-1 | Ar-86 | 588 | H-111 | L-3 | Ar-1 |
| 203 | H-1 | L-1 | Ar-87 | 589 | H-112 | L-3 | Ar-1 |
| 204 | H-1 | L-1 | Ar-88 | 590 | H-113 | L-3 | Ar-1 |
| 205 | H-1 | L-1 | Ar-89 | 591 | H-114 | L-3 | Ar-1 |
| 206 | H-1 | L-1 | Ar-90 | 592 | H-115 | L-3 | Ar-1 |
| 207 | H-1 | L-1 | Ar-91 | 593 | H-116 | L-3 | Ar-1 |
| 208 | H-1 | L-1 | Ar-92 | 594 | H-117 | L-3 | Ar-1 |
| 209 | H-1 | L-1 | Ar-93 | 595 | H-118 | L-3 | Ar-1 |
| 210 | H-1 | L-1 | Ar-94 | 596 | H-119 | L-3 | Ar-1 |
| 211 | H-1 | L-1 | Ar-95 | 597 | H-120 | L-3 | Ar-1 |
| 212 | H-1 | L-1 | Ar-96 | 598 | H-121 | L-3 | Ar-1 |
| 213 | H-1 | L-1 | Ar-97 | 599 | H-122 | L-3 | Ar-1 |
| 214 | H-1 | L-1 | Ar-98 | 600 | H-123 | L-3 | Ar-1 |
| 215 | H-1 | L-1 | Ar-99 | 601 | H-124 | L-3 | Ar-1 |
| 216 | H-1 | L-1 | Ar-100 | 602 | H-125 | L-3 | Ar-1 |
| 217 | H-1 | L-1 | Ar-101 | 603 | H-126 | L-3 | Ar-1 |
| 218 | H-1 | L-1 | Ar-102 | 604 | H-127 | L-3 | Ar-1 |
| 219 | H-1 | L-1 | Ar-103 | 605 | H-128 | L-3 | Ar-1 |
| 220 | H-1 | L-1 | Ar-104 | 606 | H-129 | L-3 | Ar-1 |
| 221 | H-1 | L-1 | Ar-105 | 607 | H-130 | L-3 | Ar-1 |
| 222 | H-1 | L-1 | Ar-106 | 608 | H-131 | L-3 | Ar-1 |
| 223 | H-1 | L-1 | Ar-107 | 609 | H-132 | L-3 | Ar-1 |
| 224 | H-1 | L-1 | Ar-108 | 610 | H-133 | L-3 | Ar-1 |
| 225 | H-1 | L-1 | Ar-109 | 611 | H-134 | L-3 | Ar-1 |
| 226 | H-1 | L-1 | Ar-110 | 612 | H-135 | L-3 | Ar-1 |
| 227 | H-1 | L-1 | Ar-111 | 613 | H-136 | L-3 | Ar-1 |
| 228 | H-1 | L-1 | Ar-112 | 614 | H-137 | L-3 | Ar-1 |
| 229 | H-1 | L-1 | Ar-113 | 615 | H-138 | L-3 | Ar-1 |
| 230 | H-1 | L-1 | Ar-114 | 616 | H-139 | L-3 | Ar-1 |
| 231 | H-1 | L-1 | Ar-115 | 617 | H-1 | L-4 | Ar-77 |
| 232 | H-1 | L-1 | Ar-116 | 618 | H-1 | L-4 | Ar-77 |
| 233 | H-1 | L-2 | Ar-1 | 619 | H-1 | L-4 | Ar-77 |
| 234 | H-1 | L-2 | Ar-2 | 620 | H-1 | L-5 | Ar-77 |
| 235 | H-1 | L-2 | Ar-3 | 621 | H-1 | L-6 | Ar-77 |
| 236 | H-1 | L-2 | Ar-4 | 622 | H-1 | L-7 | Ar-77 |
| 237 | H-1 | L-2 | Ar-5 | 623 | H-1 | L-8 | Ar-77 |
| 238 | H-1 | L-2 | Ar-6 | 624 | H-1 | L-9 | Ar-77 |
| 239 | H-1 | L-2 | Ar-7 | 625 | H-1 | L-10 | Ar-77 |
| 240 | H-1 | L-2 | Ar-8 | 626 | H-1 | L-11 | Ar-77 |
| 241 | H-1 | L-2 | Ar-9 | 627 | H-1 | L-12 | Ar-77 |
| 242 | H-1 | L-2 | Ar-10 | 628 | H-1 | L-13 | Ar-77 |
| 243 | H-1 | L-2 | Ar-11 | 629 | H-1 | L-14 | Ar-77 |
| 244 | H-1 | L-2 | Ar-12 | 630 | H-1 | L-15 | Ar-77 |
| 245 | H-1 | L-2 | Ar-13 | 631 | H-1 | L-16 | Ar-77 |
| 246 | H-1 | L-2 | Ar-14 | 632 | H-1 | L-17 | Ar-77 |
| 247 | H-1 | L-2 | Ar-15 | 633 | H-1 | L-18 | Ar-77 |
| 248 | H-1 | L-2 | Ar-16 | 634 | H-1 | L-19 | Ar-77 |
| 249 | H-1 | L-2 | Ar-17 | 635 | H-1 | L-20 | Ar-77 |
| 250 | H-1 | L-2 | Ar-18 | 636 | H-1 | L-21 | Ar-77 |
| 251 | H-1 | L-2 | Ar-19 | 637 | H-1 | L-22 | Ar-77 |
| 252 | H-1 | L-2 | Ar-20 | 638 | H-1 | L-23 | Ar-77 |
| 253 | H-1 | L-2 | Ar-21 | 639 | H-1 | L-24 | Ar-77 |
| 254 | H-1 | L-2 | Ar-22 | 640 | H-1 | L-25 | Ar-77 |
| 255 | H-1 | L-2 | Ar-23 | 641 | H-1 | L-26 | Ar-77 |
| 256 | H-1 | L-2 | Ar-24 | 642 | H-1 | L-27 | Ar-77 |
| 257 | H-1 | L-2 | Ar-25 | 643 | H-1 | L-4 | Ar-84 |
| 258 | H-1 | L-2 | Ar-26 | 644 | H-1 | L-5 | Ar-84 |
| 259 | H-1 | L-2 | Ar-27 | 645 | H-1 | L-6 | Ar-84 |
| 260 | H-1 | L-2 | Ar-28 | 646 | H-1 | L-7 | Ar-84 |
| 261 | H-1 | L-2 | Ar-29 | 647 | H-1 | L-8 | Ar-84 |
| 262 | H-1 | L-2 | Ar-30 | 648 | H-1 | L-9 | Ar-84 |
| 263 | H-1 | L-2 | Ar-31 | 649 | H-1 | L-10 | Ar-84 |
| 264 | H-1 | L-2 | Ar-32 | 650 | H-1 | L-11 | Ar-84 |
| 265 | H-1 | L-2 | Ar-33 | 651 | H-1 | L-12 | Ar-84 |
| 266 | H-1 | L-2 | Ar-34 | 652 | H-1 | L-13 | Ar-84 |
| 267 | H-1 | L-2 | Ar-35 | 653 | H-1 | L-14 | Ar-84 |
| 268 | H-1 | L-2 | Ar-36 | 654 | H-1 | L-15 | Ar-84 |
| 269 | H-1 | L-2 | Ar-37 | 655 | H-1 | L-16 | Ar-84 |
| 270 | H-1 | L-2 | Ar-38 | 656 | H-1 | L-17 | Ar-84 |
| 271 | H-1 | L-2 | Ar-39 | 657 | H-1 | L-18 | Ar-84 |
| 272 | H-1 | L-2 | Ar-40 | 658 | H-1 | L-19 | Ar-84 |
| 273 | H-1 | L-2 | Ar-41 | 659 | H-1 | L-20 | Ar-84 |
| 274 | H-1 | L-2 | Ar-42 | 660 | H-1 | L-21 | Ar-84 |
| 275 | H-1 | L-2 | Ar-43 | 661 | H-1 | L-22 | Ar-84 |
| 276 | H-1 | L-2 | Ar-44 | 662 | H-1 | L-23 | Ar-84 |
| 277 | H-1 | L-2 | Ar-45 | 663 | H-1 | L-24 | Ar-84 |
| 278 | H-1 | L-2 | Ar-46 | 664 | H-1 | L-25 | Ar-84 |
| 279 | H-1 | L-2 | Ar-47 | 665 | H-1 | L-26 | Ar-84 |
| 280 | H-1 | L-2 | Ar-48 | 666 | H-1 | L-27 | Ar-84 |
| 281 | H-1 | L-2 | Ar-49 | 667 | H-1 | L-5 | Ar-84 |
| 282 | H-1 | L-2 | Ar-50 | 668 | H-1 | L-6 | Ar-84 |
| 283 | H-1 | L-2 | Ar-51 | 669 | H-1 | L-7 | Ar-84 |
| 284 | H-1 | L-2 | Ar-52 | 670 | H-1 | L-8 | Ar-84 |
| 285 | H-1 | L-2 | Ar-53 | 671 | H-1 | L-9 | Ar-84 |
| 286 | H-1 | L-2 | Ar-54 | 672 | H-1 | L-10 | Ar-84 |
| 287 | H-1 | L-2 | Ar-55 | 673 | H-1 | L-11 | Ar-84 |
| 288 | H-1 | L-2 | Ar-56 | 674 | H-1 | L-12 | Ar-84 |
| 289 | H-1 | L-2 | Ar-57 | 675 | H-1 | L-13 | Ar-84 |
| 290 | H-1 | L-2 | Ar-58 | 676 | H-1 | L-14 | Ar-84 |
| 291 | H-1 | L-2 | Ar-59 | 677 | H-1 | L-15 | Ar-84 |
| 292 | H-1 | L-2 | Ar-60 | 678 | H-1 | L-16 | Ar-84 |
| 293 | H-1 | L-2 | Ar-61 | 679 | H-1 | L-17 | Ar-84 |
| 294 | H-1 | L-2 | Ar-62 | 680 | H-1 | L-18 | Ar-84 |
| 295 | H-1 | L-2 | Ar-63 | 681 | H-1 | L-4 | Ar-75 |
| 296 | H-1 | L-2 | Ar-64 | 682 | H-1 | L-5 | Ar-75 |
| 297 | H-1 | L-2 | Ar-65 | 683 | H-1 | L-6 | Ar-75 |
| 298 | H-1 | L-2 | Ar-66 | 684 | H-1 | L-7 | Ar-75 |
| 299 | H-1 | L-2 | Ar-67 | 685 | H-1 | L-8 | Ar-75 |
| 300 | H-1 | L-2 | Ar-68 | 686 | H-1 | L-9 | Ar-75 |
| 301 | H-1 | L-2 | Ar-69 | 687 | H-1 | L-10 | Ar-75 |
| 302 | H-1 | L-2 | Ar-70 | 688 | H-1 | L-12 | Ar-75 |
| 303 | H-1 | L-2 | Ar-71 | 689 | H-1 | L-13 | Ar-75 |
| 304 | H-1 | L-2 | Ar-72 | 690 | H-2 | L-2 | Ar-1 |
| 305 | H-1 | L-2 | Ar-73 | 691 | H-3 | L-2 | Ar-1 |
| 306 | H-1 | L-2 | Ar-74 | 692 | H-4 | L-2 | Ar-1 |
| 307 | H-1 | L-2 | Ar-75 | 693 | H-5 | L-2 | Ar-1 |
| 308 | H-1 | L-2 | Ar-76 | 694 | H-6 | L-2 | Ar-1 |
| 309 | H-1 | L-2 | Ar-77 | 695 | H-7 | L-2 | Ar-1 |
| 310 | H-1 | L-2 | Ar-78 | 696 | H-8 | L-2 | Ar-1 |
| 311 | H-1 | L-2 | Ar-79 | 697 | H-9 | L-2 | Ar-1 |
| 312 | H-1 | L-2 | Ar-80 | 698 | H-10 | L-2 | Ar-1 |
| 313 | H-1 | L-2 | Ar-81 | 699 | H-11 | L-2 | Ar-1 |
| 314 | H-1 | L-2 | Ar-82 | 700 | H-12 | L-2 | Ar-1 |
| 315 | H-1 | L-2 | Ar-83 | 701 | H-13 | L-2 | Ar-1 |
| 316 | H-1 | L-2 | Ar-84 | 702 | H-14 | L-2 | Ar-1 |
| 317 | H-1 | L-2 | Ar-85 | 703 | H-15 | L-2 | Ar-1 |
| 318 | H-1 | L-2 | Ar-86 | 704 | H-16 | L-2 | Ar-1 |
| 319 | H-1 | L-2 | Ar-87 | 705 | H-17 | L-2 | Ar-1 |
| 320 | H-1 | L-2 | Ar-88 | 706 | H-18 | L-2 | Ar-1 |
| 321 | H-1 | L-2 | Ar-89 | 707 | H-19 | L-2 | Ar-1 |
| 322 | H-1 | L-2 | Ar-90 | 708 | H-20 | L-2 | Ar-1 |
| 323 | H-1 | L-2 | Ar-91 | 709 | H-21 | L-2 | Ar-1 |
| 324 | H-1 | L-2 | Ar-92 | 710 | H-22 | L-2 | Ar-1 |
| 325 | H-1 | L-2 | Ar-93 | 711 | H-23 | L-2 | Ar-1 |
| 326 | H-1 | L-2 | Ar-94 | 712 | H-24 | L-2 | Ar-1 |
| 327 | H-1 | L-2 | Ar-95 | 713 | H-25 | L-2 | Ar-1 |
| 328 | H-1 | L-2 | Ar-96 | 714 | H-26 | L-2 | Ar-1 |
| 329 | H-1 | L-2 | Ar-97 | 715 | H-27 | L-2 | Ar-1 |
| 330 | H-1 | L-2 | Ar-98 | 716 | H-28 | L-2 | Ar-1 |
| 331 | H-1 | L-2 | Ar-99 | 717 | H-29 | L-2 | Ar-1 |
| 332 | H-1 | L-2 | Ar-100 | 718 | H-30 | L-2 | Ar-1 |
| 333 | H-1 | L-2 | Ar-101 | 719 | H-31 | L-2 | Ar-1 |
| 334 | H-1 | L-2 | Ar-102 | 720 | H-32 | L-2 | Ar-1 |
| 335 | H-1 | L-2 | Ar-103 | 721 | H-33 | L-2 | Ar-1 |
| 336 | H-1 | L-2 | Ar-104 | 722 | H-34 | L-2 | Ar-1 |
| 337 | H-1 | L-2 | Ar-105 | 723 | H-35 | L-2 | Ar-1 |
| 338 | H-1 | L-2 | Ar-106 | 724 | H-36 | L-2 | Ar-1 |
| 339 | H-1 | L-2 | Ar-107 | 725 | H-37 | L-2 | Ar-1 |
| 340 | H-1 | L-2 | Ar-108 | 726 | H-38 | L-2 | Ar-1 |
| 341 | H-1 | L-2 | Ar-109 | 727 | H-39 | L-2 | Ar-1 |
| 342 | H-1 | L-2 | Ar-110 | 728 | H-40 | L-2 | Ar-1 |
| 343 | H-1 | L-2 | Ar-111 | 729 | H-41 | L-2 | Ar-1 |
| 344 | H-1 | L-2 | Ar-112 | 730 | H-42 | L-2 | Ar-1 |
| 345 | H-1 | L-2 | Ar-113 | 731 | H-43 | L-2 | Ar-1 |
| 346 | H-1 | L-2 | Ar-114 | 732 | H-44 | L-2 | Ar-1 |
| 347 | H-1 | L-2 | Ar-115 | 733 | H-45 | L-2 | Ar-1 |
| 348 | H-1 | L-2 | Ar-116 | 734 | H-46 | L-2 | Ar-1 |
| 349 | H-1 | L-2 | Ar-103 | 735 | H-47 | L-2 | Ar-1 |
| 350 | H-1 | L-2 | Ar-104 | 736 | H-48 | L-2 | Ar-1 |
| 351 | H-1 | L-2 | Ar-105 | 737 | H-49 | L-2 | Ar-1 |
| 352 | H-1 | L-2 | Ar-106 | 738 | H-50 | L-2 | Ar-1 |
| 353 | H-1 | L-2 | Ar-107 | 739 | H-51 | L-2 | Ar-1 |
| 354 | H-1 | L-2 | Ar-108 | 740 | H-52 | L-2 | Ar-1 |
| 355 | H-1 | L-2 | Ar-109 | 741 | H-53 | L-2 | Ar-1 |
| 356 | H-1 | L-2 | Ar-110 | 742 | H-54 | L-2 | Ar-1 |
| 357 | H-1 | L-2 | Ar-111 | 743 | H-55 | L-2 | Ar-1 |
| 358 | H-1 | L-2 | Ar-112 | 744 | H-56 | L-2 | Ar-1 |
| 359 | H-1 | L-2 | Ar-113 | 745 | H-57 | L-2 | Ar-1 |
| 360 | H-1 | L-2 | Ar-114 | 746 | H-58 | L-2 | Ar-1 |
| 361 | H-1 | L-2 | Ar-115 | 747 | H-59 | L-2 | Ar-1 |
| 362 | H-1 | L-2 | Ar-116 | 748 | H-60 | L-2 | Ar-1 |
| 363 | H-1 | L-3 | Ar-1 | 749 | H-61 | L-2 | Ar-1 |
| 364 | H-1 | L-3 | Ar-2 | 750 | H-62 | L-2 | Ar-1 |
| 365 | H-1 | L-3 | Ar-3 | 751 | H-63 | L-2 | Ar-1 |
| 366 | H-1 | L-3 | Ar-4 | 752 | H-64 | L-2 | Ar-1 |
| 367 | H-1 | L-3 | Ar-5 | 753 | H-65 | L-2 | Ar-1 |
| 368 | H-1 | L-3 | Ar-6 | 754 | H-66 | L-2 | Ar-1 |
| 369 | H-1 | L-3 | Ar-7 | 755 | H-67 | L-2 | Ar-1 |
| 370 | H-1 | L-3 | Ar-8 | 756 | H-68 | L-2 | Ar-1 |
| 371 | H-1 | L-3 | Ar-9 | 757 | H-69 | L-2 | Ar-1 |
| 372 | H-1 | L-3 | Ar-10 | 758 | H-70 | L-2 | Ar-1 |
| 373 | H-1 | L-3 | Ar-11 | 759 | H-1 | L-1 | Ar-117 |
| 374 | H-1 | L-3 | Ar-12 | 760 | H-1 | L-1 | Ar-118 |
| 375 | H-1 | L-3 | Ar-13 | 761 | H-1 | L-1 | Ar-119 |
| 376 | H-1 | L-3 | Ar-14 | 762 | H-1 | L-1 | Ar-120 |
| 377 | H-1 | L-3 | Ar-15 | 763 | H-1 | L-1 | Ar-121 |
| 378 | H-1 | L-3 | Ar-16 | 764 | H-1 | L-1 | Ar-122 |
| 379 | H-1 | L-3 | Ar-17 | 765 | H-1 | L-1 | Ar-123 |
| 380 | H-1 | L-3 | Ar-18 | 766 | H-1 | L-1 | Ar-124 |
| 381 | H-1 | L-3 | Ar-19 | 767 | H-1 | L-1 | Ar-125 |
| 382 | H-1 | L-3 | Ar-20 | 768 | H-1 | L-1 | Ar-126 |
| 383 | H-1 | L-3 | Ar-21 | 769 | H-1 | L-1 | Ar-127 |
| 384 | H-1 | L-3 | Ar-22 | 770 | H-1 | L-1 | Ar-128 |
| 385 | H-1 | L-3 | Ar-23 | 771 | H-1 | L-1 | Ar-129 |
| 386 | H-1 | L-3 | Ar-24 | 772 | H-1 | L-1 | Ar-130 |

;
wherein optionally, hydrogens in Compound 1 to Compound 772 can be partially or fully substituted with deuterium.

12. The electroluminescent device according to claim 1, wherein the second compound has a structure represented by Formula 2-1 or Formula 2-2: 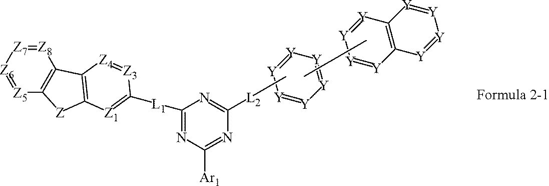 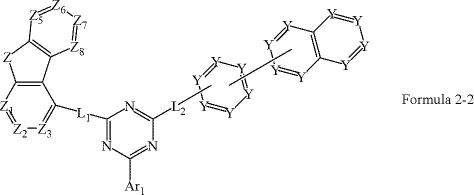
wherein
Z is selected from O, S or Se;
Z₁ to Z₈ are, at each occurrence identically or differently, selected from N or CR_{z};
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

13. The electroluminescent device according to claim 1, wherein Z₁ to Z₈ are, at each occurrence identically or differently, selected from C or CR_{z}, and/or Y is, at each occurrence identically or differently, selected from C or CR_{y}, wherein R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof; and
preferably, R_{z} and R_{y} are, at each occurrence identically or differently, selected from the group consisting of: hydrogen, deuterium, substituted or unsubstituted phenyl, substituted or unsubstituted naphthyl, substituted or unsubstituted biphenyl and combinations thereof.

14. The electroluminescent device according to claim 1, wherein Z is selected from O or S; preferably, Z is O.

15. The electroluminescent device according to claim 1, wherein Ar₁ is, at each occurrence identically or differently, selected from substituted or unsubstituted aryl having 6 to 30 carbon atoms; and
preferably, Ar₁ is, at each occurrence identically or differently, selected from the group consisting of: phenyl, naphthyl, biphenyl, phenanthryl, terphenyl, triphenylenyl and combinations thereof.

16. The electroluminescent device according to claim 1, wherein L₁ and L₂ are, at each occurrence identically or differently, selected from a single bond, substituted or unsubstituted arylene having 6 to 18 carbon atoms, substituted or unsubstituted heteroarylene having 3 to 18 carbon atoms or a combination thereof; and
preferably, L₁ and L₂ are, at each occurrence identically or differently, selected from a single bond, substituted or unsubstituted phenylene, substituted or unsubstituted naphthylene, substituted or unsubstituted biphenylene or a combination thereof.

17. The electroluminescent device according to claim 1, wherein the second compound is selected from the group consisting of the following structures: 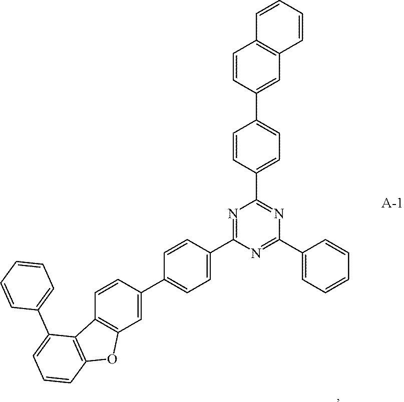 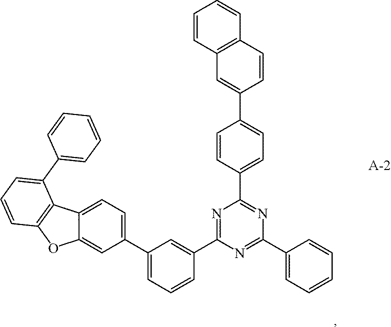 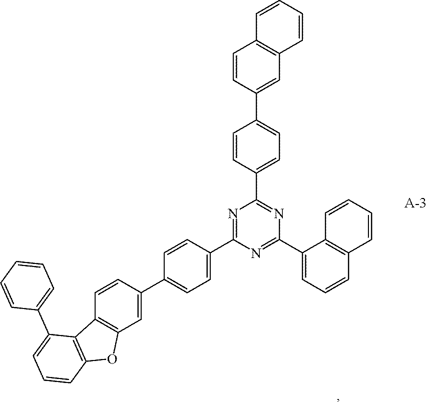 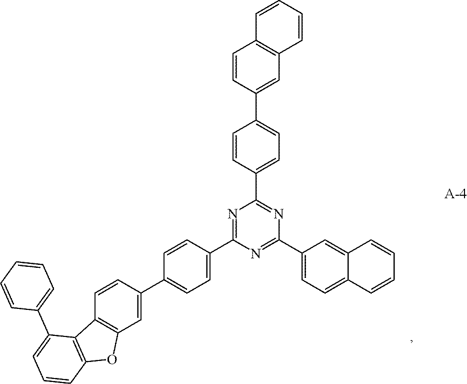 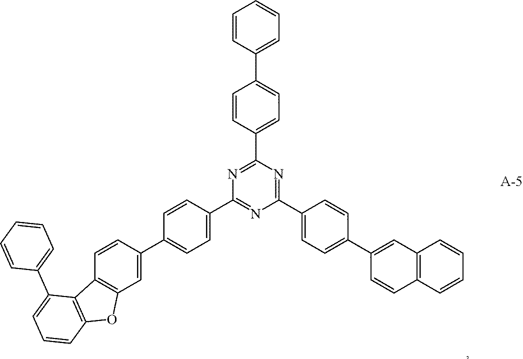 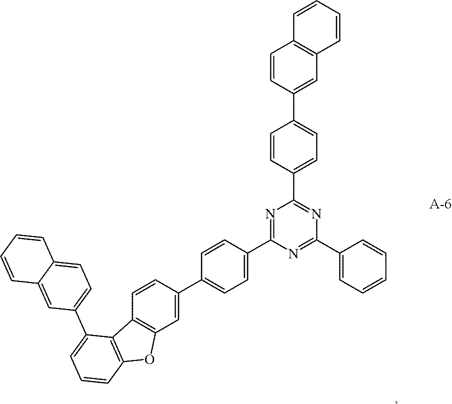 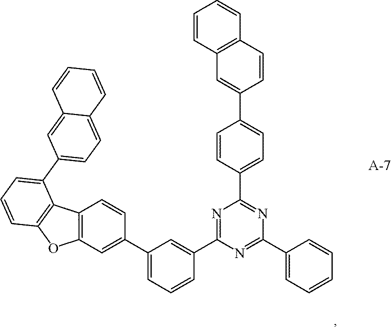 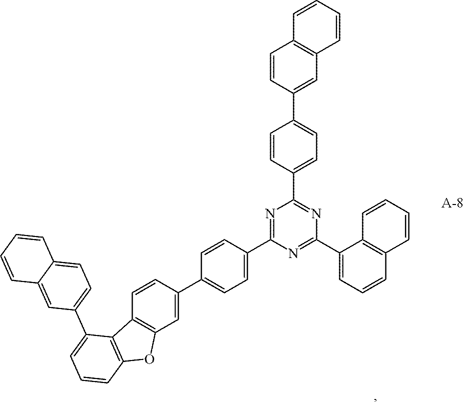 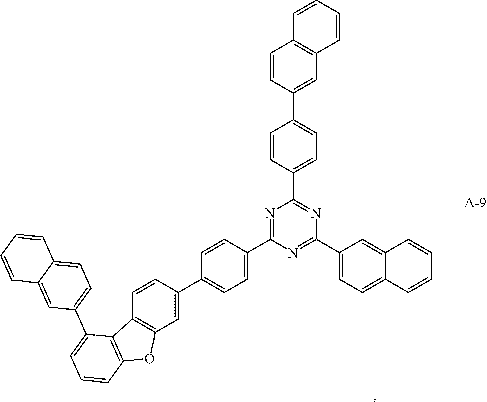 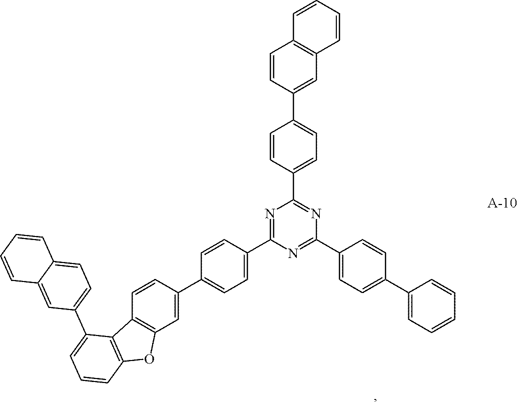 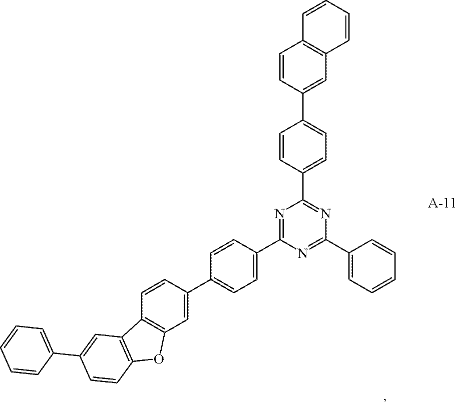 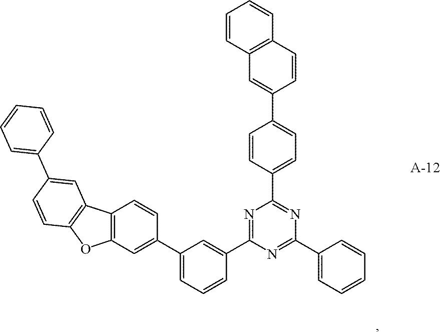 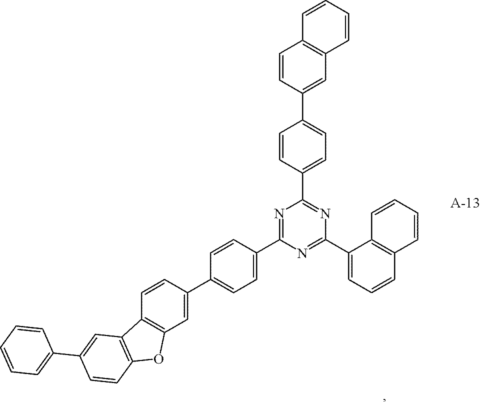 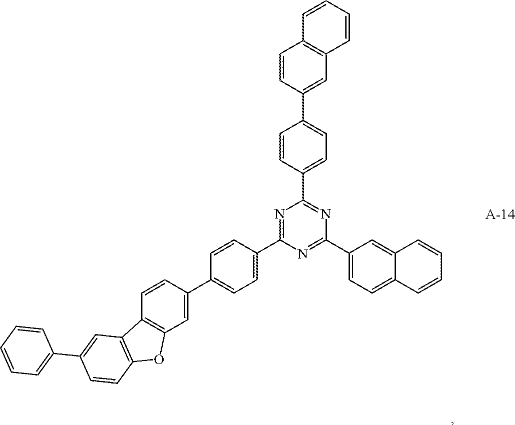 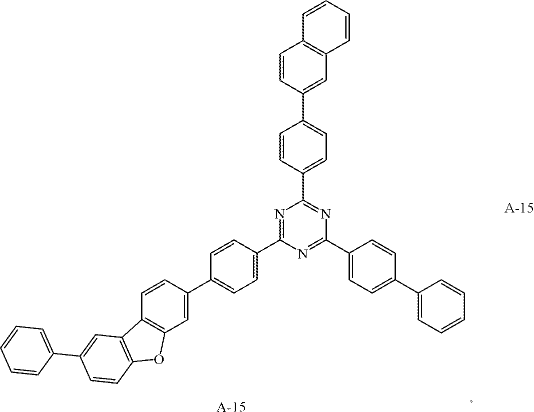 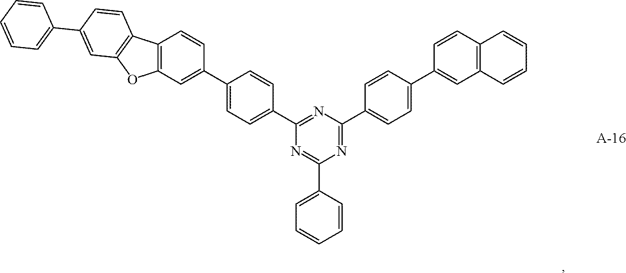 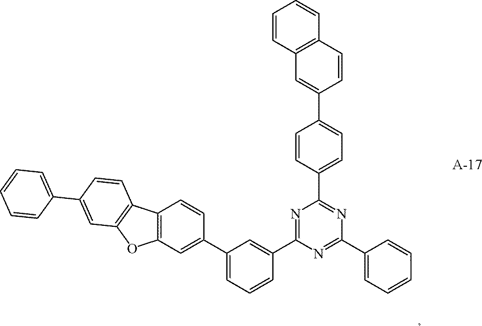 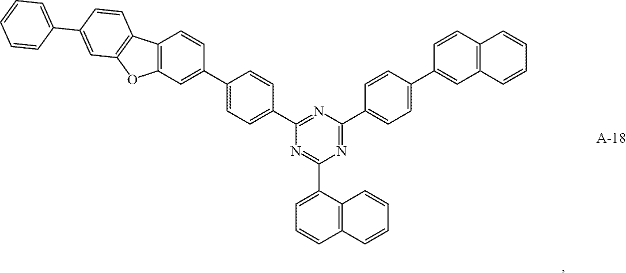 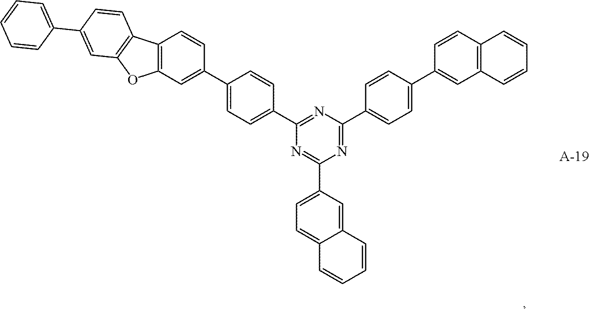 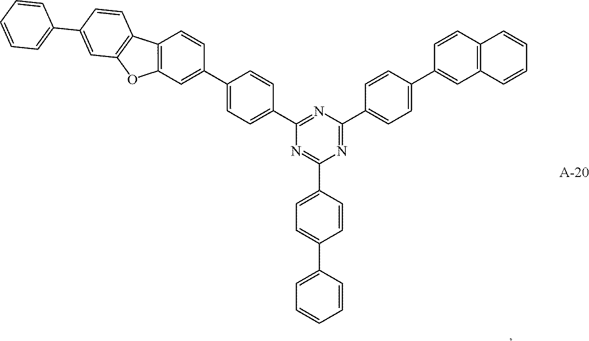 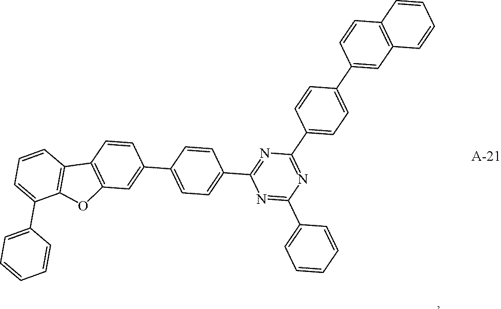 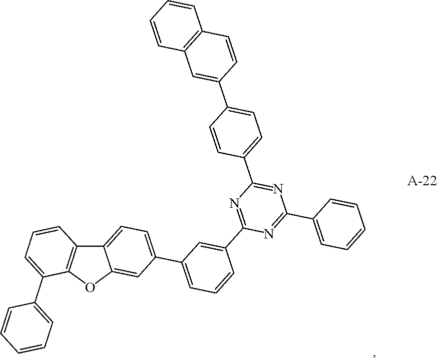 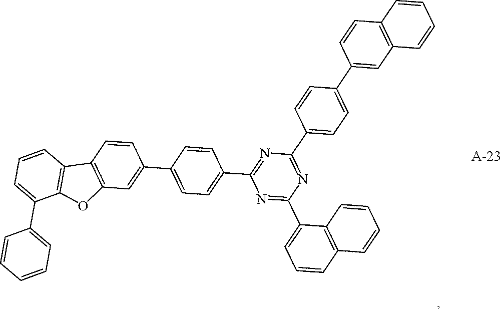 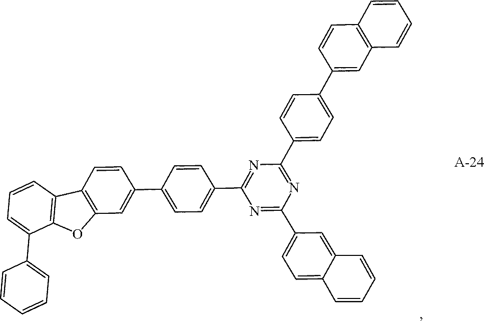 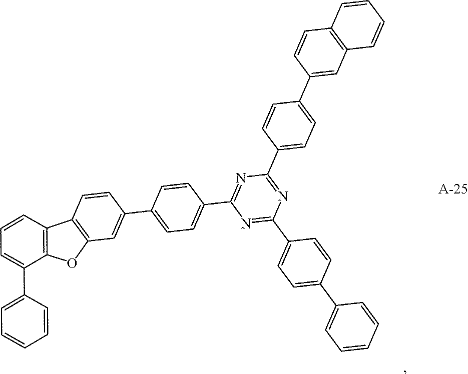 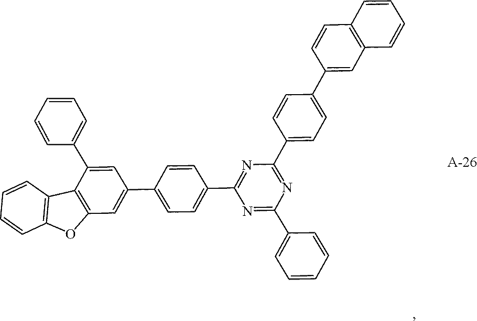 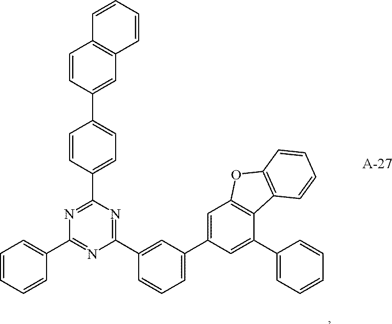 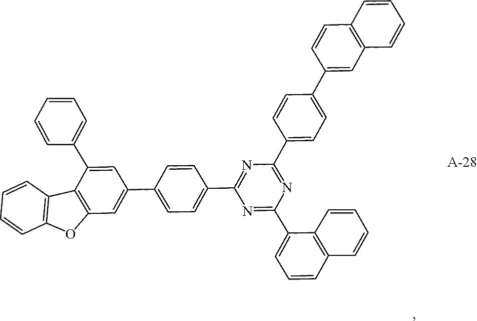 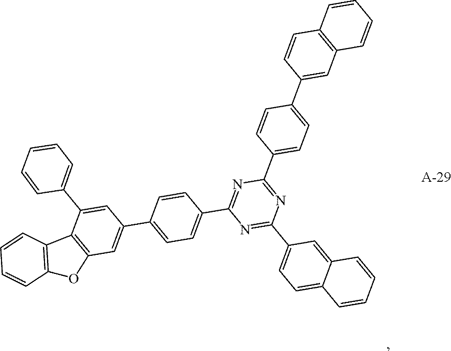 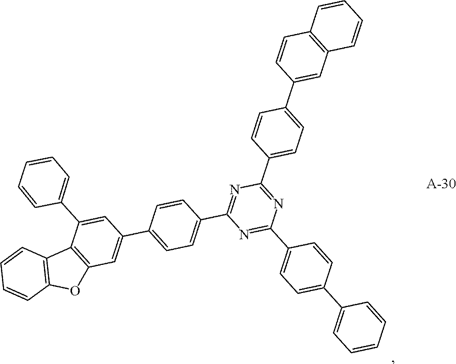 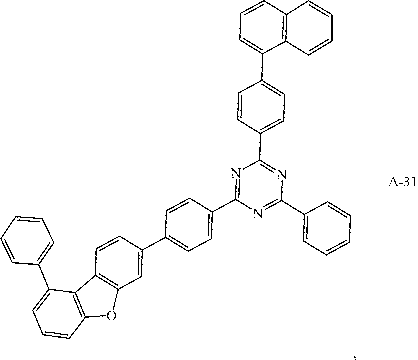 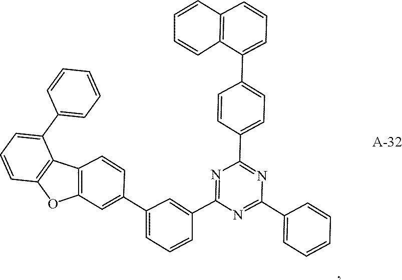 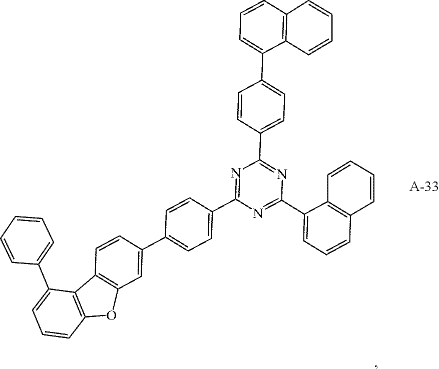 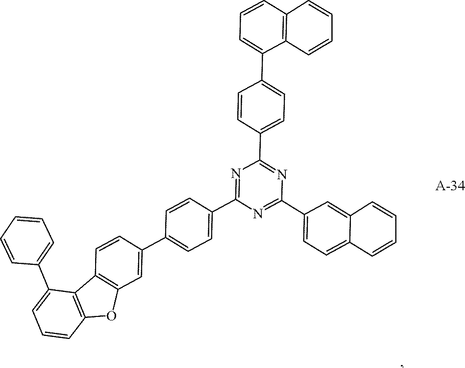 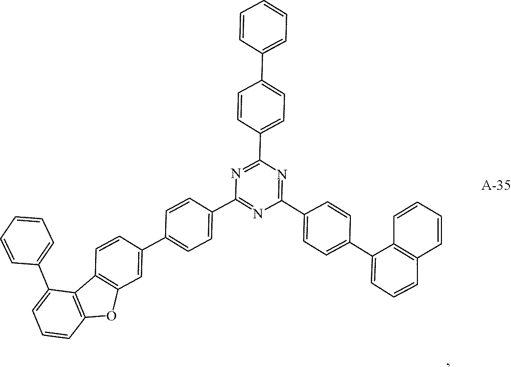 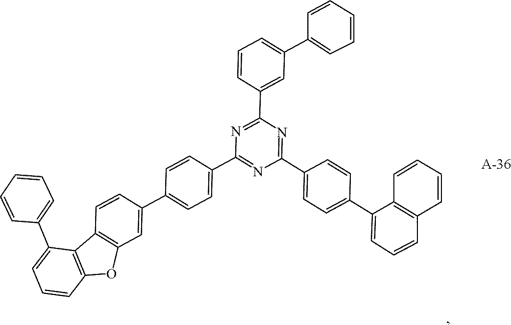 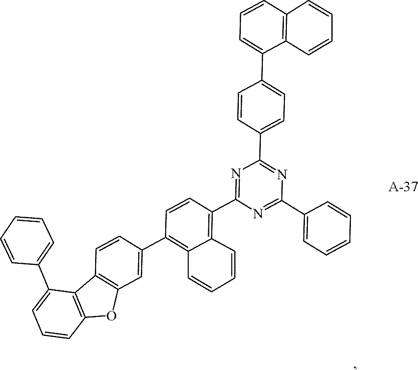 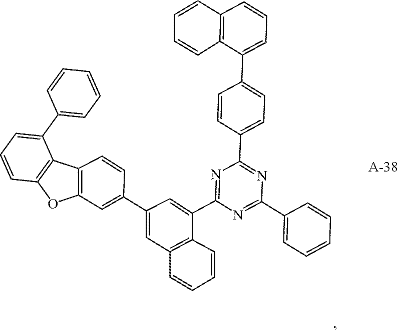 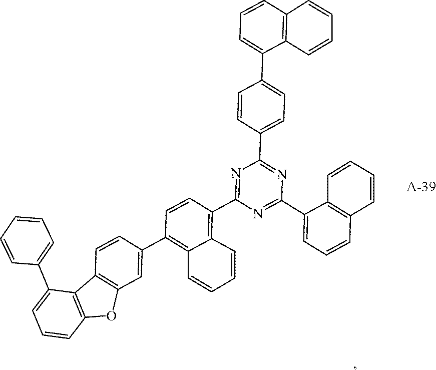 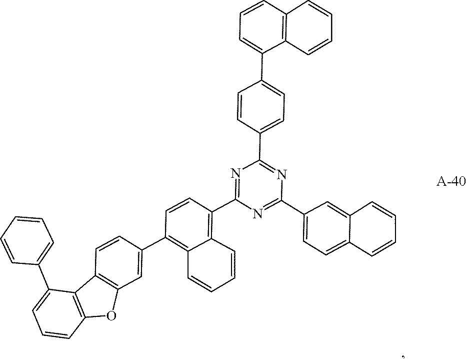 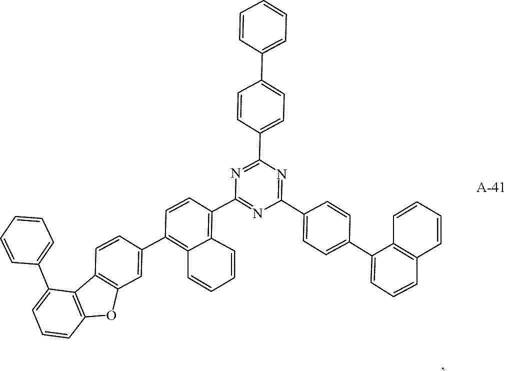 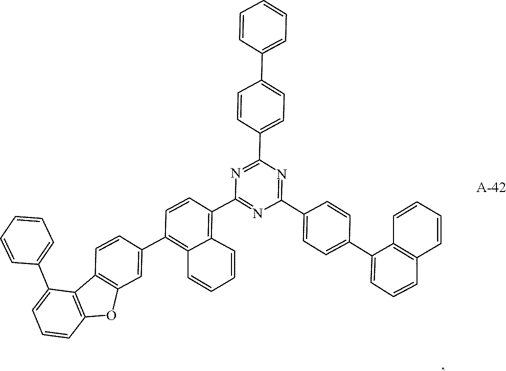 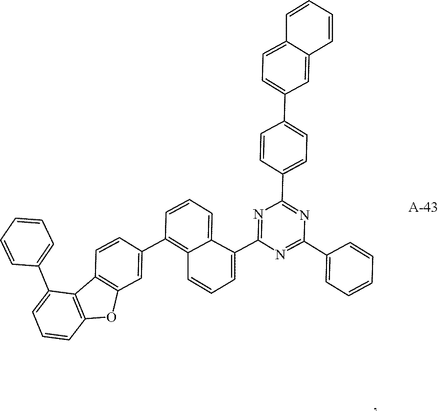 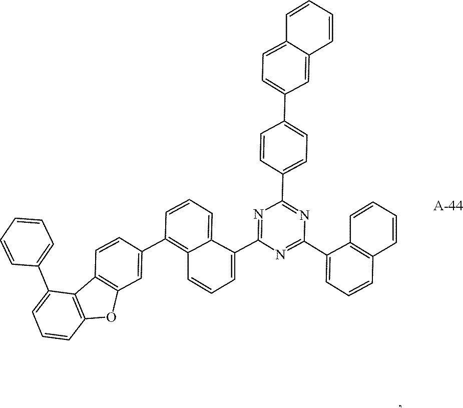 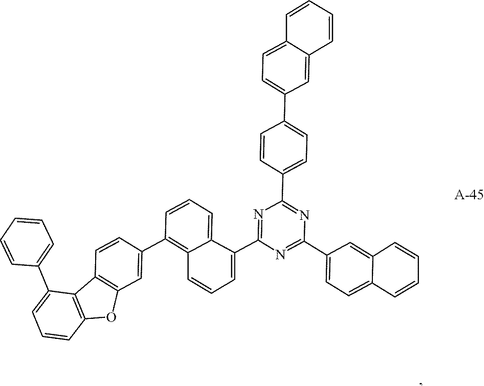 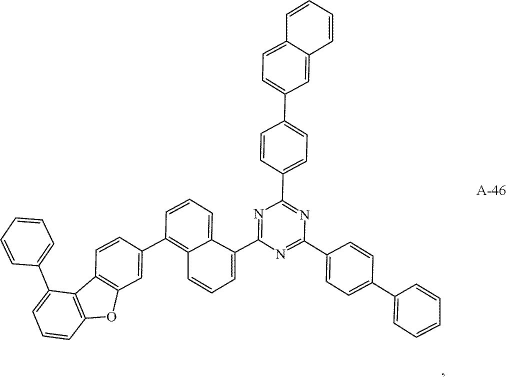 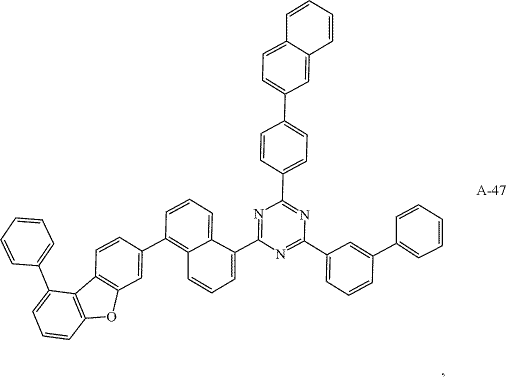 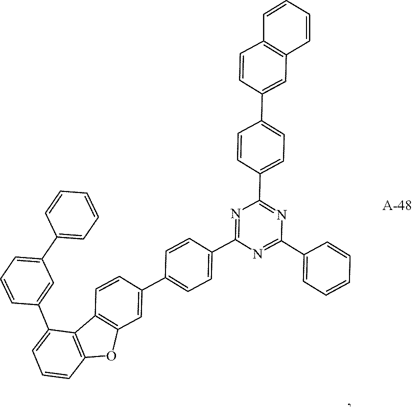 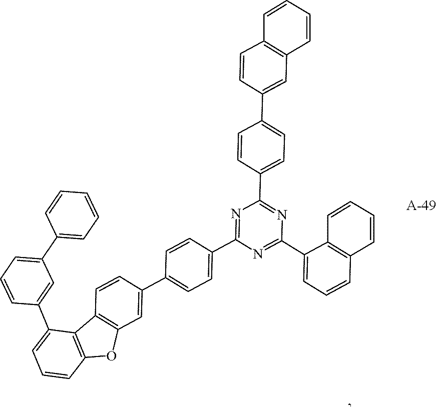 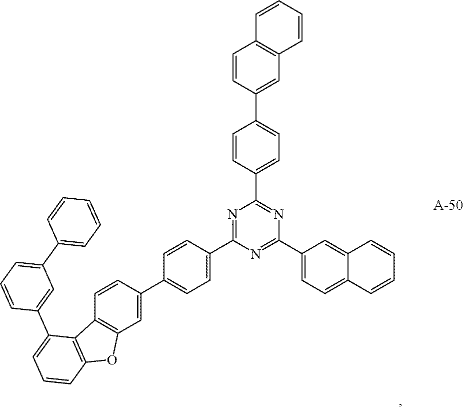 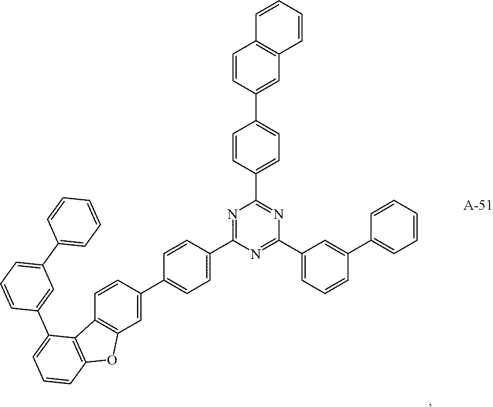 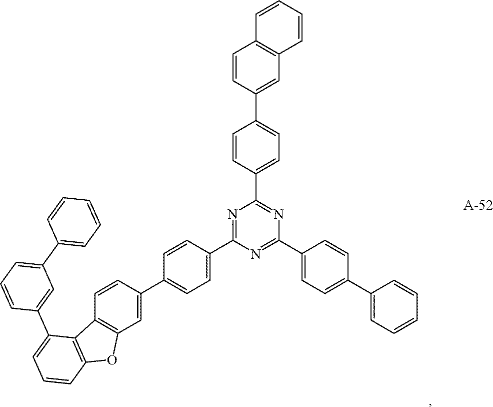 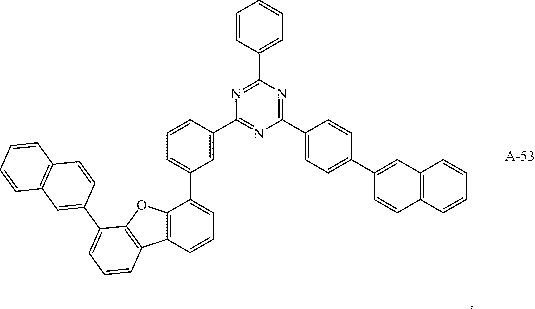 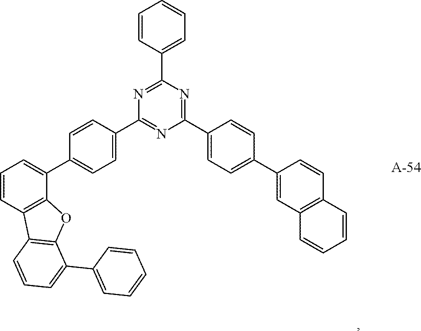 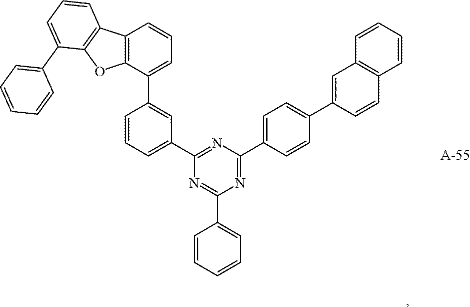 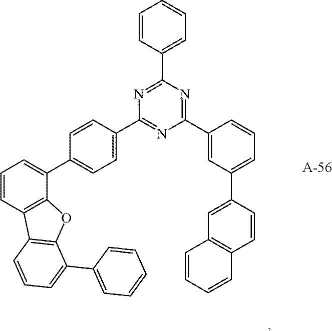 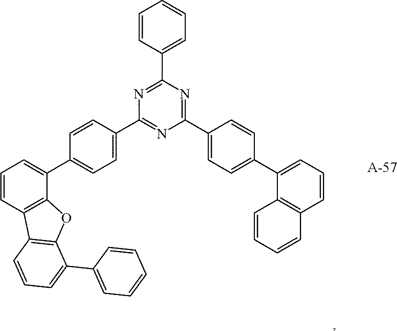 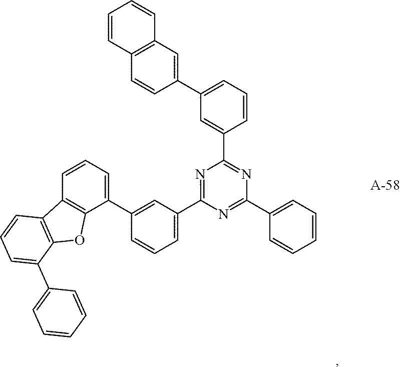 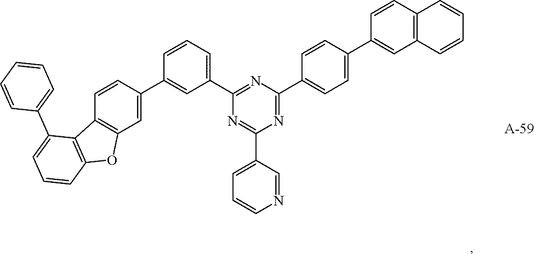 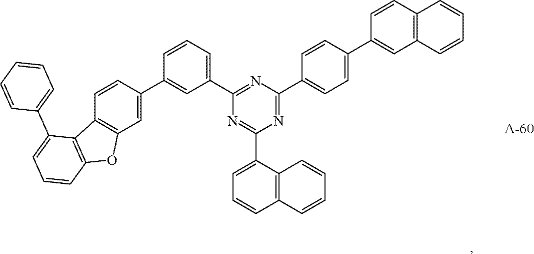 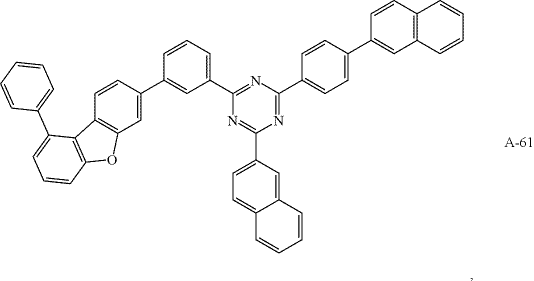 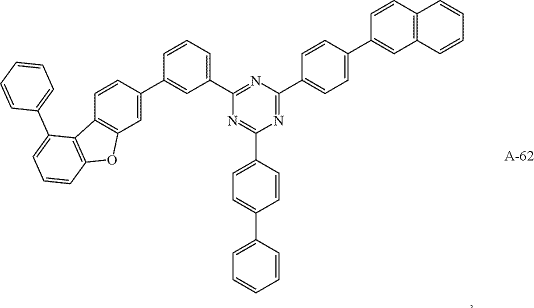 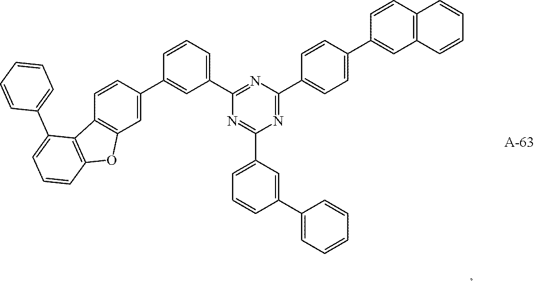 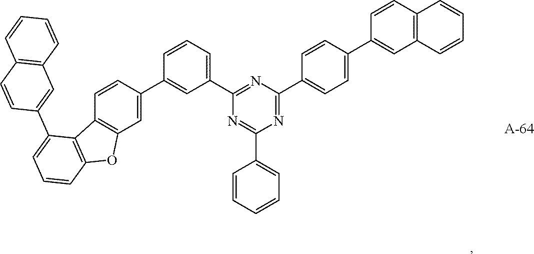 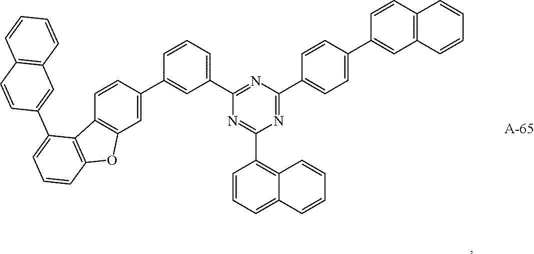 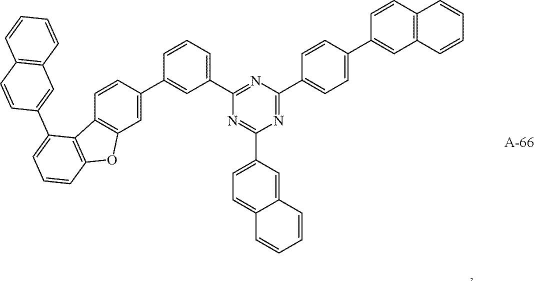 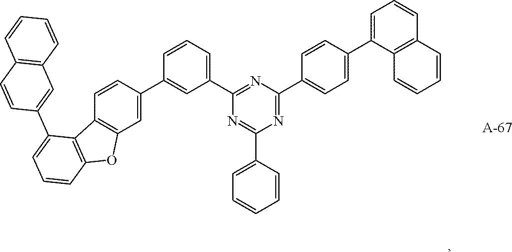 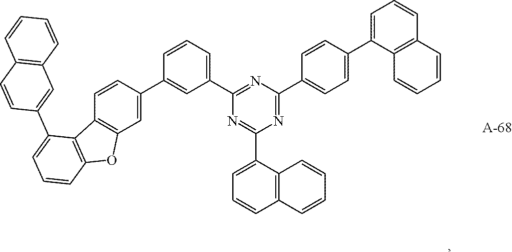 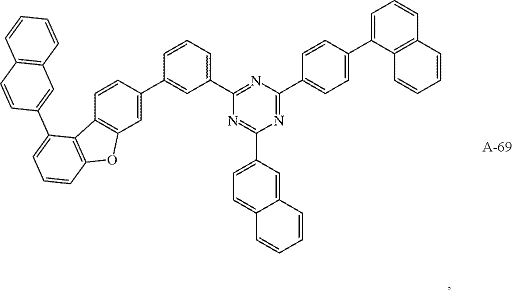 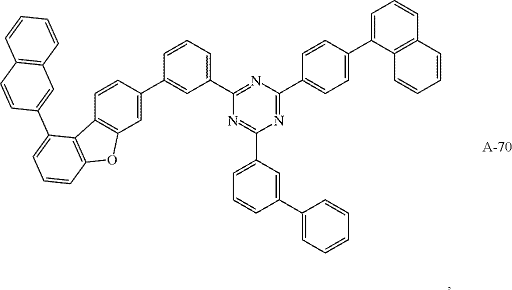 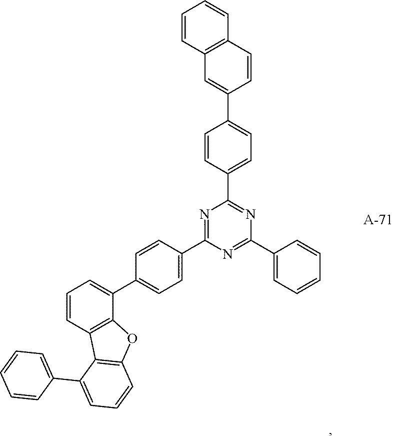 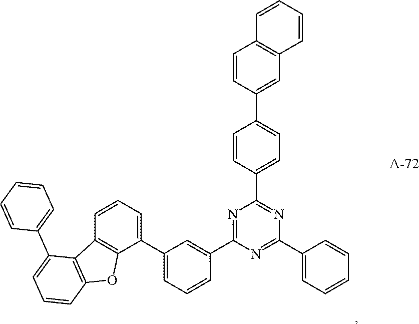 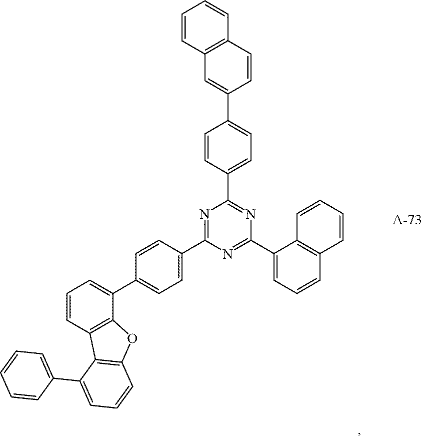 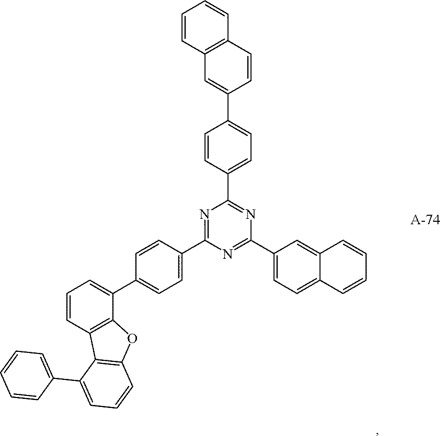 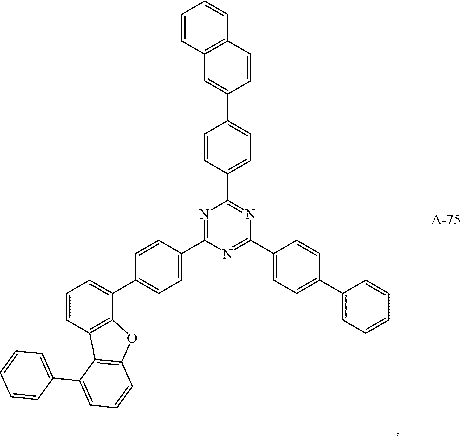 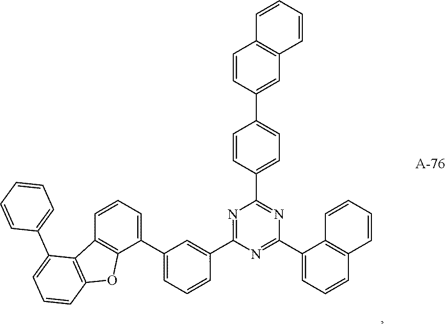 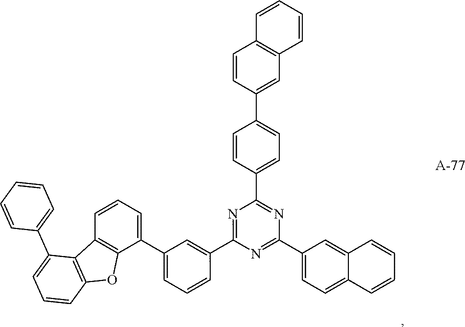 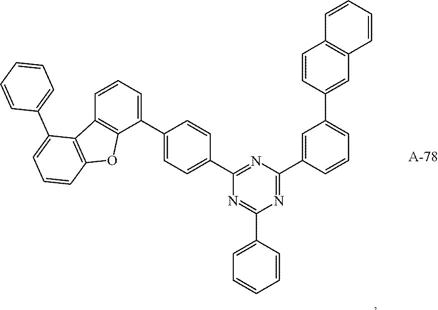 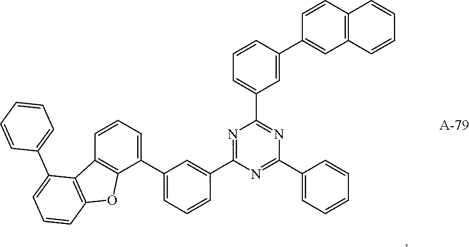 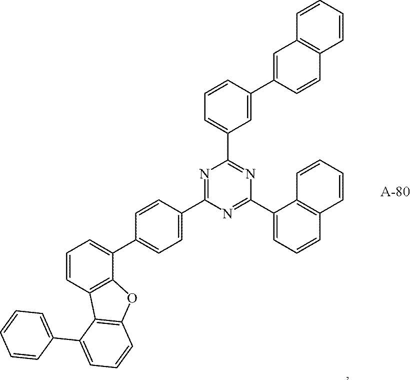 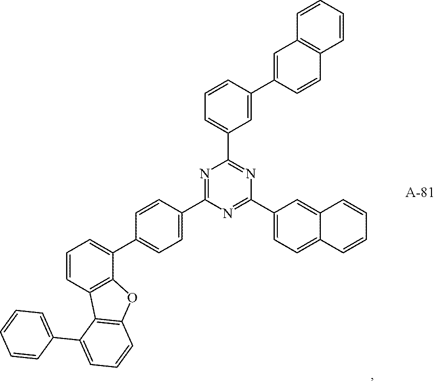 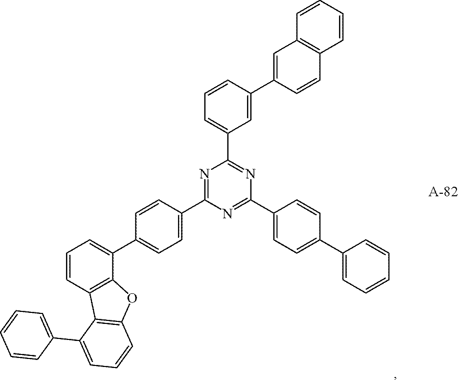 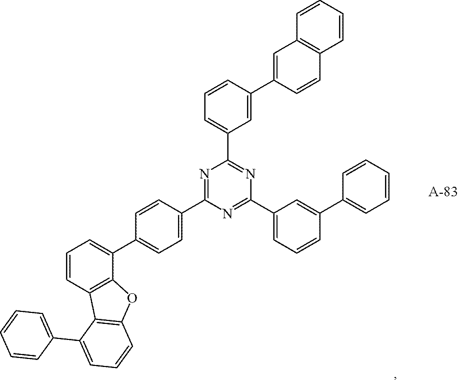 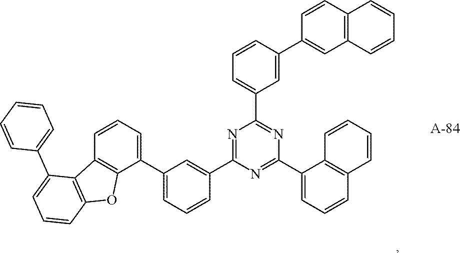 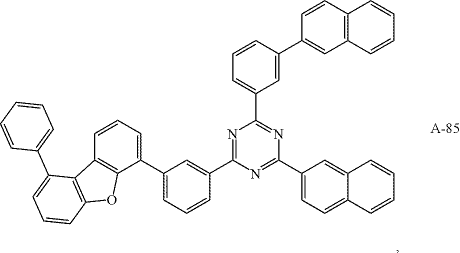 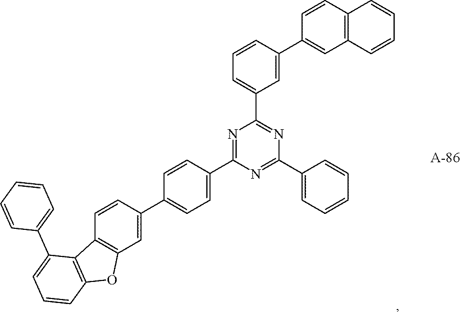 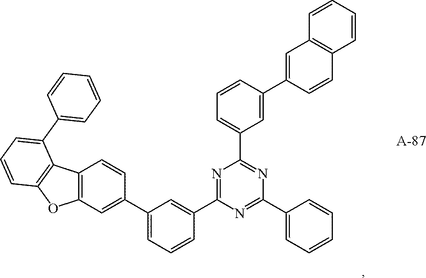 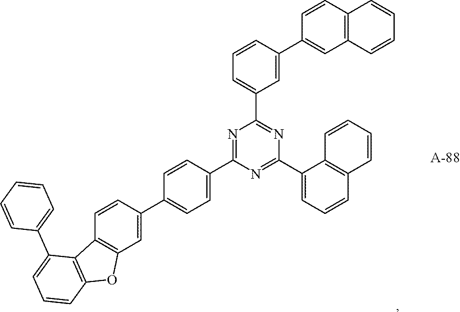 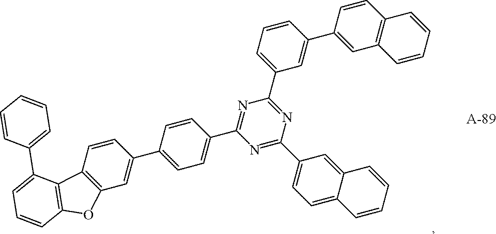 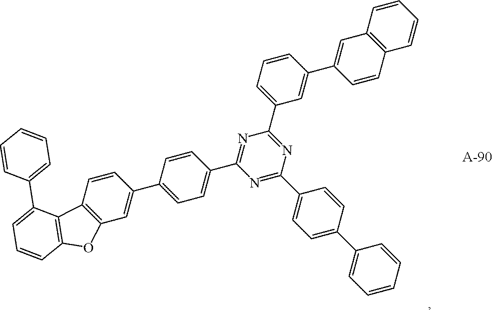 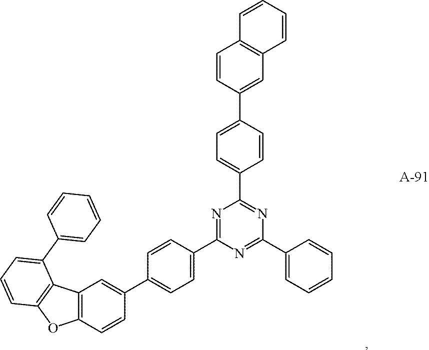 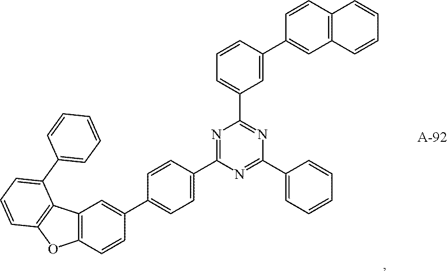 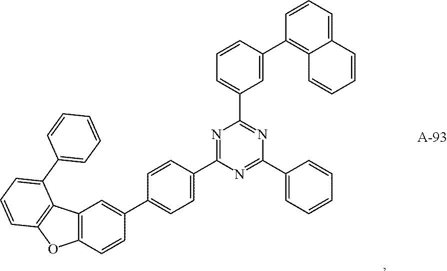 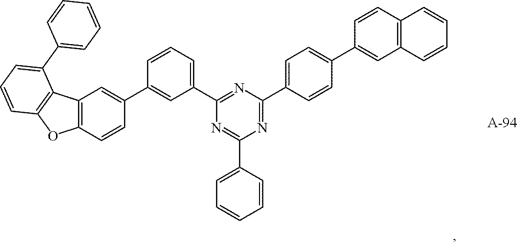 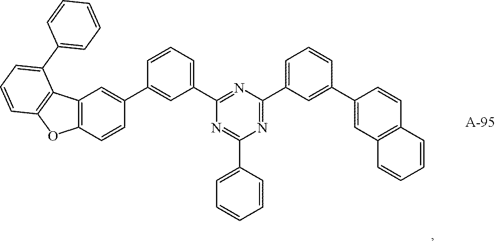 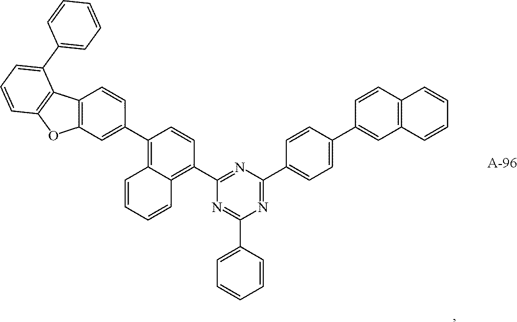 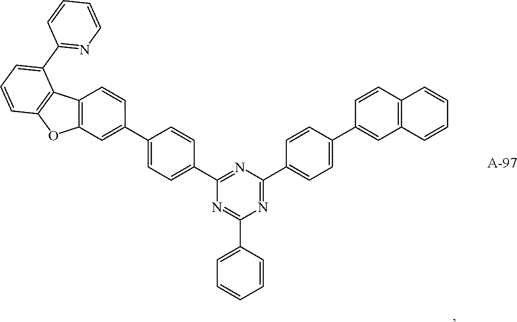 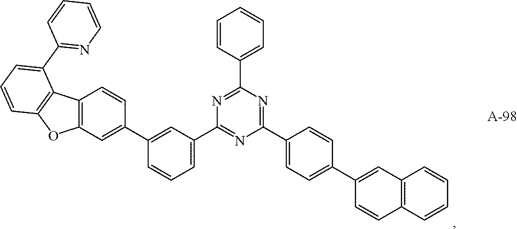 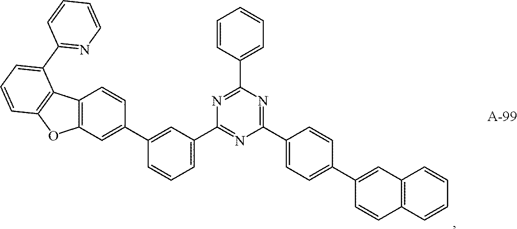 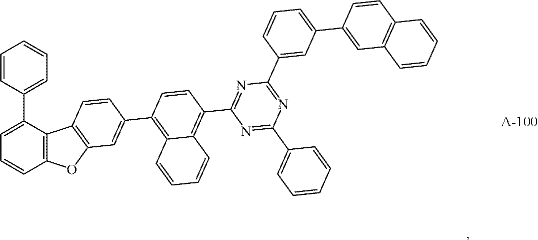 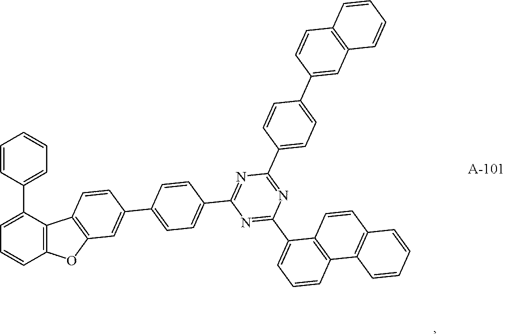 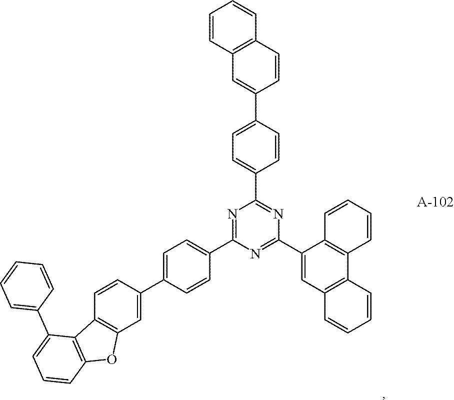 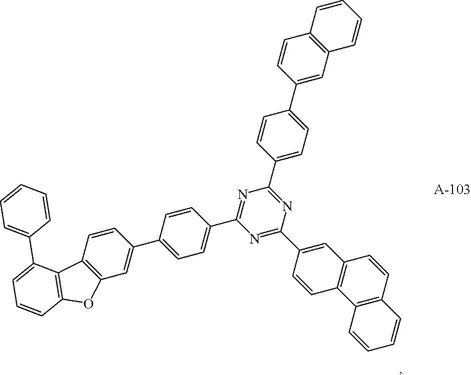 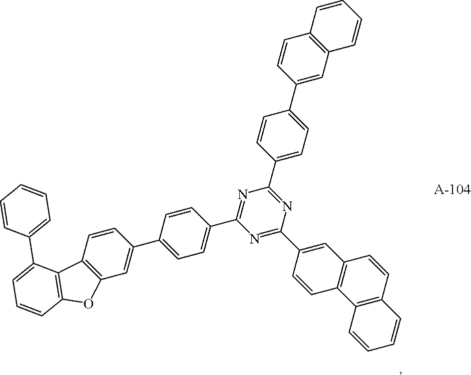 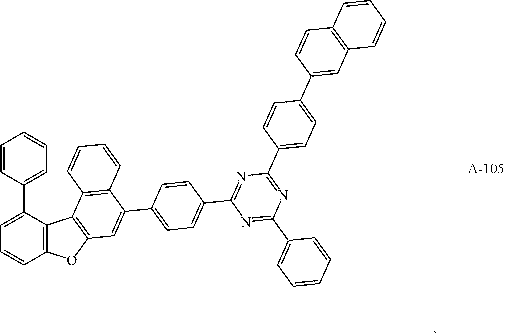 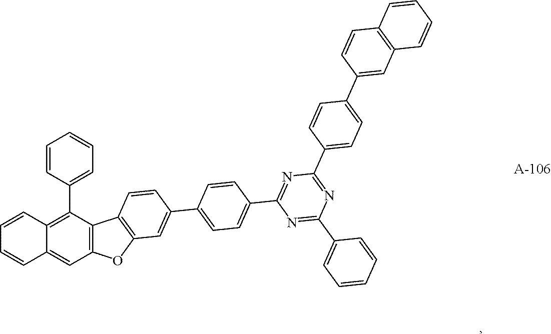 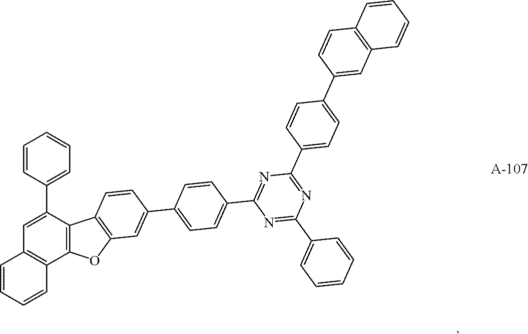 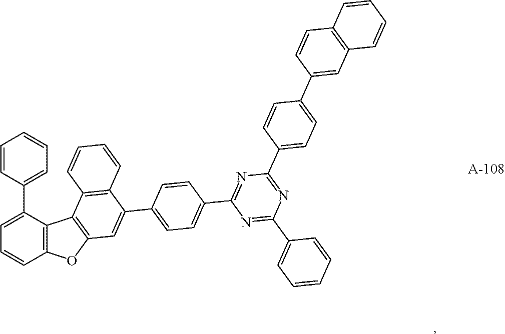 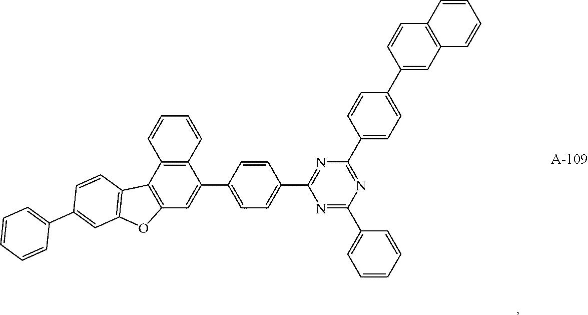 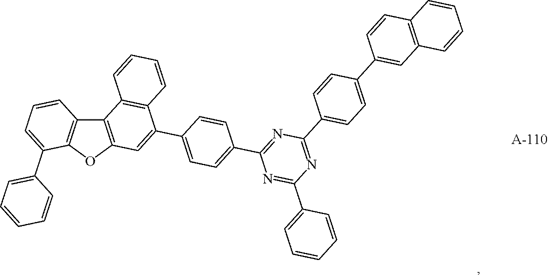 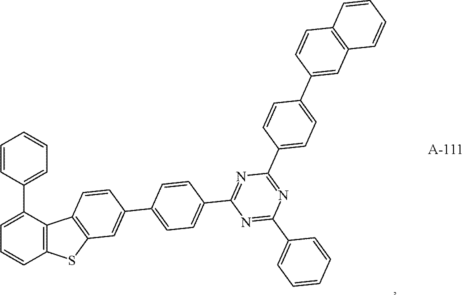 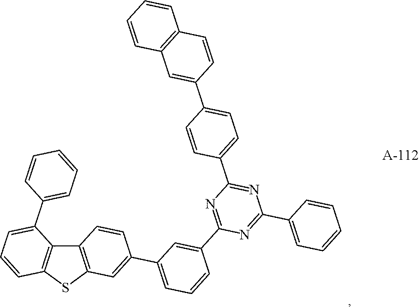 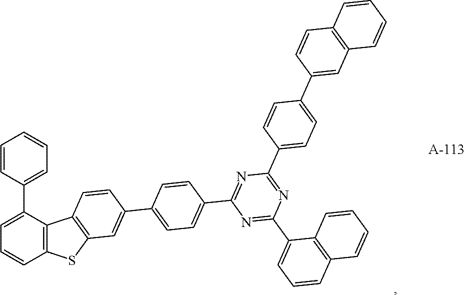 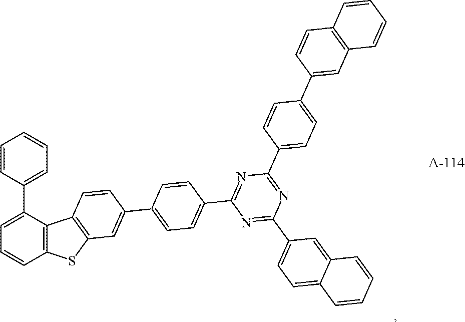 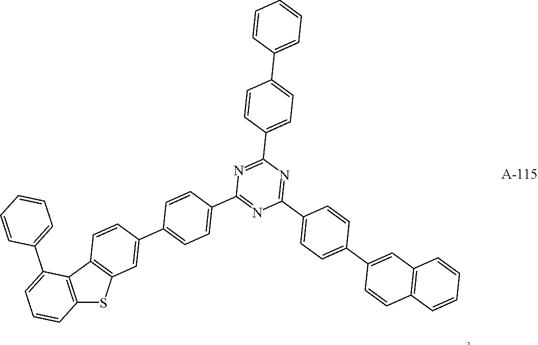 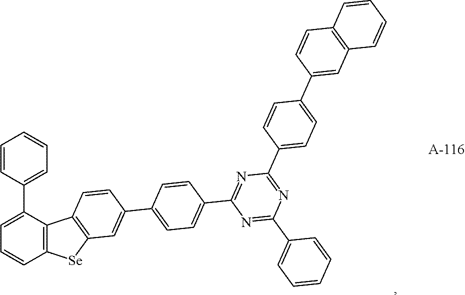 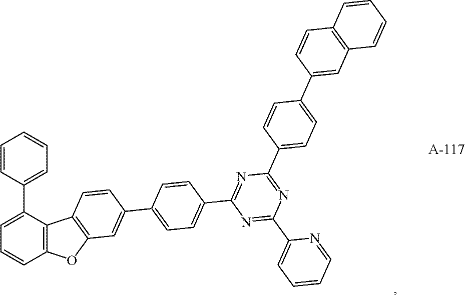 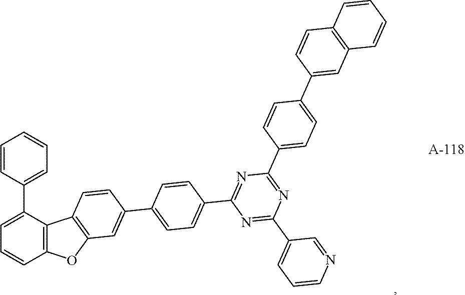 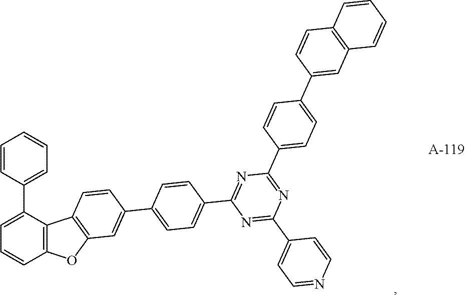 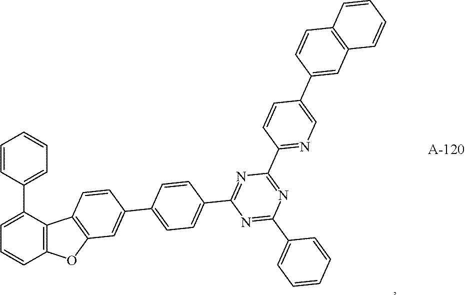 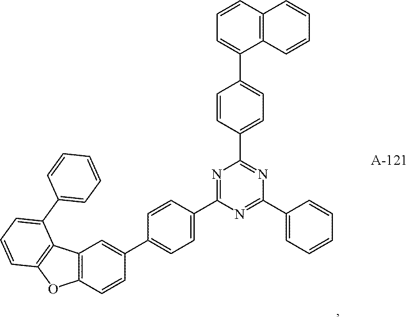 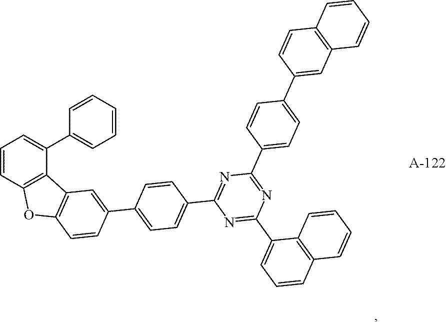 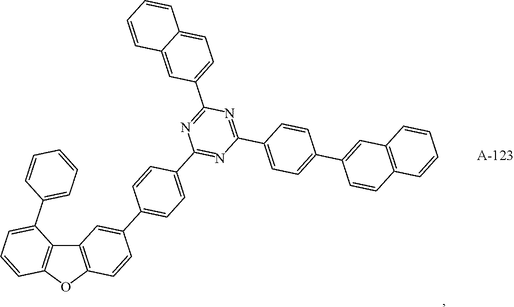 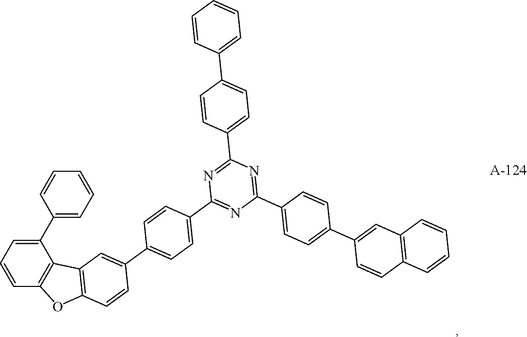 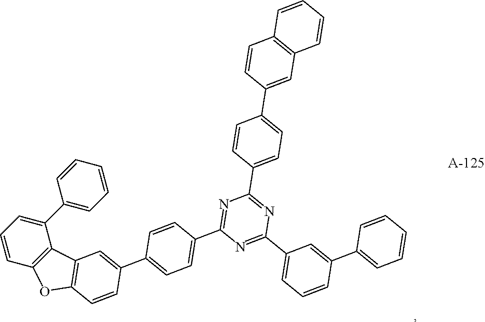 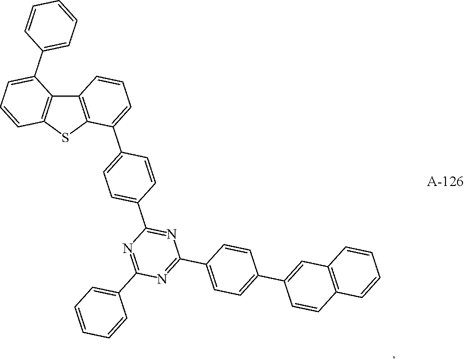 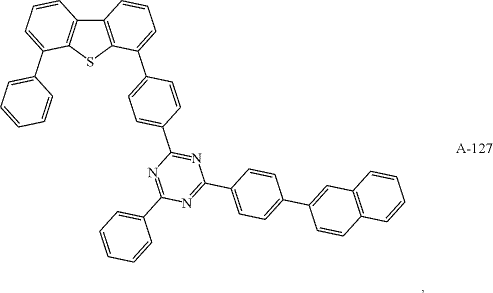 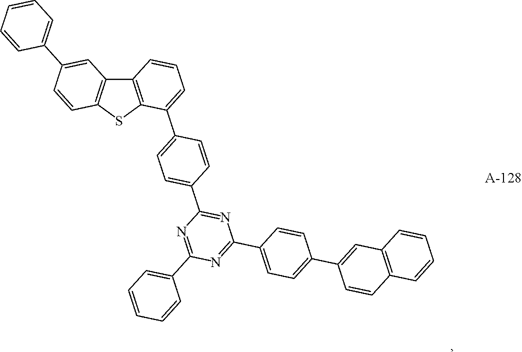 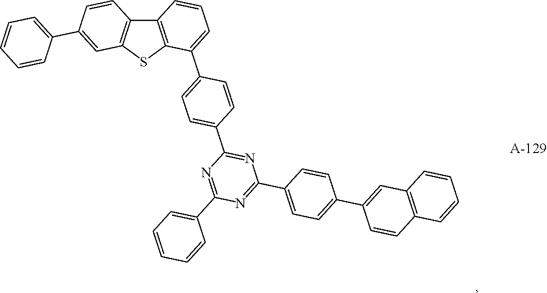 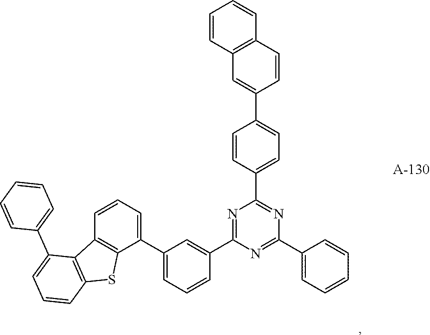 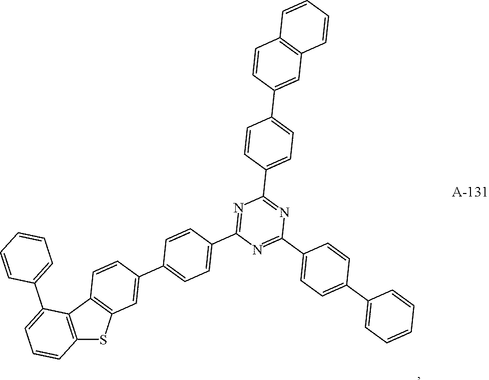 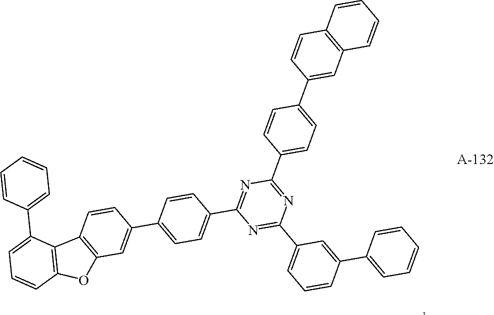 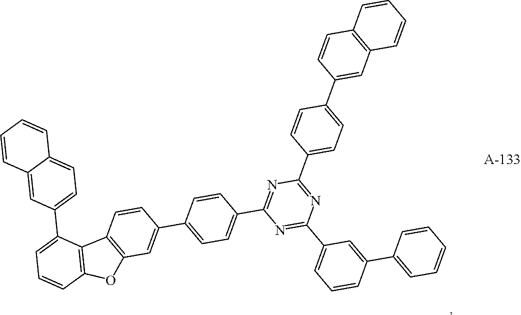 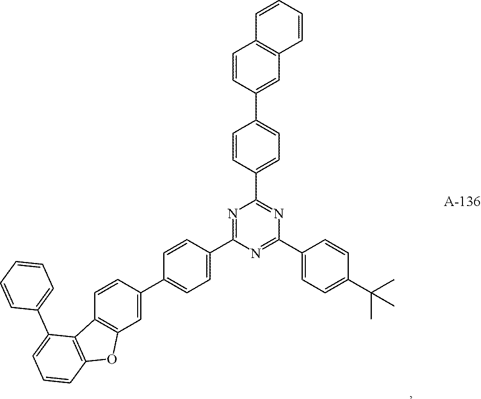 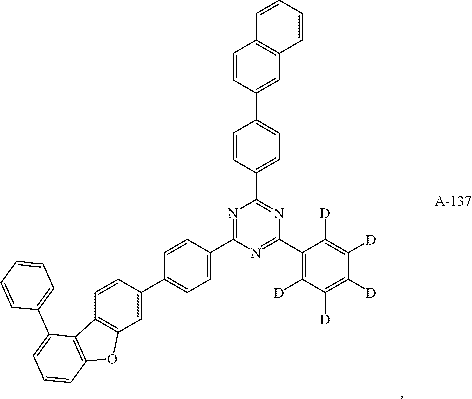 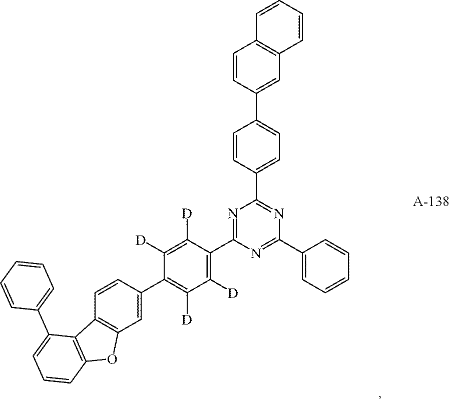 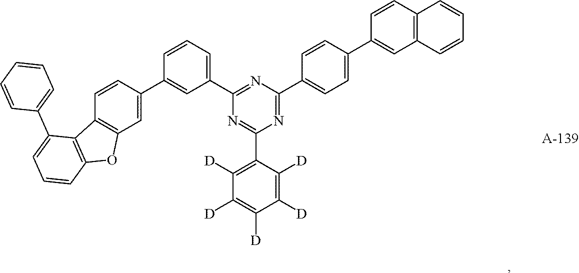 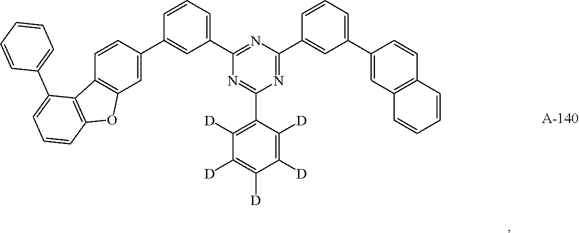 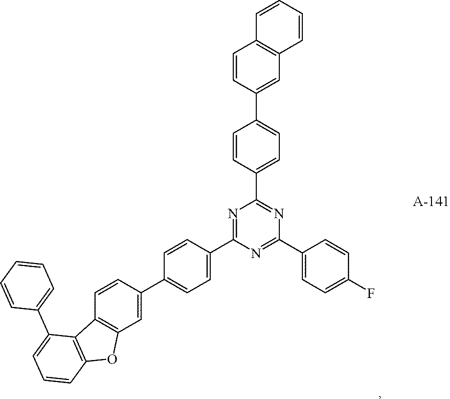 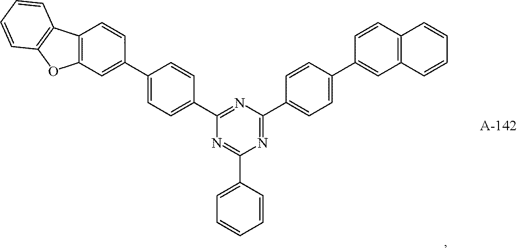 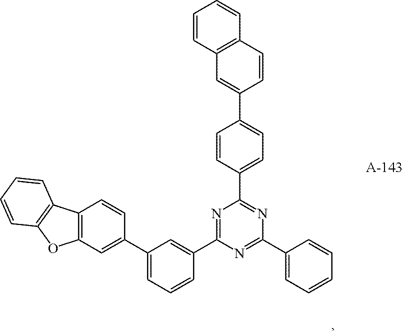 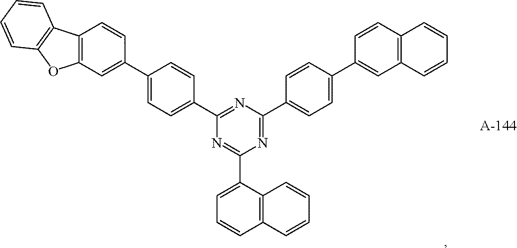 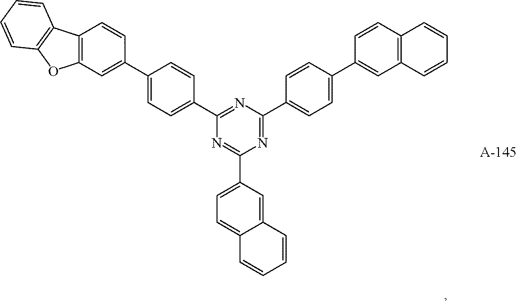 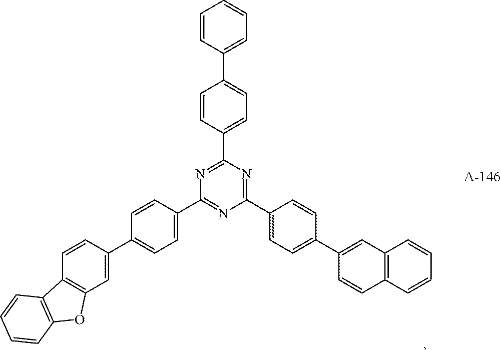 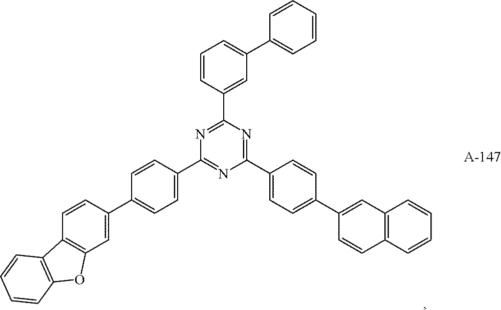 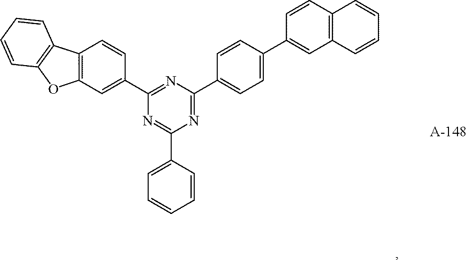 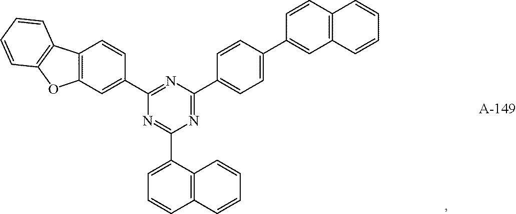 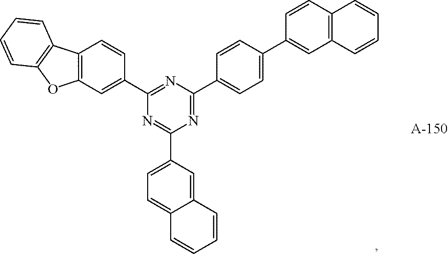 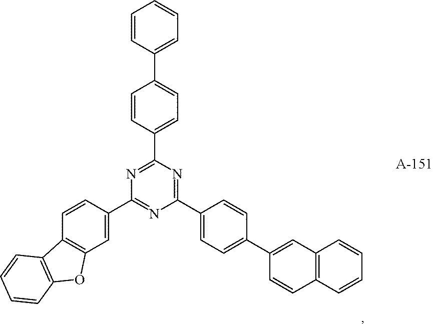 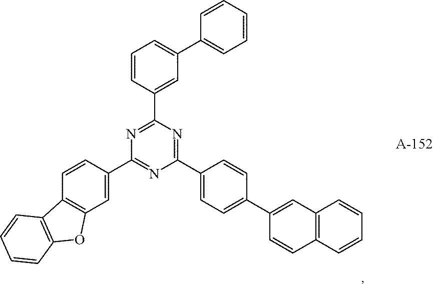 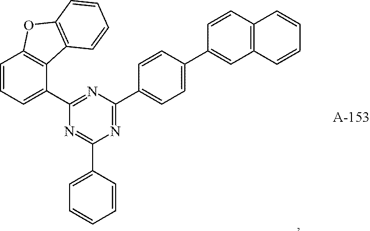 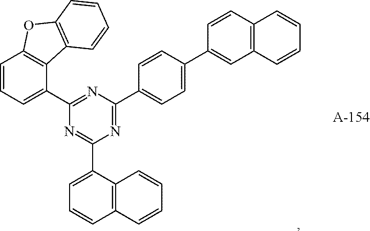 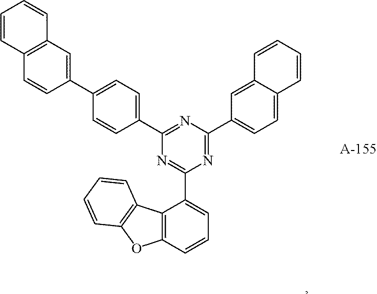 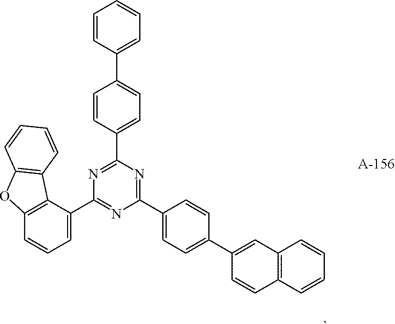 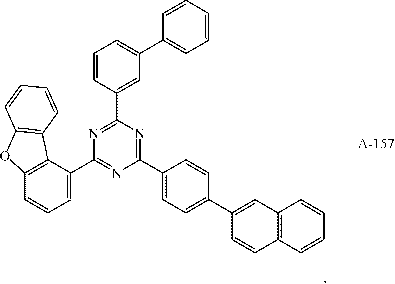 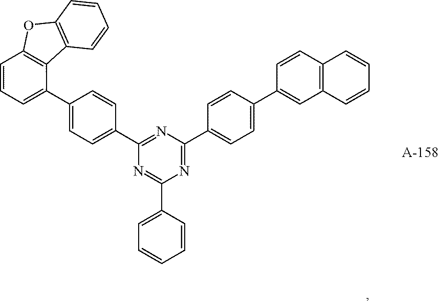 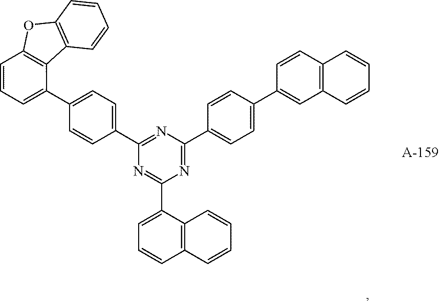 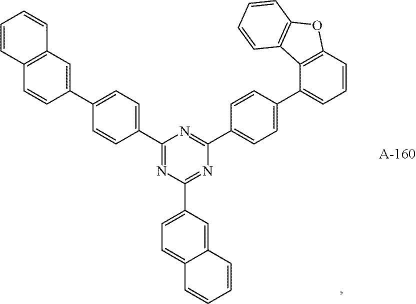 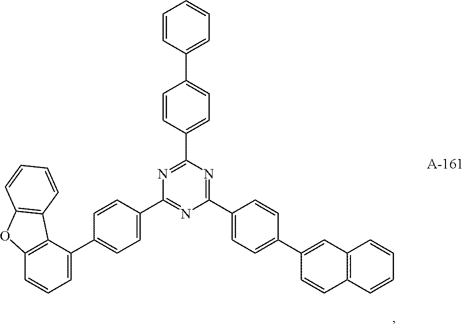 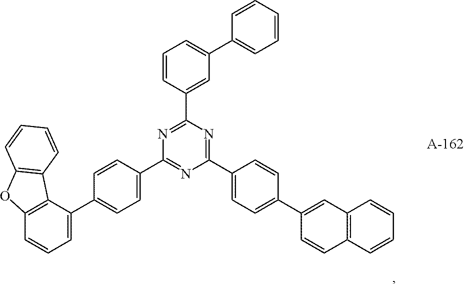 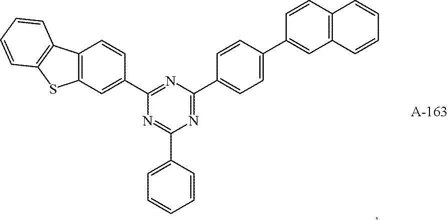 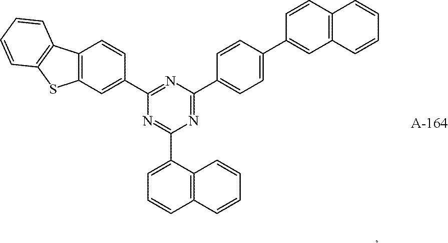 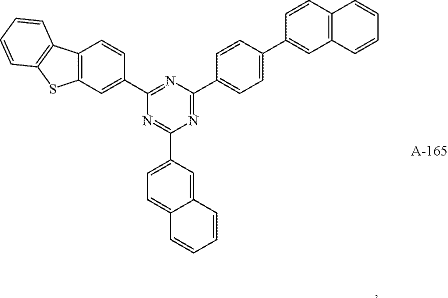 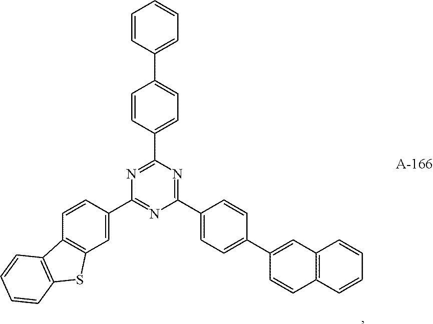 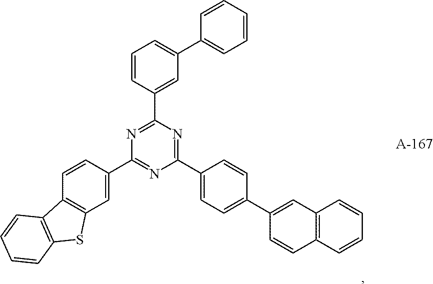 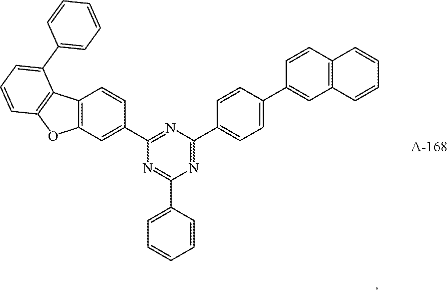 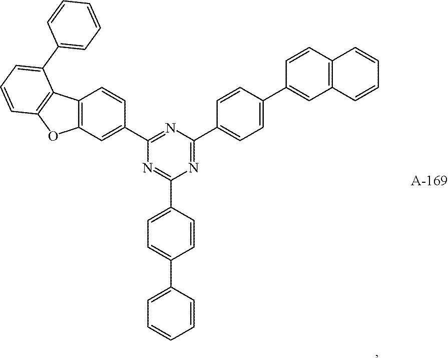 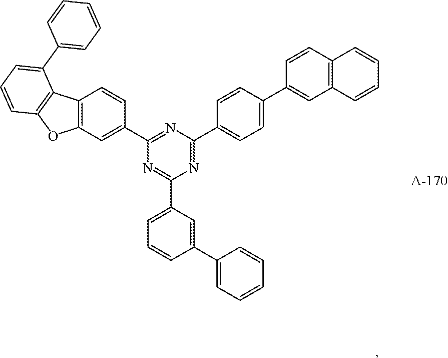 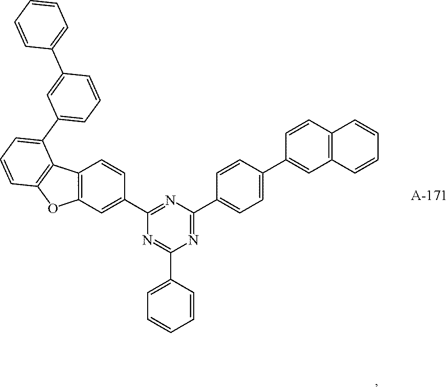 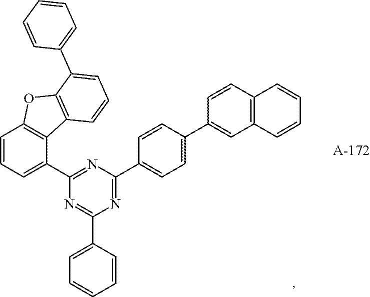 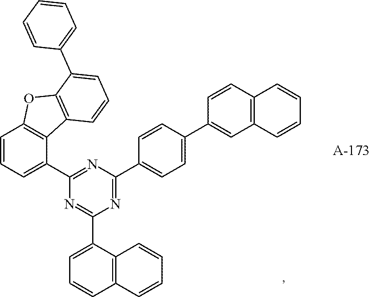 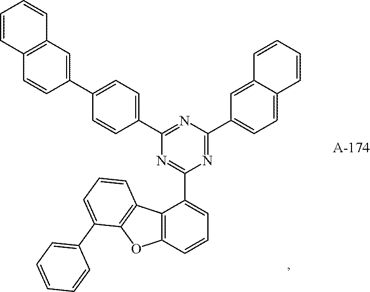 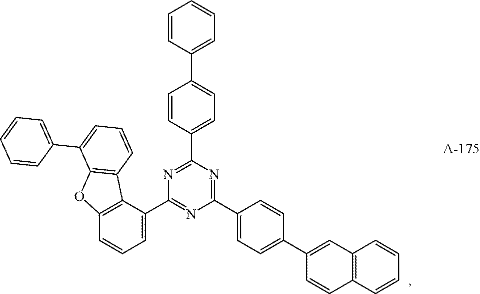 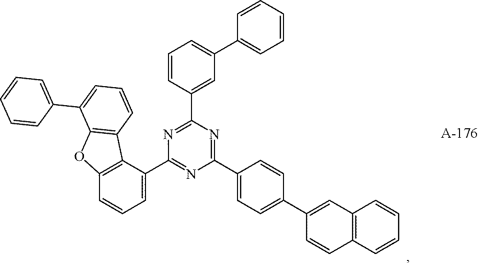 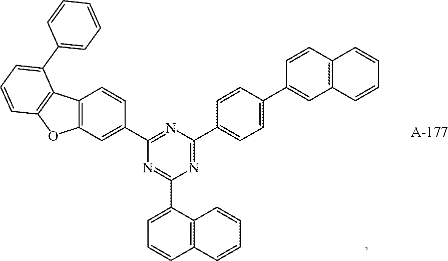 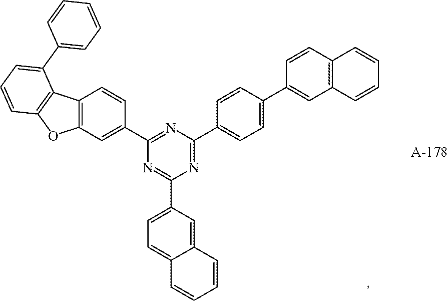 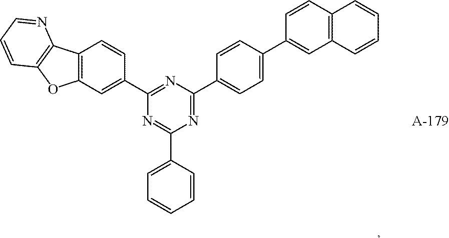 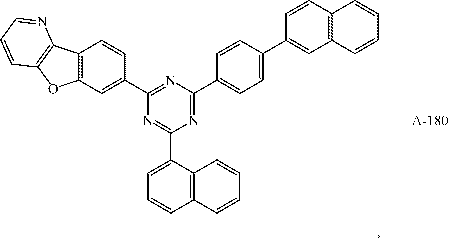 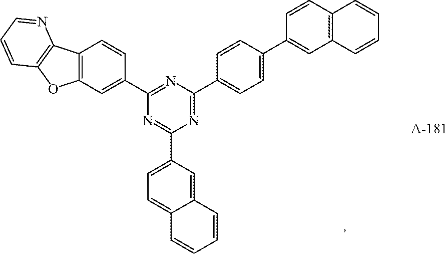 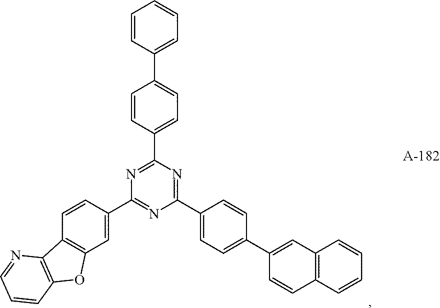 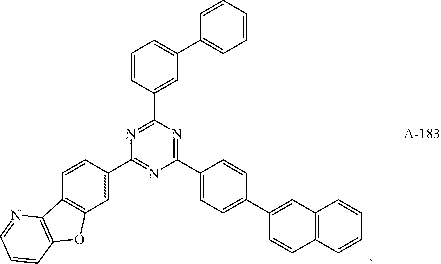 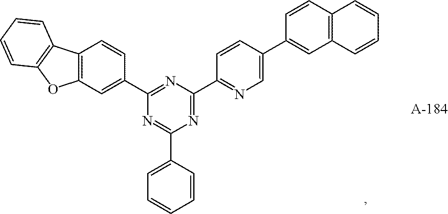 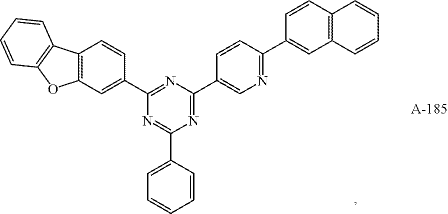 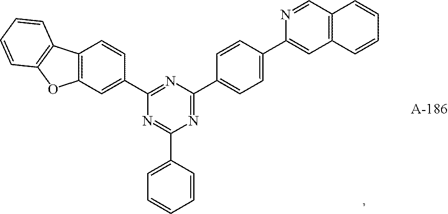 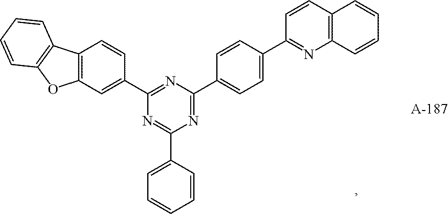 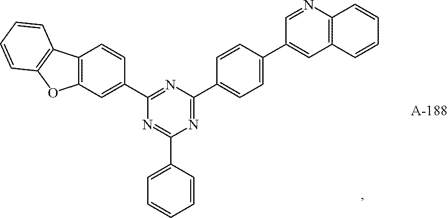 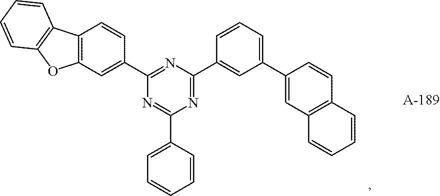 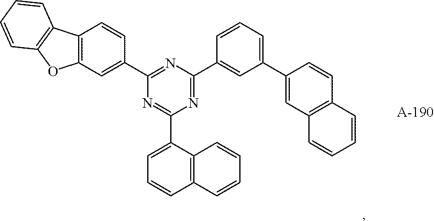 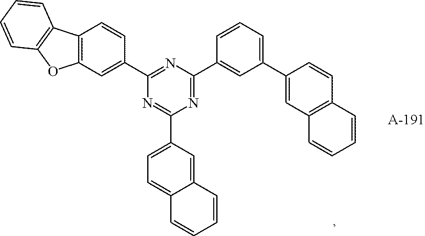 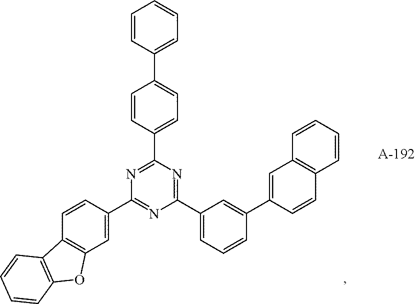 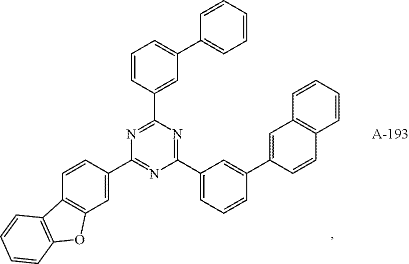 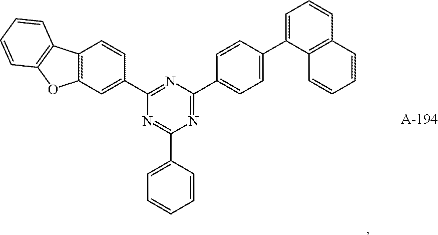 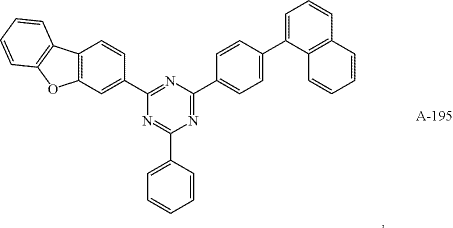 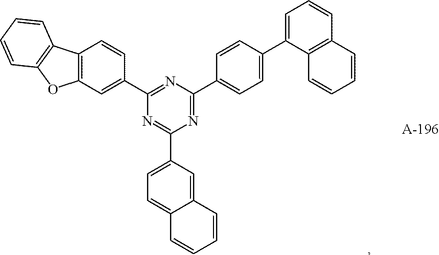 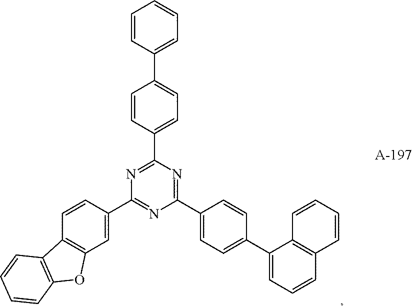 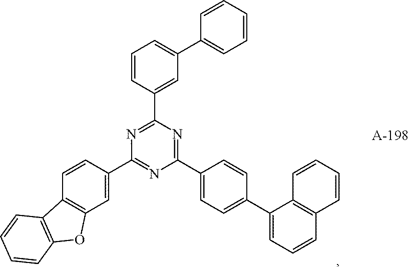 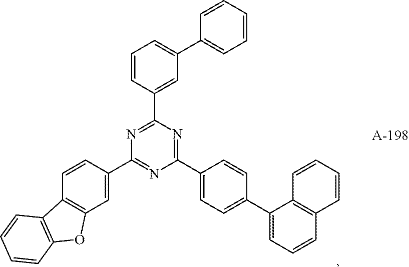 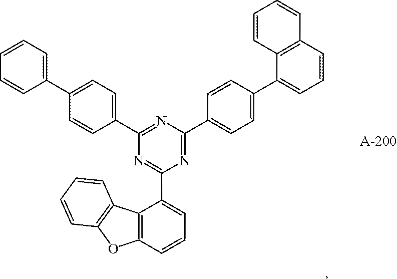
wherein optionally, hydrogens in Compound A-1 to Compound A-200 can be partially or fully substituted with deuterium.

18. The electroluminescent device according to claim 1, wherein the organic layer is a light-emitting layer, and the first compound and the second compound are host materials.

19. The electroluminescent device according to claim 18, wherein the light-emitting layer further comprises at least one phosphorescent material.

20. The electroluminescent device according to claim 19, wherein the phosphorescent material is a metal complex having a general formula of M(Lₐ)ₘ(L_{b})ₙ(L_{c})_{q};
M is selected from a metal with a relative atomic mass greater than 40;
Lₐ, L_{b} and L_{c} are a first ligand, a second ligand and a third ligand coordinated to M, respectively; Lₐ, L_{b} and L_{c} can be optionally joined to form a multidentate ligand; and
Lₐ, L_{b} and L_{c} may be identical or different; m is 1, 2 or 3; n is 0, 1 or 2; q is 0, 1 or 2; the sum of m, n and q is equal to an oxidation state of M; when m is greater than or equal to 2, a plurality of Lₐ may be identical or different; when n is 2, two L_{b} may be identical or different; when q is 2, two L_{c} may be identical or different;
wherein Lₐ has a structure represented by Formula 3: 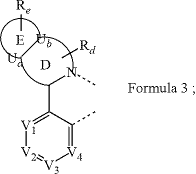
wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and Rₑ represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ, Rᵥ can be optionally joined to form a ring;
wherein L_{b} and L_{c} are, at each occurrence identically or differently, selected from any one of the following structures: 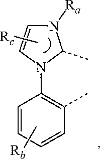 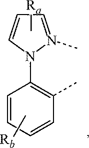 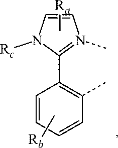 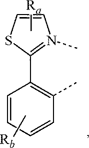 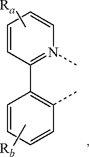 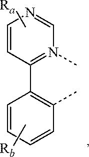 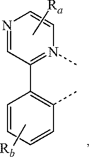 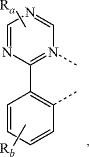 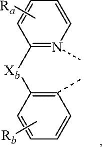 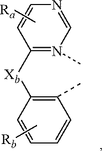 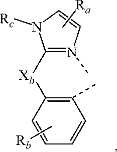 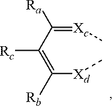
wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in the structures of the ligands L_{b} and L_{c}, adjacent substituents Rₐ, R_{b}, R_{c}, R_{N1}, R_{N2}, R_{C1} and R_{C2} can be optionally joined to form a ring.

21. The electroluminescent device according to claim 19, wherein the phosphorescent material is a metal complex having a general formula of M(Lₐ)ₘ(L_{b})ₙ;
M is selected from a metal with a relative atomic mass greater than 40;
Lₐ and L_{b} are a first ligand and a second ligand coordinated to M, respectively; Lₐ and L_{b} can be optionally joined to form a multidentate ligand; and
m is 1, 2 or 3; n is 0, 1 or 2; the sum of m and n is equal to an oxidation state of M; when m is greater than or equal to 2, a plurality of Lₐ may be identical or different; when n is 2, two L_{b} may be identical or different;
wherein Lₐ has a structure represented by Formula 3: 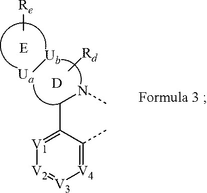
wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and Rₑ represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ, Rᵥ can be optionally joined to form a ring;
wherein the ligand L_{b} has the following structure: 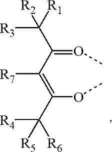
wherein R₁ to R₇ are each independently selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group and combinations thereof;
preferably, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

22. The electroluminescent device according to claim 1, wherein the electroluminescent device emits red light.

23. A compound combination, comprising a first compound and a second compound, wherein the first compound has a structure of H-L-Ar, wherein H has a structure represented by Formula 1: 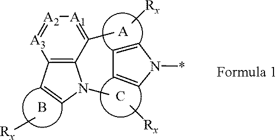
wherein in Formula 1,
A₁, A₂ and A₃ are, at each occurrence identically or differently, selected from N or CR, and the ring A, the ring B and the ring C are, at each occurrence identically or differently, selected from a carbocyclic ring having 5 to 18 carbon atoms or a heterocyclic ring having 3 to 18 carbon atoms;
Rₓ represents, at each occurrence identically or differently, mono-substitution, multiple substitutions or non-substitution;
Ar is selected from substituted or unsubstituted aryl having 6 to 30 carbon atoms, substituted or unsubstituted heteroaryl having 3 to 30 carbon atoms, substituted or unsubstituted arylamino having 6 to 30 carbon atoms or a combination thereof;
L is selected from a single bond, substituted or unsubstituted arylene having 6 to 30 carbon atoms, substituted or unsubstituted heteroarylene having 3 to 30 carbon atoms or a combination thereof;
R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ can be optionally joined to form a ring; and
“*” represents a position where H is joined to L;
wherein the second compound has a structure represented by Formula 2: 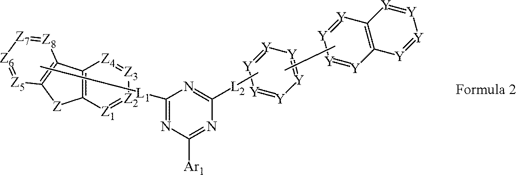
wherein in Formula 2,
Z is selected from O, S or Se;
Z₁ to Z₈ are selected from C, N or CR_{z}, and one of Z₁ to Z₈ is selected from C and joined to L₁;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Y is, at each occurrence identically or differently, selected from C, CR_{y} or N;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

24. An electronic apparatus, comprising the electroluminescent device according to claim 1.
